(19) United States
(12) Patent Application Publication
(10) Pub. No.: US 2011/0067750 A1
(43) Pub. Date: Mar. 24, 2011

(54) TRACKING SOLAR PHOTOVOLTAIC POWER GENERATION SYSTEM, AND TRACKING CONTROL METHOD AND TRACKING SHIFT CORRECTION METHOD FOR TRACKING SOLAR PHOTOVOLTAIC POWER GENERATION SYSTEM

(76) Inventor: Kousuke Ueda, Osaka (JP)

(21) Appl. No.: 12/992,688

(22) PCT Filed: May 28, 2009
(86) PCT No.: PCT/JP2009/059792

§ 371 Date: Nov. 15, 2010

(30) Foreign Application Priority Data
May 28, 2008 (JP) 2008-139819
Jan. 19, 2009 (JP) 2009-009112

(51) Int. Cl. H01L 31/052

(52) U.S. Cl. 136/246

(57) ABSTRACT

According to one embodiment, a tracking drive solar photovoltaic power generator (1) in a tracking solar photovoltaic power generation system comprises a photovoltaic panel (10) that converts sunlight into electric power, and a tracking control portion (13) that provides tracking control over a turning position and a tilt position of the photovoltaic panel (10) so that the photovoltaic panel can track the solar trajectory based on a turning coordinate and a tilt coordinate that have been set corresponding to the solar azimuth angle and the solar altitude. The turning direction and the tilt direction of the photovoltaic panel (10) are controlled by a driving portion (12). The driving portion (12) is capable of tracking the solar trajectory based on the turning coordinate and the tilt coordinate transmitted from the tracking control portion (13) via a control line (13c).

### TECHNICAL FIELD

The present invention relates to a tracking solar photovoltaic power generation system for causing a photovoltaic panel to track the solar trajectory, and a tracking control method and a tracking shift correction method for the tracking solar photovoltaic power generation system.

### BACKGROUND ART

Various types of solar photovoltaic power generators for converting solar energy into electric power have been put to practical use, and tracking drive solar photovoltaic power generators of the type that track the motion of the sun (solar trajectory) and provide a rotation (tracking drive) of a photovoltaic panel have been developed in order to increase the power generating capacity and accordingly obtain large amounts of electric power.

In particular, concentrating solar photovoltaic power generators, in which electric power is generated by concentrating sunlight with a concentrating lens, have the advantage of considerably improved power generation efficiency because their sun-tracking drive (tracking and concentrating) allows sunlight to be perpendicularly concentrated and applied onto the light receiving surfaces of solar cell elements. With such advantageous features, tracking drive (tracking and concentrating) solar photovoltaic power generators using concentrating lenses are used for power supply and power stations in such areas as where a large area is available for installation.

As one example of conventional tracking drive solar photovoltaic power generators, a device that enables a tracking drive of a photovoltaic panel attached to a column has been proposed (see Patent Document 1, for example).

Also, various proposals have been made for an alignment control method (tracking control method) for causing a photovoltaic panel to be opposed to (directly face) the solar trajectory (see Patent Documents 2 to 4, for example).

In the case of tracking sunlight with a sensor (pyrheliometer), there are concerns that additional sensor installation is needed and the accuracy of sensors needs to be ensured. In addition, when some of solar cells are used as sensors, a problem arises that generated electric power is wasted.

Also, in the case of using no sensor, another problem arises that high-level installation work is required in order to improve installation accuracy. In other words, as a precondition for a photovoltaic panel to directly face the solar trajectory, the photovoltaic panel needs to be positioned and installed with high precision on a driving portion including a column (supporting portion).

FIG. 27 is a perspective view illustrating an overview of a conventional tracking drive solar photovoltaic power generator.

The tracking drive solar photovoltaic power generator shown in the drawing includes a photovoltaic panel 110 that can be driven during tracking. The photovoltaic panel 110 is held by a column 111, and its turning direction Roth (turning coordinate φ) and tilt direction Rotv (tilt coordinate θ) are controlled by a driving portion 112 provided on the top of the column 111.

The driving portion 112 includes a turning drive portion (not shown) and a tilt drive portion (not shown) and is configured to track the solar trajectory based on the turning coordinate φ (turning direction Roth) and the tilt coordinate θ (tilt direction Rotv) transmitted from a tracking control portion 113 via a control line 113c.

Although the column 111 is installed vertically relative to the ground, it is difficult in practice to install the column 111 completely vertically, and therefore the column 111 has a tilt to some extent. In addition, the driving portion 112 needs to be positioned with high precision in advance relative to a reference (the ground) since it controls the turning direction Roth and the tilt direction Rotv of the photovoltaic panel 110.

In order to position the driving portion 112 with high precision relative to the reference, the positioning of the driving portion 112 is implemented by applying a declinometer, a clinometer, or a GPS, for example (see Patent Document 4, for example). The positioning of the driving portion 112 thus takes enormous effort and time. In other words, there are problems in that, even in the case of installing only a single tracking drive solar photovoltaic power generator, installation work requires excessive effort and cost. In addition, in the case of building up a system with a large number of photovoltaic panels 110, a situation may arise in which installation itself is difficult.

That is, conventional tracking drive solar photovoltaic power generators necessitate highly reliable sensors that operate with high precision, or conventional tracking drive solar photovoltaic power generators have problems in terms of installation, such as requiring installation work with high-precision positioning.

### PRIOR ART DOCUMENT

### Patent Document

[Patent Document 1] JP 11-284217A
[Patent Document 2] JP 8-241125A
[Patent Document 3] JP 2002-202817A
[Patent Document 4] JP 2007-19331A

### SUMMARY OF INVENTION

### Problem to be Solved by the Invention

The present invention has been conceived in view of such circumstances, and it is an object of the present invention to provide a tracking control method for a tracking solar photovoltaic power generation system, in which a shift in the position of the turning coordinate relative to the solar azimuth angle is detected with use of the turning coordinate at which the panel output reaches its maximum value, and a shift in the position of the tilt coordinate relative to the solar altitude is detected with use of the tilt coordinate at which the panel output reaches its maximum value, and therefore the turning position and the tilt position of a photovoltaic panel can be adjusted with ease and high precision so that the photovoltaic panel can directly face the solar trajectory (solar azimuth and altitude).

It is also another object of the present invention to provide a highly reliable and productive tracking shift correction method for a tracking solar photovoltaic power generation system, the method eliminating the need to stop the tracking solar photovoltaic power generation system associated with tracking shift correction and causing no loss in the amount of generated electric power, by detecting a tracking shift of a photovoltaic panel that is targeted for tracking shift correction in a state in which a tracking drive solar photovoltaic power generator is connected to a power conversion portion in the tracking solar photovoltaic power generation system.

It is still another object of the present invention to provide a highly reliable and productive tracking solar photovoltaic power generation system that eliminates the need to be stopped associated with tracking shift correction and causes no loss in the amount of generated electric power, by adopting a configuration in which the system comprises a power conversion portion that converts direct-current electric power generated by a plurality of tracking drive solar photovoltaic power generators, which are arranged in parallel connection, into alternating-current electric power and supplies the alternating-current electric power to an interconnection load, and a tracking shift of a photovoltaic panel targeted for tracking shift correction is detected in a state in which the photovoltaic panel is running by being connected to the power conversion portion.

### Means for Solving the Problems

The present invention provides a tracking control method for a tracking solar photovoltaic power generation system for causing a photovoltaic panel to track the solar trajectory, in which a tracking drive solar photovoltaic power generator includes a photovoltaic panel that converts sunlight into electric power, and a tracking control portion that provides tracking control over the turning position and the tilt position of the photovoltaic panel so that the photovoltaic panel can directly face the solar trajectory based on control coordinates, namely a turning coordinate and a tilt coordinate, that have been set corresponding to the solar azimuth angle and the solar altitude. The method comprises a first directly-facing turning coordinate detection process for detecting a first directly-facing turning coordinate at which a panel output reaches its maximum value, by moving the turning position of the photovoltaic panel while sequentially changing the turning coordinate in a first turning detection range that is defined in connection with a first turning coordinate corresponding to the solar azimuth angle, and a first directly-facing tilt coordinate detection process for detecting a first directly-facing tilt coordinate at which the panel output reaches its maximum value, by moving the tilt position of the photovoltaic panel while sequentially changing the tilt coordinate in a first tilt detection range that is defined in connection with a first tilt coordinate corresponding to the solar altitude.

This configuration makes it possible to detect a shift in the position of the turning coordinate (first turning coordinate) relative to the solar azimuth angle with use of the first directly-facing turning coordinate and to detect a shift in the position of the tilt coordinate (first tilt coordinate) relative to the solar altitude with use of the first directly-facing tilt coordinate. By correcting both the shift in the position of the turning coordinate (first directly-facing turning coordinate) relative to the solar azimuth angle and the shift in the position of the tilt coordinate (first directly-facing tilt coordinate) relative to the solar altitude to be corrected together, it is possible to adjust the turning position and tilt position of a photovoltaic panel with ease and high precision so that the photovoltaic panel can directly face the solar trajectory (solar azimuth angle and solar altitude).

Moreover, in the tracking control method for the tracking solar photovoltaic power generation system according to the present invention, the first turning detection range is defined from a first turning detection start coordinate to a first turning detection end coordinate by using the first turning coordinate as a first turning detection reference coordinate and applying a predetermined first turning displacement angle in both positive and negative directions of the first turning detection reference coordinate, and the first tilt detection range is defined from a first tilt detection start coordinate to a first tilt detection end coordinate by using either the first tilt coordinate or a first time-dependent corrected tilt coordinate obtained through time-dependent correction of the first tilt coordinate as a first tilt detection reference coordinate and applying a predetermined first tilt displacement angle in both positive and negative directions of the first tilt detection reference coordinate.

This configuration makes it possible to define the first turning detection range and the first tilt detection range with ease and high precision, thus enabling the first directly-facing turning coordinate and the first directly-facing tilt coordinate to be detected with ease and high precision.

Moreover, in the tracking control method for the tracking solar photovoltaic power generation system according to the present invention, the first directly-facing tilt coordinate detection process is performed after execution of a first directly-facing turning coordinate alignment process in which the turning coordinate is aligned with the first directly-facing turning coordinate detected in the first directly-facing turning coordinate detection process.

This configuration makes it possible to detect a shift in the position of the tilt coordinate (first tilt coordinate) in a state in which the photovoltaic panel directly faces the solar trajectory in the turning direction, thus enabling precise detection of the first directly-facing tilt coordinate.

Moreover, in the tracking control method for the tracking solar photovoltaic power generation system according to the present invention, before execution of the first directly-facing tilt coordinate detection process, the first time-dependent corrected tilt coordinate is calculated through time-dependent correction of the first tilt coordinate that reflects an amount of change in the solar altitude over time, and the first tilt detection reference coordinate is displaced in advance from the first tilt coordinate to the first time-dependent corrected tilt coordinate.

This configuration makes it possible to perform the first directly-facing tilt coordinate detection process by applying the first time-dependent corrected tilt coordinate that has been calculated with the amount of change in the solar altitude over time being reflected in the tilt coordinate, thus enabling the first directly-facing tilt coordinate to be detected in a short time with high precision.

Moreover, in the tracking control method for the tracking solar photovoltaic power generation system according to the present invention, a photovoltaic panel is driven by applying a corrected target turning coordinate and a corrected target tilt coordinate that have been defined by specifying a targeted solar azimuth angle as a target solar azimuth angle and a targeted solar altitude as a target solar altitude, performing coordinate transformation using preset equations from the target solar azimuth angle and the target solar altitude to a target turning coordinate and a target tilt coordinate for the turning coordinate and the tilt coordinate, and correcting the target turning coordinate and the target tilt coordinate based on the first directly-facing turning coordinate and the first directly-facing tilt coordinate.

With this configuration, since a photovoltaic panel is driven by applying the corrected target turning coordinate and the corrected target tilt coordinate that have been defined through the correction based on the first directly-facing turning coordinate and the first directly-facing tilt coordinate, it is possible to correct a shift in position with ease and high precision before driving a photovoltaic panel.

Moreover, in the tracking control method for the tracking solar photovoltaic power generation system according to the present invention, voltage is used to detect the panel output in the first directly-facing turning coordinate detection process and the first directly-facing tilt coordinate detection process.

This configuration makes it possible to detect the panel output with ease and a simple structure even if a shift in position is relatively large.

Moreover, in the tracking control method for the tracking solar photovoltaic power generation system according to the present invention, current is used to detect the panel output in the first directly-facing turning coordinate detection process and the first directly-facing tilt coordinate detection process.

This configuration makes it possible to detect the panel output with high precision and a simple structure.

Moreover, the tracking control method for the tracking solar photovoltaic power generation system according to the present invention comprises a second directly-facing turning coordinate detection process for detecting a second directly-facing turning coordinate at which the panel output reaches its maximum value, by moving the turning position of the photovoltaic panel while sequentially changing the turning coordinate in a second turning detection range that is defined in connection with the first directly-facing turning coordinate, and a second directly-facing tilt coordinate detection process for detecting a second directly-facing tilt coordinate at which the panel output reaches its maximum value, by moving the tilt position of the photovoltaic panel while sequentially changing the tilt coordinate in a second tilt detection range that is defined in connection with the first directly-facing tilt coordinate.

This configuration makes it possible to detect a shift in the position of the first directly-facing turning coordinate relative to the solar azimuth angle with high precision with use of the second directly-facing turning coordinate detected in the second turning detection range that is smaller than the first turning detection range and to detect a shift in the position of the first directly-facing tilt coordinate relative to the solar altitude with high precision with use of the second directly-facing tilt coordinate detected in the second tilt detection range that is smaller than the first tilt detection range. By correcting together the shift in the position of the turning coordinate (second directly-facing turning coordinate) relative to the solar azimuth angle and the shift in the position of the tilt coordinate (second directly-facing tilt coordinate) relative to the solar altitude, it is thus possible to adjust the turning position and tilt position of the photovoltaic panel with ease and high precision so that the photovoltaic panel can directly face the solar trajectory.

Moreover, in the tracking control method for the tracking solar photovoltaic power generation system according to the present invention, the second turning detection range is defined from a second turning detection start coordinate to a second turning detection end coordinate by using either the first directly-facing turning coordinate or a first time-dependent corrected turning coordinate obtained through time-dependent correction of the first directly-facing turning coordinate as a second turning detection reference coordinate and applying a predetermined second turning displacement angle smaller than the first turning displacement angle in both positive and negative directions of the second turning detection reference coordinate, and the second tilt detection range is defined from a second tilt detection start coordinate to a second tilt detection end coordinate by using either the first directly-facing tilt coordinate or a second time-dependent corrected tilt coordinate obtained through time-dependent correction of the first directly-facing tilt coordinate as a second tilt detection reference coordinate and applying a predetermined second tilt displacement angle smaller than the first tilt displacement angle in both positive and negative directions of the second tilt detection reference coordinate.

This configuration makes it possible to define the second turning detection range and the second tilt detection range to be smaller than the first turning detection range and the first tilt detection range, thus enabling the second directly-facing turning coordinate and the second directly-facing tilt coordinate to be detected with higher precision than the first directly-facing turning coordinate and the first directly-facing tilt coordinate.

Moreover, in the tracking control method for the tracking solar photovoltaic power generation system according to the present invention, before execution of the second directly-facing turning coordinate detection process, the first time-dependent corrected turning coordinate is calculated through time-dependent correction of the first directly-facing turning coordinate that reflects an amount of change in the solar azimuth angle over time, and the second turning detection reference coordinate is displaced in advance from the first directly-facing turning coordinate to the first time-dependent corrected turning coordinate.

This configuration makes it possible to perform subsequent processing (second operation pattern) by applying the first time-dependent corrected turning coordinate that has been calculated with the amount of change in the solar azimuth angle over time being reflected in the first directly-facing turning coordinate, thus enabling the second directly-facing turning coordinate to be detected in a short time with high precision.

Moreover, in the tracking control method for the tracking solar photovoltaic power generation system according to the present invention, the second directly-facing tilt coordinate detection process is performed after execution of a second directly-facing turning coordinate alignment process in which the turning coordinate is aligned with the second directly-facing turning coordinate detected in the second directly-facing turning coordinate detection process.

This configuration makes it possible to detect a shift in the position of the tile coordinate in a state in which a photovoltaic panel directly faces the solar trajectory in the turning direction, thus enabling precise detection of the second directly-facing tilt coordinate.

Moreover, in the tracking control method for the tracking solar photovoltaic power generation system according to the present invention, before execution of the second directly-facing tilt coordinate detection process, the second time-dependent corrected tilt coordinate is calculated through time-dependent correction of the first directly-facing tilt coordinate that reflects an amount of change in the solar altitude over time, and the second tilt detection reference coordinate is displaced in advance from the first directly-facing tilt coordinate to the second time-dependent corrected tilt coordinate.

This configuration makes it possible to perform the second directly-facing tilt coordinate detection process by applying the second time-dependent corrected tilt coordinate that has been calculated with the amount of change in the solar altitude θ over time being reflected in the first directly-facing tilt coordinate, thus enabling the second directly-facing tilt coordinate to be detected in a short time with high precision.

Moreover, in the tracking control method for the tracking solar photovoltaic power generation system according to the present invention, a photovoltaic panel is driven by applying a corrected target turning coordinate and a corrected target tilt coordinate that have been defined by specifying a targeted solar azimuth angle as a target solar azimuth angle and a targeted solar altitude as a target solar altitude, performing coordinate transformation using preset equations from the target solar azimuth angle and the target solar altitude to a target turning coordinate and a target tilt coordinate for the turning coordinate and the tilt coordinate, and correcting the target turning coordinate and the target tilt coordinate based on the second directly-facing turning coordinate and the second directly-facing tilt coordinate.

With this configuration, since a photovoltaic panel is driven by applying the corrected target turning coordinate and the corrected target tilt coordinate that are defined by the correction based on the second directly-facing turning coordinate and the second directly-facing tilt coordinate, it is possible to correct a shift in position with ease and high precision before driving the photovoltaic panel.

Moreover, in the tracking control method for the tracking solar photovoltaic power generation system according to the present invention, voltage is used to detect the panel output in the first directly-facing turning coordinate detection process and the first directly-facing tilt coordinate detection process, and current is used to detect the panel output in the second directly-facing turning coordinate detection process and the second directly-facing tilt coordinate detection process.

This configuration makes it possible to detect the panel output with ease with use of voltage in previous processes (first directly-facing turning coordinate detection process and first directly-facing tilt coordinate detection process) and to detect the panel output with high precision with use of current in subsequent processes (second directly-facing turning coordinate detection process and second directly-facing tilt coordinate detection process), thus enabling a shift in the position of the turning coordinate relative to the solar azimuth angle and a shift in the position of the tilt coordinate to be detected with ease and high precision.

Moreover, in the tracking control method for the tracking solar photovoltaic power generation system according to the present invention, current is used to detect the panel output in the first directly-facing turning coordinate detection process and the first directly-facing tilt coordinate detection process as well as to detect the panel output in the second directly-facing turning coordinate detection process and the second directly-facing tilt coordinate detection process.

This configuration makes it possible to detect the panel output with high precision with use of current in both previous (first directly-facing turning coordinate detection process and first directly-facing tilt coordinate detection process) and subsequent (second directly-facing turning coordinate detection process and second directly-facing tilt coordinate detection process) processes, thus enabling a shift in the position of the turning coordinate relative to the solar azimuth angle and a shift in the position of the tilt coordinate to be detected with ease and high precision.

Moreover, the tracking control method for the tracking solar photovoltaic power generation system according to the present invention comprises a third directly-facing turning coordinate detection process for detecting a third directly-facing turning coordinate at which the panel output reaches its maximum value by controlling the turning position of the photovoltaic panel while sequentially changing the turning coordinate in a third turning detection range that is defined in connection with the second directly-facing turning coordinate, and a third directly-facing tilt coordinate detection process for detecting a third directly-facing tilt coordinate at which the panel output reaches its maximum value, by controlling the tilt coordinate in a third tilt detection range that is defined in connection with the second directly-facing tilt coordinate. The third turning detection range is defined from a third turning detection start coordinate to a third turning detection end coordinate by using either the second directly-facing turning coordinate or a second time-dependent corrected turning coordinate obtained through time-dependent correction of the second directly-facing turning coordinate as a third turning detection reference coordinate and applying a predetermined third turning displacement angle smaller than the second turning displacement angle in both positive and negative directions of the third turning detection reference coordinate, and the third tilt detection range is defined from a third tilt detection start coordinate to a third tilt detection end coordinate by using either the second directly-facing tilt coordinate or a third time-dependent corrected tilt coordinate obtained through time-dependent correction of the second directly-facing tilt coordinate as a third tilt detection reference coordinate and applying a predetermined third tilt displacement angle smaller than the second tilt displacement angle in both positive and negative directions of the third tilt detection reference coordinate.

This configuration makes it possible to define the third turning detection range to be smaller than the second turning detection range and define the third tilt detection range to be smaller than the second tilt detection range, thus enabling the third directly-facing turning coordinate and the third directly-facing tilt coordinate to be detected with higher precision than the second directly-facing turning coordinate and the second directly-facing tilt coordinate. Furthermore, by correcting a shift in the position of the turning coordinate (third directly-facing turning coordinate) relative to the solar azimuth angle and a shift in the position of the tilt coordinate (third directly-facing tilt coordinate) relative to the solar altitude with high precision, it is possible to adjust the turning position and the tilt position of the photovoltaic panel with ease and higher precision so that the photovoltaic panel can directly face the solar trajectory.

Moreover, in the tracking control method for the tracking solar photovoltaic power generation system according to the present invention, current is used to detect the panel output in the third directly-facing turning coordinate detection process and the third directly-facing tilt coordinate detection process.

This configuration it possible to detect the maximum panel output multiple times with use of current, thus enabling the panel output to be detected with ease and high precision in a state in which the positions of the turning coordinate and the tilt coordinate are slightly shifted relative to the solar azimuth angle.

Moreover, the present invention provides a tracking shift correction method for a tracking solar photovoltaic power generation system for causing a photovoltaic panel to track a solar trajectory, the system comprising a plurality of tracking drive solar photovoltaic power generators that are arranged in parallel connection and a power conversion portion that converts direct-current electric power generated by the tracking drive solar photovoltaic power generators into alternating-current electric power and supplies the alternating-current electric power to an interconnection load, each of the tracking drive solar photovoltaic power generators comprising a photovoltaic panel that converts sunlight into direct-current electric power, and a driving portion that drives the photovoltaic panel based on tracking information causing the photovoltaic panel to track the solar trajectory, wherein a tracking shift of the one of the photovoltaic panels that is targeted for tracking shift correction is detected in a state in which the corresponding tracking drive solar photovoltaic power generator is running by being connected to the power conversion portion.

With this configuration, since a tracking shift of a photovoltaic panel is detected with the photovoltaic panel being connected to the power conversion portion, the tracking shift of the photovoltaic panel can be corrected while maintaining system interconnection by continuing electric power generation by the tracking drive solar photovoltaic power generators and electric power supply from the power conversion portion to the interconnection load. It is thus possible to provide a highly reliable and productive tracking shift correction method for the tracking solar photovoltaic power generation system, which eliminates the need to stop the tracking solar photovoltaic power generation system associated with tracking shift correction and causes no loss in the amount of generated electric power.

Moreover, in the tracking shift correction method for the tracking solar photovoltaic power generation system according to the present invention, each of the tracking drive solar photovoltaic power generators comprises a tracking control portion that outputs the tracking information, in which a tracking shift is detected by the tracking control portion, and the driving portion is configured to correct a tracking shift of the photovoltaic panel in accordance with the tracking shift detected by the tracking control portion.

This configuration makes it possible to detect and correct a tracking shift individually for each of the tracking drive solar photovoltaic power generators, thus enabling the tracking control portions to be dispersed in the tracking solar photovoltaic power generation system. It is thus possible to provide a highly reliable tracking solar photovoltaic power generation system at low cost, which simplifies wiring structure of a control system and accordingly simplifies installation work.

Moreover, in the tracking shift correction method for the tracking solar photovoltaic power generation system according to the present invention, each of the tracking drive solar photovoltaic power generators comprises a detection circuit that detects the output of the photovoltaic panel, and the tracking control portion detects a tracking shift based on the output of the photovoltaic panel detected by the detection circuit.

This configuration makes it possible to detect the output of the photovoltaic panel with ease and high precision, thus enabling a tracking shift of the photovoltaic panel to be detected and corrected with ease and high precision.

Moreover, in the tracking shift correction method for the tracking solar photovoltaic power generation system according to the present invention, the detection circuit includes a current detecting portion that detects output current of the photovoltaic panel.

This configuration makes it possible to detect the output current of the photovoltaic panel to be detected with ease and high precision, thus enabling a tracking shift of the photovoltaic panel to be corrected with ease and high precision.

Moreover, in the tracking shift correction method for the tracking solar photovoltaic power generation system according to the present invention, a directly-facing position in which the photovoltaic panel directly faces the solar trajectory is determined based on the output current detected by the current detecting portion, and the photovoltaic panel is moved to the directly-facing position so as to correct a shift in position.

This configuration makes it possible to correct a tracking shift by applying variations in the output current that is sensitive to a tracking shift, thus enabling the directly-facing position in which the photovoltaic panel directly faces the solar trajectory to be determined with ease and high precision and accordingly a tracking shift to be corrected with ease and high precision.

Moreover, in the tracking shift correction method for the tracking solar photovoltaic power generation system according to the present invention, the detection circuit includes a voltage detecting portion that detects output voltage of the photovoltaic panel.

This configuration makes it possible to detect the output voltage of the photovoltaic panel with ease and high precision, thus enabling a tracking shift of the photovoltaic panel to be corrected with ease and high precision.

Moreover, in the tracking shift correction method for the tracking solar photovoltaic power generation system according to the present invention, a directly-facing position in which the photovoltaic panel directly faces the solar trajectory is determined based on the output voltage detected by the voltage detecting portion, and the photovoltaic panel is moved to the directly-facing position so as to correct a shift in position.

This configuration makes it possible to correct a tracking shift by applying variations in the output voltage that is responsive to a wide range of tracking shifts, thus enabling the directly-facing position in which the photovoltaic panel directly faces the solar trajectory to be determined with ease and high precision and accordingly a tracking shift to be corrected with ease and high precision.

Moreover, in the tracking shift correction method for the tracking solar photovoltaic power generation system according to the present invention, the directly-facing position is determined as a directly-facing turning position that is a directly-facing position in a turning direction.

This configuration makes it possible to correct a tracking shift in the turning direction with ease and high precision.

Moreover, in the tracking shift correction method for the tracking solar photovoltaic power generation system according to the present invention, the directly-facing position is determined as a directly-facing tilt position that is a directly-facing position in a tilt direction.

This configuration makes it possible to correct a tracking shift in the tilt direction with ease and high precision.

Moreover, in the tracking shift correction method for the tracking solar photovoltaic power generation system according to the present invention, the power conversion portion comprises a common inverter that is connected so as to convert direct-current electric power that is output from each of the photovoltaic panels collectively into alternating-current electric power and supply the resultant alternating-current electric power to the interconnection load.

With this configuration, a plurality of tracking drive solar photovoltaic power generators are run by being connected to a single common inverter. It is thus possible to simplify the configuration of the power conversion portion and to stabilize the operating voltage at the direct-current electric power, thus enabling a tracking shift to be detected with ease and high precision.

Moreover, in the tracking shift correction method for the tracking solar photovoltaic power generation system according to the present invention, the power conversion portion comprises a plurality of individual inverters that are connected so as to each convert direct-current electric power that is output from each of the photovoltaic panels individually into alternating-current electric power and supply the resultant alternating-current electric power collectively to the interconnection load.

With this configuration, the individual inverters each having a capacity corresponding to the capacity of each tracking drive solar photovoltaic power generator (photovoltaic panel) are arranged in direct correspondence with the photovoltaic panels. It is thus possible to stabilize the operating voltage by adjusting the outputs of the photovoltaic panels and to thereby detect a tracking shift with ease and high precision.

Moreover, in the tracking shift correction method for the tracking solar photovoltaic power generation system according to the present invention, the common inverter is configured to cause output operating points of the photovoltaic panels to follow an optimum operating point under maximum power point tracking control.

This configuration makes it possible to correct a tracking shift in a state in which the photovoltaic panels are operated at the optimum operating point (optimum output voltage), thus enabling a tracking shift to be corrected with ease and high precision under stable operating conditions.

Moreover, in the tracking shift correction method for the tracking solar photovoltaic power generation system according to the present invention, the common inverter or the individual inverters operate under constant voltage control and hold output operating points of the photovoltaic panels at a constant voltage.

This configuration makes it possible to correct a tracking shift in a state in which the photovoltaic panels are operated at a constant voltage, thus enabling a tracking shift to be corrected with ease and high precision under stable operating conditions.

Moreover, the present invention provides a tracking solar photovoltaic power generation system for causing a photovoltaic panel to track a solar trajectory, the system comprising a plurality of tracking drive solar photovoltaic power generators that are arranged in parallel connection, and a power conversion portion that converts direct-current electric power generated by the tracking drive solar photovoltaic power generators into alternating-current electric power and supply the alternating-current electric power to an interconnection load, each of the tracking drive solar photovoltaic power generators comprising a photovoltaic panel that converts sunlight into direct-current electric power, and a driving portion that drives the photovoltaic panel based on tracking information causing the photovoltaic panel to track the solar trajectory, wherein a tracking shift of the one of the photovoltaic panels that is targeted for tracking shift correction is detected in a state in which the corresponding tracking drive solar photovoltaic power generator is running by being connected to the power conversion portion.

This configuration makes it possible to detect a tracking shift of a photovoltaic panel in a state in which the corresponding tracking drive solar photovoltaic power generator is running by being connected to the power conversion portion, thus providing a highly reliable and productive tracking solar photovoltaic power generation system that eliminates the need to be stopped associated with tracking shift correction and causes no loss in the amount of generated electric power.

Moreover, in the tracking solar photovoltaic power generation system according to the present invention, the power conversion portion comprises a common inverter that is connected so as to convert direct-current electric power that is output from each of the photovoltaic panels collectively into alternating-current electric power and supply the resultant alternating-current electric power to the interconnection load.

This configuration simplifies the configuration of the power conversion portion and stabilizes the operating voltage with direct-current electric power, thus enabling a tracking shift to be detected with ease and high precision.

Moreover, in the tracking solar photovoltaic power generation system according to the present invention, the power conversion portion comprises a plurality of individual inverters that are connected so as to each convert direct-current electric power that is output from each of the photovoltaic panels individually into alternating-current electric power and supply the resultant alternating-current electric power collectively to the interconnection load.

This configuration makes it possible to use individual inverters each having a capacity corresponding to the capacity of each tracking drive solar photovoltaic power generator, thus enabling a tracking solar photovoltaic power generation system to be easily constructed at low cost by applying small-capacity, low-cost individual inverters. In addition, since the photovoltaic panels and the individual inverters are in direct correspondence with one another, it becomes easy to optimize the outputs of the photovoltaic panels and simplify output wiring. This makes the tracking solar photovoltaic power generation system rational and economical.

### EFFECTS OF THE INVENTION

In accordance with the tracking control method for the tracking solar photovoltaic power generation system according to the present invention, the method comprises the first directly-facing turning coordinate detection process for detecting the first directly-facing turning coordinate at which the panel output reaches its maximum value, by moving the turning position of the photovoltaic panel while sequentially changing the turning coordinate in the first turning detection range that is defined in connection with the first turning coordinate corresponding to the solar azimuth angle, and the first directly-facing tilt coordinate detection process for detecting the first directly-facing tilt coordinate at which the panel output reaches its maximum value, by moving the tilt position of the photovoltaic panel while sequentially changing the tilt coordinate in the first tilt detection range that is defined in connection with the first tilt coordinate corresponding to the solar altitude. Therefore, a shift in the position of the turning coordinate (first turning coordinate) relative to the solar azimuth angle is detected with use of the first directly-facing turning coordinate, and a shift in the position of the tilt coordinate (first tilt coordinate) relative to the solar altitude is detected with use of the first directly-facing tilt coordinate.

Correcting together a shift in the position of the turning coordinate (first directly-facing turning coordinate) relative to the solar azimuth angle and a shift in the position of the tilt coordinate θ (first directly-facing tilt coordinate) relative to the solar altitude brings about the effect of enabling easy and high-precision adjustment of the turning position and the tilt position of a photovoltaic panel so that the photovoltaic panel can directly face the solar trajectory (solar azimuth angle and solar altitude).

Moreover, in accordance with the tracking shift correction method for the tracking solar photovoltaic power generation system according to the present invention, each of the tracking drive solar photovoltaic power generators comprises a photovoltaic panel that converts sunlight into direct-current electric power and a driving portion that drives the photovoltaic panel based on tracking information causing the photovoltaic panel to track the solar trajectory, and a configuration is adopted in which a tracking shift of the one of the photovoltaic panels that is targeted for tracking shift correction is detected in a state in which the corresponding tracking drive solar photovoltaic power generator is running while being connected to the power conversion portion. It is thus possible to detect a tracking shift of a photovoltaic panel while connecting the photovoltaic panel to the power conversion portion and to thereby correct a tracking shift of the photovoltaic panel while maintaining the system interconnection by continuing electric power generation by the tracking drive solar photovoltaic power generators and electric power supply from the power conversion portion to the interconnection load. This brings about the effect of providing a highly reliable and productive tracking shift correction method for the tracking solar photovoltaic power generation system, which eliminates the need to stop the tracking solar photovoltaic power generation system associated with tracking shift correction and causes no loss in the amount of generated electric power.

Moreover, in accordance with the tracking solar photovoltaic power generation system according to the present invention, the system comprises a plurality of tracking drive solar photovoltaic power generators that are arranged in parallel connection, and a power conversion portion that converts direct-current electric power generated by the tracking drive solar photovoltaic power generators into alternating-current electric power and supplies the alternating-current electric power to an interconnection load, wherein each of the tracking drive solar photovoltaic power generator comprises a photovoltaic panel that converts sunlight into direct-current electric power and a driving portion that drives the photovoltaic panel based on tracking information causing the photovoltaic panel to track the solar trajectory, and a tracking shift of the one of the photovoltaic panels that is targeted for tracking shift correction is detected in a state in which the corresponding tracking drive solar photovoltaic power generator is running by being connected to the power conversion portion. This configuration makes it possible to detect a tracking shift of a photovoltaic panel in a state in which the corresponding tracking drive solar photovoltaic power generator is running by being connected to the power conversion portion, thus providing a highly reliable and productive tracking solar photovoltaic power generation system that eliminates the need to be stopped associated with tracking shift correction and causes no loss in the amount of generated electric power.

### BRIEF DESCRIPTION OF DRAWINGS

FIG. 1 is a block diagram illustrating a schematic configuration of a tracking drive solar photovoltaic power generator during operation, according to Embodiment 1 of the present invention.

FIG. 2 is a block diagram illustrating a schematic configuration of a tracking solar photovoltaic power generation system when performing a tracking control method, according to Embodiment 1 of the present invention.

FIG. 3 is a block diagram illustrating a schematic configuration of a personal computer applied to perform the tracking control method for the tracking solar photovoltaic power generation system according to Embodiment 1 of the present invention.

FIG. 4 is a flowchart showing the procedure performed according to a first operation pattern when detecting and correcting a shift in the position of a tracking drive solar photovoltaic power generator according to Embodiment 2 of the present invention.

FIG. 5A is a reference chart containing detailed information about the transition of control coordinates according to the first operation pattern shown in FIG. 4.

FIG. 5B is an explanatory chart containing footnotes to FIG. 5A.

FIG. 6 is a coordinate diagram plotting the transition of the control coordinates according to the first operation pattern shown in FIG. 4.

FIG. 7 is a flowchart showing the procedure performed according to a second operation pattern when detecting and correcting a shift in the position of a tracking drive solar photovoltaic power generator according to Embodiment 3 of the present invention.

FIG. 8A is a reference chart containing detailed information about the transition of the control coordinates according to the second operation pattern shown in FIG. 7.

FIG. 8B is an explanatory chart containing footnotes to FIG. 8A.

FIG. 9 is a coordinate diagram plotting the transition of the control coordinates according to the second operation pattern shown in FIG. 7.

FIG. 10 is a flowchart showing the procedure performed according to a third operation pattern when detecting and correcting a shift in the position of a tracking drive solar photovoltaic power generator according to Embodiment 4 of the present invention.

FIG. 11A is a reference chart containing detailed information about the transition of the control coordinates according to the third operation pattern shown in FIG. 10.

FIG. 11B is an explanatory chart containing footnotes to FIG. 11A.

FIG. 12 is a coordinate diagram plotting the transition of the control coordinates according to the third operation pattern shown in FIG. 10.

FIG. 13 shows a coordinate graphic illustrating the correlation between a coordinate system applied to a tracking drive solar photovoltaic power generator and control parameters, according to Embodiment 5 of the present invention.

FIG. 14 is a flowchart showing the procedure of computation processing performed based on the coordinate graphic shown in FIG. 13 when correcting a shift in the positions of the control coordinates and driving a photovoltaic panel.

FIG. 15 is a block diagram illustrating a schematic configuration of a tracking solar photovoltaic power generation system during operation, according to Embodiment 6 of the present invention.

FIG. 16 is a block diagram illustrating a schematic configuration of a tracking solar photovoltaic power generation system when performing a tracking control method, according to Embodiment 6 of the present invention.

FIG. 17 is a block diagram illustrating a schematic configuration of a tracking solar photovoltaic power generation system according to Embodiment 7 of the present invention.

FIG. 18 is a block diagram illustrating a schematic configuration of a tracking drive solar photovoltaic power generator constituting the tracking solar photovoltaic power generation system shown in FIG. 17.

FIG. 19 is a characteristic graph showing a VI characteristic curve representative of the output state of a photovoltaic panel in the tracking solar photovoltaic power generation system shown in FIG. 17.

FIG. 20 is a flowchart showing the procedure for correcting a tracking shift in a tracking shift correction method for a tracking solar photovoltaic power generation system, according to Embodiment 8 of the present invention.

FIGS. 21(A) and 21(B) are explanatory drawings for explaining the procedure for detecting a tracking shift in the turning direction in accordance with the flowchart shown in FIG. 20, FIG. 21(A) being a graph showing the relationship between the turning position and the output current, and FIG. 21(B) being a flowchart showing the procedure.

FIGS. 22(A) and 22(B) are explanatory drawings for explaining the procedure for correcting a tracking shift in the tilt direction in accordance with the flowchart shown in FIG. 20, FIG. 22(A) being a graph showing the relationship between the tilt position and the output current, and FIG. 22(B) being a flowchart showing the procedure.

FIG. 23 is a block diagram illustrating a schematic configuration of a tracking solar photovoltaic power generation system according to Embodiment 10 of the present invention.

FIGS. 24(A) to 24(C) are graphs showing VI characteristic curves of a photovoltaic panel in a tracking solar photovoltaic power generation system according to Embodiment 11 of the present invention, FIG. 24(A) showing normal characteristics of a photovoltaic panel that is not targeted for correction, FIG. 24(B) showing normal characteristics of a photovoltaic panel that is targeted for correction, and FIG. 24(C) showing combined characteristics of the photovoltaic panel that is not targeted for correction and the photovoltaic panel that is targeted for correction.

FIGS. 25(A) to 25(C) are graphs showing VI characteristic curves of a photovoltaic panel in the tracking solar photovoltaic power generation system under MPPT control, according to Embodiment 11 of the present invention, FIG. 25(A) showing normal characteristics of a photovoltaic panel that is not targeted for correction, FIG. 25(B) showing characteristics in a state in which a tracking position is moved in order to detect a shift in the position of a photovoltaic panel that is targeted for correction, and FIG. 25(C) showing combined characteristics of the photovoltaic panel that is not targeted for correction and a photovoltaic panel that is targeted for correction.

FIGS. 26(A) to 26(C) are graphs showing VI characteristic curves of a photovoltaic panel in the tracking solar photovoltaic power generation system under constant voltage control, according to Embodiment 11 of the present invention, FIG. 26(A) showing normal characteristics of a photovoltaic panel that is not targeted for correction, FIG. 26(B) showing characteristics in a state in which the tracking position is moved in order to detect a shift in the position of a photovoltaic panel that is targeted for correction, and FIG. 26(C) showing combined characteristics of the photovoltaic panel that is not targeted for correction and the photovoltaic panel that is targeted for correction.

FIG. 27 is a perspective view illustrating an overview of a conventional tracking drive solar photovoltaic power generator.

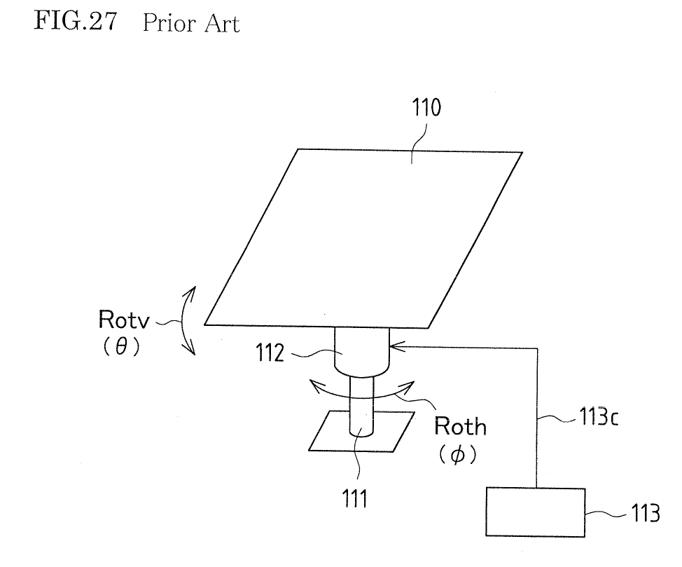

### MODE FOR CARRYING OUT THE INVENTION

Hereinafter, a tracking solar photovoltaic power generation system and a tracking control method and a tracking shift correction method for the tracking solar photovoltaic power generation system according to embodiments of the present invention will be described in orderly sequence with reference to the drawings.

### Tracking Control Method for Tracking Solar Photovoltaic Power Generation System

### Embodiment 1

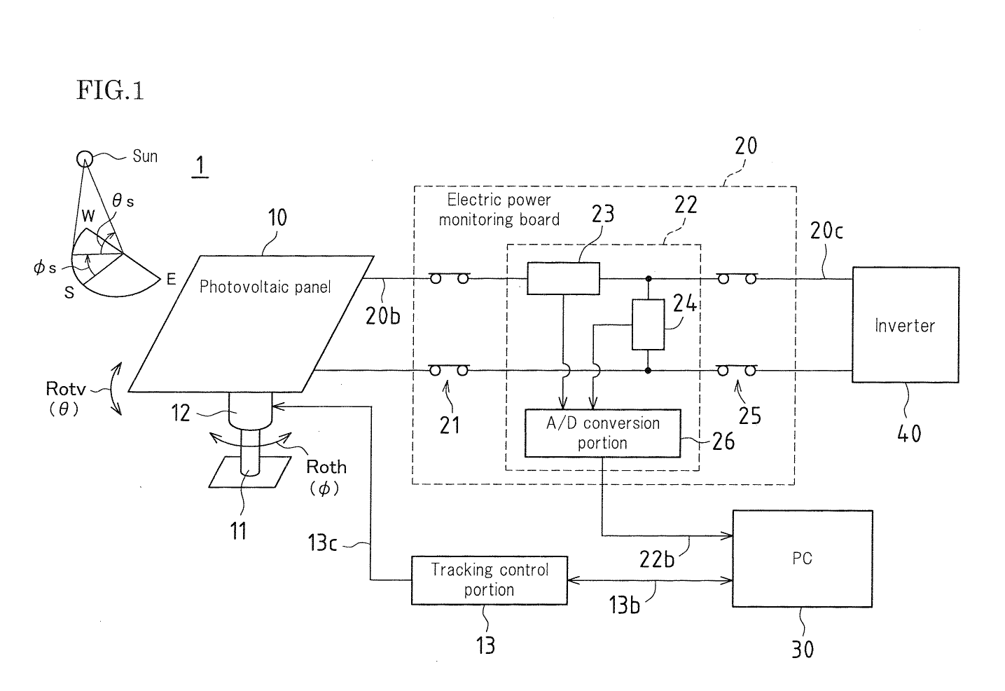

First is a description of a tracking control method for a tracking solar photovoltaic power generation system according to Embodiment 1, given with reference to FIGS. 1 to 3.

FIG. 1 is a block diagram illustrating a schematic configuration of the tracking solar photovoltaic power generation system according to Embodiment 1.

In the tracking control method for the tracking solar photovoltaic power generation system according to the present embodiment, a tracking drive solar photovoltaic power generator 1 includes a photovoltaic panel 10 that converts sunlight into electric power, and a tracking control portion 13 that provides tracking control over the turning position and tilt position of the photovoltaic panel 10 so that the photovoltaic panel 10 can track the solar trajectory based on a turning coordinate φ (turning direction Roth) and a tilt coordinate θ (tilt direction Rotv) that have been set corresponding to a solar azimuth angle φs and a solar altitude θs.

Also, the photovoltaic panel 10 is held by a column 11, and its turning direction Roth (turning coordinate φ) and tilt direction Rotv (tilt coordinate θ) are controlled by a driving portion 12 provided on the top of the column 11. The driving portion 12 includes a turning drive portion (not shown) and a tilt drive portion (not shown) and is capable of tracking the solar trajectory based on the turning coordinate φ (turning direction Roth) and the tilt coordinate θ (tilt direction Rotv) transmitted from the tracking control portion 13 via a control line 13c.

The tracking control portion 13 supplies the turning coordinate φ (turning direction Roth) and the tilt coordinate θ (tilt direction Rotv) to the driving portion 12 in accordance with data supplied from a personal computer (PC) 30 via a communication line 13b. In other words, the PC 30 is configured to hold data about solar coordinates (solar azimuth angle φs and solar altitude θs) and generate control coordinates (turning coordinate φ and tilt coordinate θ) corresponding to the solar coordinates.

Electric power generated on the photovoltaic panel 10 is input to an electric power monitoring board 20 via an electric power line 20b and is output from the electric power monitoring board 20 via an electric power line 20c to an inverter 40 as a load. The electric power monitoring board 20 includes a switch 21 that is installed in the middle of the electric power line 20b and used to control the closing and opening of connection to the photovoltaic panel 10, a detection circuit 22 that detects the condition of generated electric power, and an output side circuit breaker 25 that is installed in the middle of the electric power line 20c and is used to control the closing and opening of connection to the inverter 40.

The detection circuit 22 includes a current detecting resistor 23 for detecting the magnitude of generated electric power by current and a voltage detection resistor 24 for detecting the magnitude of generated electric power by voltage. The current (analog value) detected by the current detecting resistor 23 and the voltage (analog value) detected by the voltage detection resistor 24 are transmitted to an A/D conversion portion 26 in which analog-to-digital conversion is performed, and are converted into digital values in a form that can be handled by the PC 30.

Such current data and voltage data converted into digital values are transmitted to the PC 30 via a detection line 22b, so that the PC 30 can monitor the status of generation of electric power. In other words, the PC 30 is configured to perform operation management during operation. For example, a configuration is also possible in which, in the event of a data error (power generation malfunction) during monitoring, a warning is output according to a pre-installed computer program.

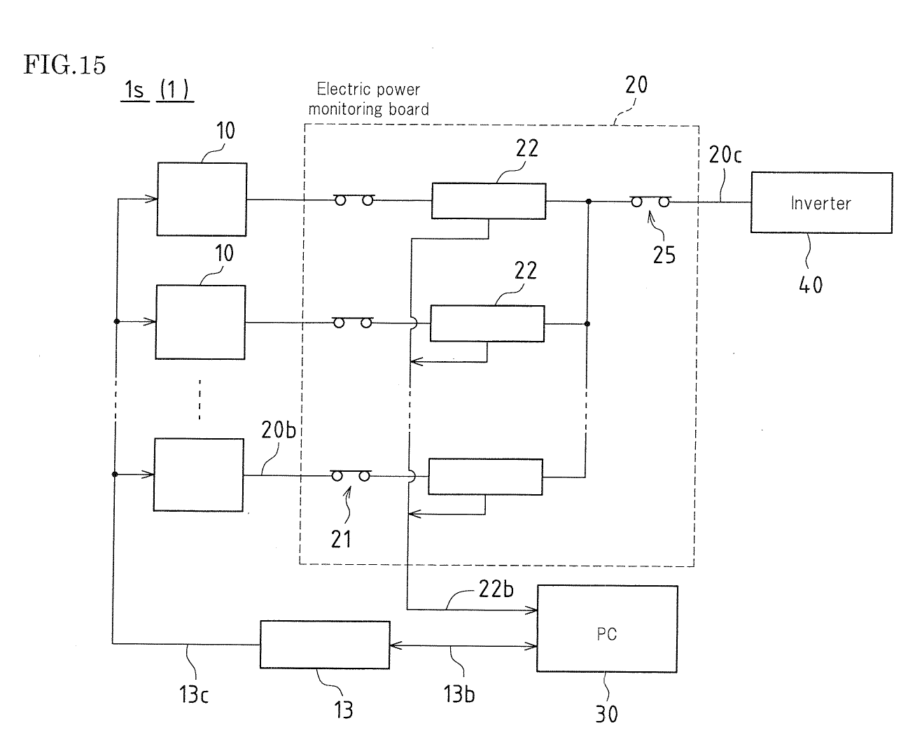

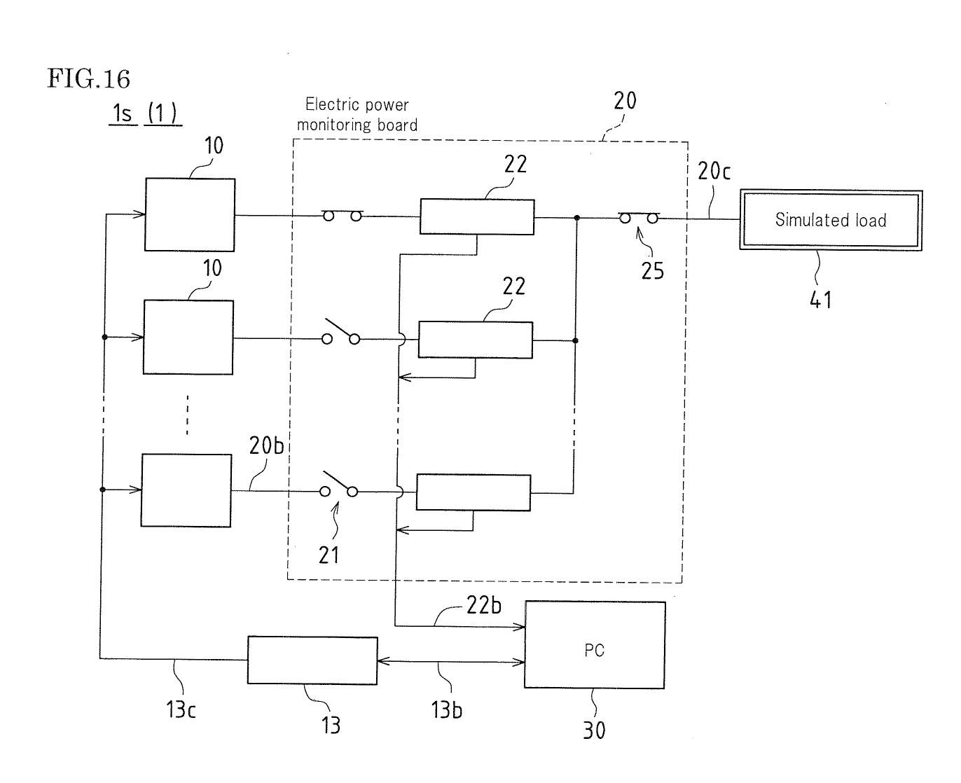

It should be noted that, although the present embodiment will be described with the case where a single electric power monitoring board 20 is arranged for a single photovoltaic panel 10, the electric power monitoring board 20 may be configured with multiple photovoltaic panels 10 being connected thereto (see FIGS. 15 and 16).

Alternatively, in the case where a single or several photovoltaic panels 10 are operated by being directly connected to the inverter 40, a configuration is also possible in which the detection circuit 22 is connected individually to each of the photovoltaic panels 10 so that the photovoltaic panels 10 can operate without applying the electric power monitoring board 20.

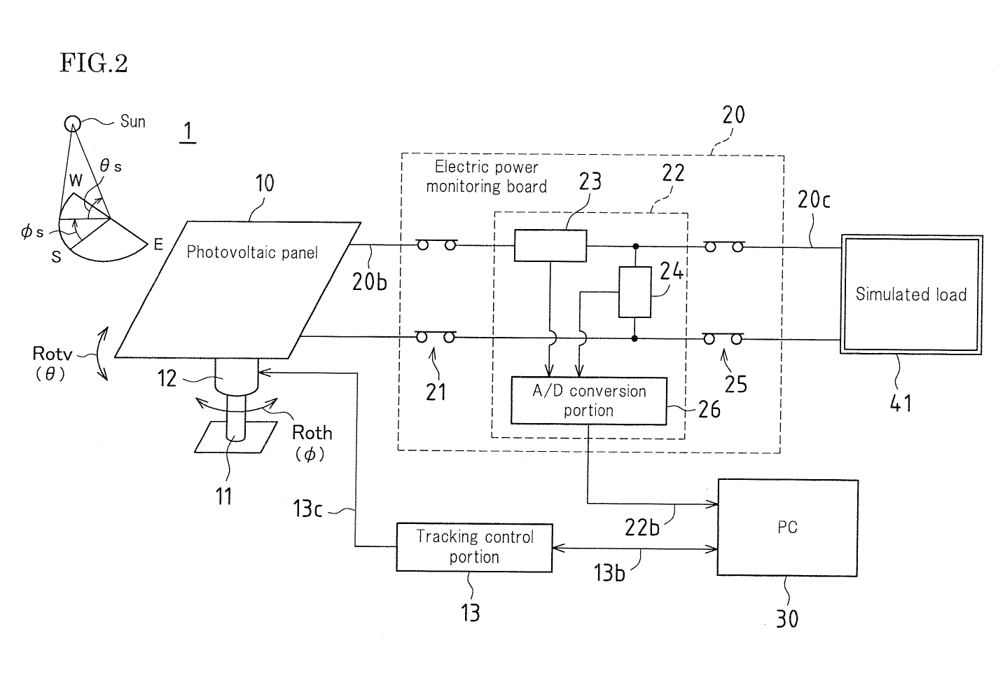

FIG. 2 is a block diagram illustrating a schematic configuration of the tracking drive solar photovoltaic power generator 1 when performing the tracking control method, according to Embodiment 1 of the present invention.

FIG. 2 illustrates a connection state of constituent blocks in the case where a shift in the position of the turning coordinate φ relative to the solar azimuth angle φs and a shift in the position of the tilt coordinate θ relative to the solar altitude θs are detected and corrected. The basic configuration is similar to that during operation shown in FIG. 1, and therefore descriptions are primarily given regarding different points.

In the tracking control method (detection and correction of shifts in positions) for the tracking drive solar photovoltaic power generator 1 according to the present embodiment, a simulated load 41 is connected instead of the inverter 40. The simulated load 41 can provide stable load conditions if constituted as, for example, a resistor, and therefore it is possible to stably detect and correct a shift in position.

The switching between the inverter 40 and the simulated load 41 can be performed safely in a state in which the supply of electric power from the photovoltaic panel is eliminated with both the switch 21 and the output side circuit breaker 25 being set to an open state (OFF). It should be noted that, although the switching between the open (OFF) and closed (ON) states of the switch 21 and the output side circuit breaker 25 can be performed by transmitting instructions from the PC 30 to the switch 21 and the output side circuit breaker 25 via control lines (not shown), the switching may be performed manually.

Moreover, it is also possible to install an operation program (computer program used in the operating state in FIG. 1) and a correction program (computer program used in the correction state in FIG. 2) together on the PC 30. Accordingly, the same apparatus can be applied as the PC 30 used during operation and the PC 30 used during correction.

It should be noted that it is also possible, instead of applying the same apparatus, to apply different PCs for operation and correction. Also, the connection of the tracking control portion 13 and the A/D conversion portion 26 to the PC 30 can be established by appropriate switching using, for example, a USB terminal, and therefore detailed descriptions thereof have been omitted.

In the connection state in FIG. 2, a computer program for detecting a shift in position and a computer program for correcting a shift in position based on the detected shift in position are executed. It should be noted that a configuration is possible in which those computer programs are pre-installed on the PC 30 and their menus are displayed on the display screen of the PC 30 so that the computer programs can be executed by selecting a corresponding instruction button from the menus (menu buttons).

A configuration is also possible in which the PC 30 is defined as a dedicated device and equipped with special-purpose operation buttons corresponding to instructions.

The contents of the tracking control method (detection and correction of a shift in position) performed by the tracking drive solar photovoltaic power generator 1 in the connection state shown in FIG. 2 will be described in detail in Embodiment 2.

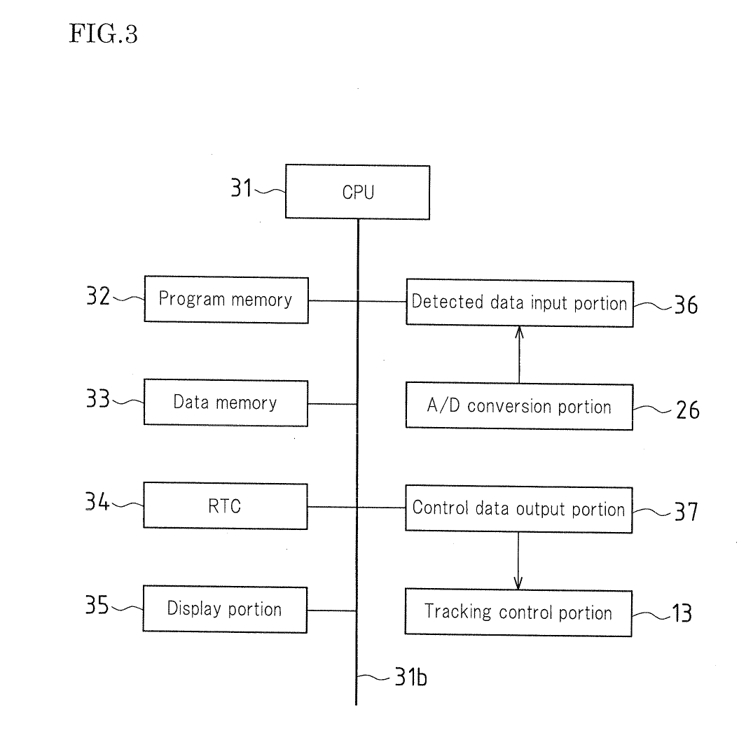

FIG. 3 is a block diagram illustrating a schematic configuration of the PC applied to perform the tracking control method for the tracking solar photovoltaic power generation system according to Embodiment 1.

The PC 30 applied to the tracking drive solar photovoltaic power generator 1 according to the present embodiment includes a CPU (central processing unit) 31 that serves as, for example, a controller for executing an instruction selected from the menu and to which a program memory 32, a data memory 33, an RTC (real time clock) 34, a display portion 35, a detected data input portion 36, and a control data output portion 37 are connected via a bus 31b.

The program memory 32 has pre-installed thereon an operation program for performing the tracking control method for operating the tracking drive solar photovoltaic power generator 1, and a positional shift detection/correction program for detecting and correcting a shift in the position of the tracking drive solar photovoltaic power generator 1.

The data memory 33 stores data, such as position information corresponding to the latitude and the longitude, data indicating the solar coordinates (solar azimuth angle φs and solar altitude θs) corresponding to the solar trajectory determined based on the position information and time information, and the amount of a shift in position.

The RTC (real time clock) 34 is an electronic component that generates the current time and day, year, month, and date. Providing time data enables the solar coordinates corresponding to time to be provided with high precision.

The display portion 35 is configured to, for example, display a menu screen and allow selection of operations, such as an operation performed in the operating state in the tracking control method and an operation performed in a state in which a shift in position is detected or corrected in the tracking control method.

The detected data input portion 36 receives inputs of the current data detected by the current detecting resistor 23 and the voltage data detected by the voltage detection resistor 24 as digital data via the A/D conversion portion 26. The CPU 31 is thus capable of determining the control coordinates (turning coordinate φ and tilt coordinate θ) at which the photovoltaic panel can directly face the sun, based on the input current data and voltage data.

The current data and the voltage data can be acquired by, for example, sampling the panel output (current data and voltage data input that are input to the CPU 31) per second, accumulating the sampled data in the data memory 33, and performing computations in the PC 30.

It should be noted that the photovoltaic panel 10 (solar cell) has characteristics that, when the amount of sunlight irradiation varies, the output voltage varies little, but the output current varies greatly. Therefore, in the case where detection is performed by voltage, the coordinates (turning coordinate φ and tilt coordinate θ) at the middle of the duration, during which the measured voltage was, for example, 95% or more of the detected maximum value, may be obtained as detection results. Also, in the case where detection is performed by current, the coordinates (turning coordinate φ and tilt coordinate θ) at, for example, a position corresponding to a maximum value may be obtained as detection results. That is, a configuration is possible in which the voltage data and the current data are detected while limiting the influence of variations in sunlight.

The control data output portion 37 is capable of outputting, to the tracking control portion 13, new control coordinates (turning coordinate φ and tilt coordinate θ) that are obtained through correction based on the difference (shifts in the positions of the control coordinates that produce a shift in the position of the photovoltaic panel 10) between the obtained control coordinates (turning coordinate φ and tilt coordinate θ; e.g., later-described first directly-facing turning coordinate φ1m and first directly-facing tilt coordinate θ1m) at which the photovoltaic panel directly faces the sun, and the solar coordinates (solar azimuth angle φs and solar altitude θs).

### Second Embodiment

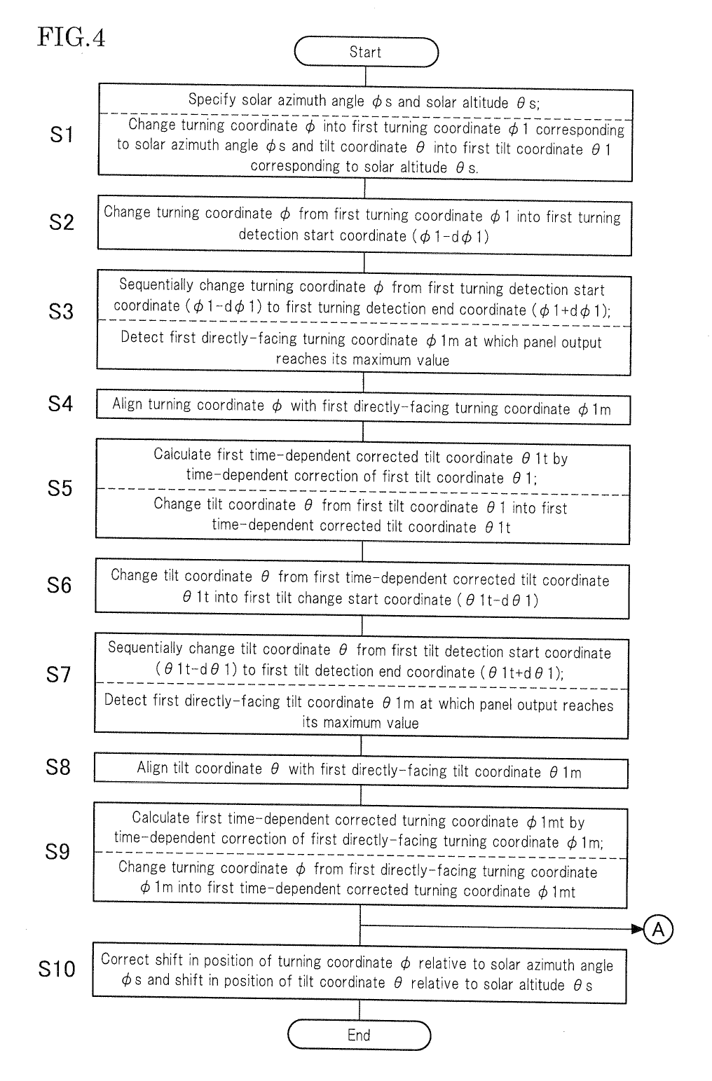

Next is a description of a tracking control method (tracking control method adopting a positional shift detection/correction program) for a tracking solar photovoltaic power generation system according to Embodiment 2 of the present invention, given with reference to FIGS. 4 to 6.

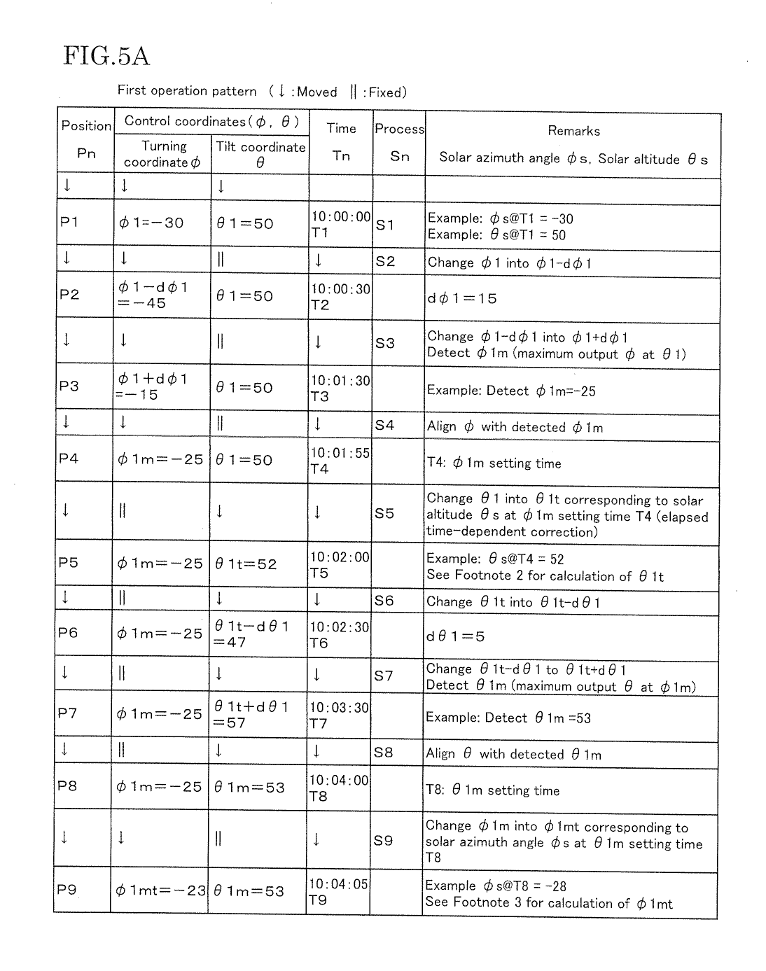

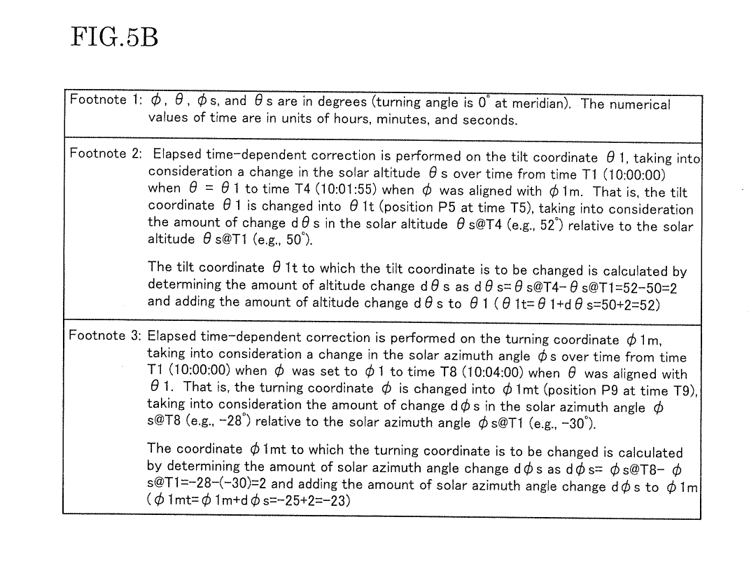

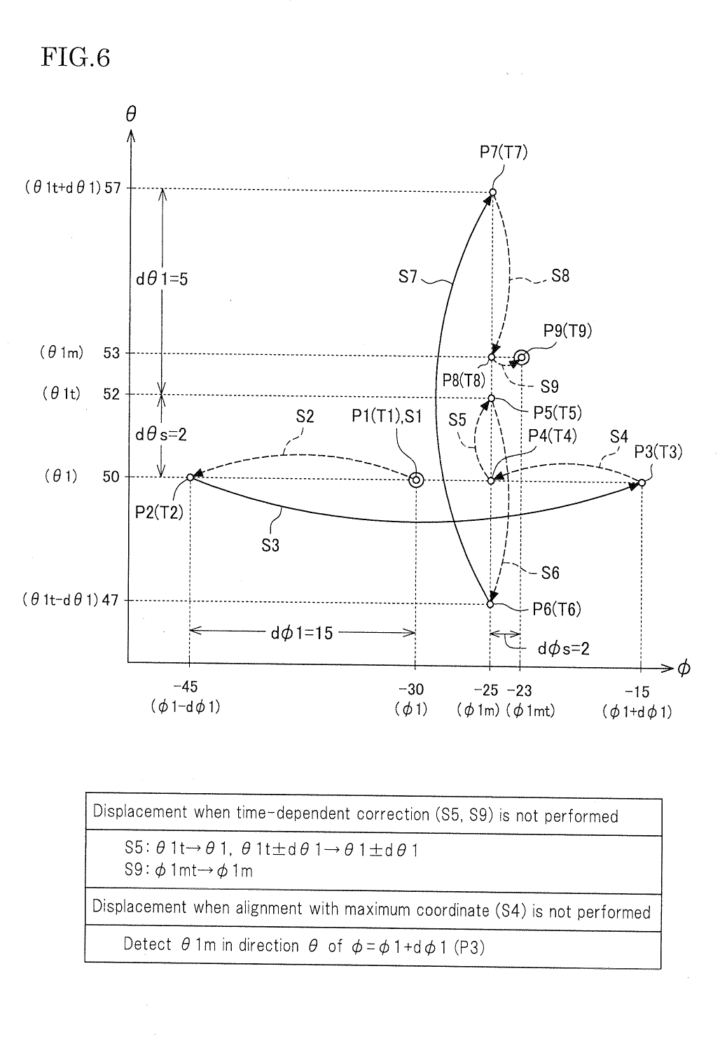

FIG. 4 is a flowchart showing the procedure performed according to a first operation pattern when detecting and correcting a shift in the position of a tracking drive solar photovoltaic power generator in accordance with the tracking control method for the tracking solar photovoltaic power generation system according to Embodiment 2. FIG. 5A is a reference chart containing detailed information about the transition of the control coordinates according to the first operation pattern shown in FIG. 4, and FIG. 5B is an explanatory chart containing footnotes to FIG. 5A. FIG. 6 is a coordinate diagram plotting the transition of the control coordinates according to the first operation pattern shown in FIG. 4.

The tracking control method (tracking control method adopting a positional shift detection/correction program) for the tracking solar photovoltaic power generation system according to Embodiment 2 is performed in accordance with a procedure (first operation pattern) including, for example, steps S1 to S10. It should be noted that the following steps S1 to S10 are performed according to a computer program installed on the PC 30 as described above.

### Step S1 (Process S1):

Solar coordinates (solar azimuth angle φs and solar altitude θs) are specified at time T1 when the tracking control method adopting the positional shift detection/correction program is executed (started).

For example, when the program is started at time T1, e.g., 10:00:00 a.m. (hereinafter, hour, minute, and second are simply indicated in the format of time “10:00:00”), the solar azimuth angle φs@T1 as −30° and the solar altitude θs@T1 as 50°, for example, are specified corresponding to the solar trajectory. It should be noted that the turning coordinate φ and the solar azimuth angle φs are 0° at the meridian (due south).

The values of the solar coordinates are set (applied) as is to the control coordinates (turning coordinate φ and tilt coordinate θ) that are to be set corresponding to the solar coordinates, because it is prior to correction of a shift in position. That is, the turning coordinate φ and the tilt coordinate θ are changed respectively into a first turning coordinate φ1 (φ1=−30°) that corresponds to the solar azimuth angle φs and a first tilt coordinate θ1 (θ1=50°) that corresponds to the solar altitude θs.

Accordingly, the control coordinates are arranged in position P1 at time T1. Meanwhile, the turning position of the photovoltaic panel 10 is moved in accordance with the turning coordinate φ, whereas the tilt position of the photovoltaic panel 10 is moved in accordance with the tilt coordinate θ. That is, the orientation of the photovoltaic panel 10 is controlled by changing the control coordinates.

### Step S2 (Process S2):

With the tilt coordinate θ fixed at the first tilt coordinate θ1 (θ1=50°), the turning coordinate φ is moved from the first turning coordinate φ1 (φ1=−30°) in a negative direction by a first turning displacement angle dφ1 (dφ1=15°) and changed into a the first turning detection start coordinate (φ1−dφ1) (φ1−dφ1=−30−15=−45).

Specifically, the turning coordinate φ is moved from position P1 (first turning coordinate φ1) to position P2 (first turning detection start coordinate (φ1−dφ1)). Here, time T2 when the turning coordinate has moved to position P2 is 10:00:30, for example. The time required for the movement varies depending on the drive speed of the driving portion 12 (drive speed when moving the photovoltaic panel 10), and the drive speed of the driving portion 12 is preset corresponding to the functions required.

### Step S3 (Process S3):

With the first tilt coordinate φ1 (φ1=50°) fixed, the turning coordinate φ is sequentially changed from the first turning detection start coordinate (φ1−dφ1) (φ1−dφ1=−45°) to a first turning detection end coordinate (φ1+dφ1) (φ1+dφ1=−30+15=−15°).

Specifically, the turning coordinate φ is moved from position P2 (first turning detection start coordinate (φ1−dφ1)) to position P3 (first turning detection end coordinate (φ1+dφ1)). Here, time T3 when the turning coordinate has moved to position P3 is 10:01:30, for example.

In this step, a first directly-facing turning coordinate φ1m at which the panel output (the output of the photovoltaic panel 10) transmitted from the A/D conversion portion 26 reaches its maximum value is also detected concurrently with changes in the turning coordinate φ (first directly-facing turning coordinate detection process). For example, it is assumed that the first directly-facing turning coordinate φ1m is detected as −25°.

It should be noted that the maximum value of the panel output can be detected in the form of either voltage or current. In other words, the first directly-facing turning coordinate φ1m at which the panel output reaches its maximum value can be determined by, for example, the turning coordinate φ at which the voltage detected by the voltage detection resistor 24 reaches its maximum value. Alternatively, the turning coordinate φ at which the current detected by the current detecting resistor 23 reaches its maximum value may be used.

In this step, the first directly-facing turning coordinate φ1m at which the panel output reaches its maximum value is detected by moving the turning position of the photovoltaic panel while sequentially changing the turning coordinate φ in a first turning detection range (e.g., (φ1−dφ1) to (φ1+dφ1)) that is defined in connection with the first turning coordinate φ1 corresponding to the solar azimuth angle φs.

It should be noted that the first turning detection range is defined from the first turning detection start coordinate (e.g., (φ1−dφ1), i.e., position P2) to the first turning detection end coordinate (e.g., (φ1+dφ1), i.e., position P3) that are set by using the first turning coordinate φ1 (=−30°) as a first turning detection reference coordinate and applying a predetermined first turning displacement angle dφ1 (=15°) in both positive and negative directions of the first turning detection reference coordinate.

### Step S4 (Process S4):

With the first tilt coordinate θ1 (θ1=50°) fixed, the turning coordinate φ is aligned with the first directly-facing turning coordinate φ1m (φ1m=−25°) at which the panel output reaches its maximum value and that was detected in the first directly-facing turning coordinate detection process S3 (first directly-facing turning coordinate alignment process).

Specifically, the turning coordinate φ is moved from position P3 to position P4 (first directly-facing turning coordinate φ1m). Here, time T4 (first directly-facing turning coordinate setting time) when the turning coordinate φ has moved to position P4 is 10:01:55, for example.

It should be noted that step S5 may also be performed without moving the turning coordinate φ to position P4, i.e., with the turning coordinate φ unchanged (position P3). Specifically, in the case where the turning coordinate φ is not aligned with the coordinate (first directly-facing turning coordinate φ1m) at which the panel output reaches its maximum value, the first directly-facing tilt coordinate θ1m will be detected in the direction of the tilt coordinate θ in position P3, using the turning coordinate φ=φ1+dφ1 (see step S7).

### Step S5 (Process S5):

A first time-dependent corrected tilt coordinate θ1t (θ1t=52°) is calculated by performing time-dependent correction on the first tilt coordinate θ1 (θ1=50°). Then, with the first directly-facing turning coordinate φ1m (φ1m=−25°) fixed, the tilt coordinate θ is changed from the first tilt coordinate θ1 to the first time-dependent corrected tilt coordinate θ1t (first time-dependent tilt correction process).

Specifically, with the turning coordinate φ fixed at the first directly-facing turning coordinate φ1m, the tilt coordinate θ is changed from position P4 to position P5. Here, time T5 when the tilt coordinate θ has moved to position P5 is 10:02:00, for example.

That is, elapsed-time-dependent correction is performed on the first tilt coordinate θ1, taking into consideration a change in the solar altitude θs over time from time T1 (10:00:00) when the tilt coordinate θ has been set to the first tilt coordinate θ1 to time T4 (10:01:55) when the turning coordinate φ has been aligned with φ=φ1m (see Footnote 2 in FIG. 5B).

Accordingly, the tilt coordinate θ1 is changed into the first time-dependent corrected tilt coordinate θ1t (position P5 at time T5), taking into consideration the amount of change dθs in the solar altitude θs@T4 (e.g., 52°) relative to the solar altitude θs@T1 (e.g., 50°). It should be noted that the first time-dependent corrected tilt coordinate θ1t to which the tilt coordinate θ is to be changed is calculated by determining the amount of altitude change dθs as dθs=θs@T4−θs@T1=52−50=2° and adding the amount of altitude change dθs to the first tilt coordinate θ1 (θ1t=θ1+dθs=50+2=52°).

As described above, in this step, before execution of a later-described first directly-facing tilt coordinate detection process S7, the first time-dependent corrected tilt coordinate θ1t is calculated through the time-dependent correction of the first tilt coordinate θ1 that reflects the amount of change dθs (=2°) in the solar altitude θs over time, and a first tilt detection reference coordinate (see step S7) is displaced in advance from the first tilt coordinate θ1 to the first time-dependent corrected tilt coordinate θ1t.

This configuration makes it possible to perform the first directly-facing tilt coordinate detection process S7 by applying the first time-dependent corrected tilt coordinate θ1t that has been calculated with the amount of change dθs in the solar altitude θs over time being reflected in the tilt coordinate θ1, thus enabling the first directly-facing tilt coordinate θ1m to be detected in a short time with high precision.

When the time-dependent correction is performed on the tilt coordinate θ in this step, the first tilt detection reference coordinate is displaced from the first tilt coordinate θ1 (e.g., position P4) to the first time-dependent corrected tilt coordinate θ1t (e.g., position P5), so that the first tilt detection start coordinate is changed from the tilt coordinate (θ1−dθ1) to a tilt coordinate (θ1t−dθ1) (position P6) and the first tilt detection end coordinate is changed from the tilt coordinate (θ1+dθ1) to a tilt coordinate (θ1t+dθ1) (position P7).

In other words, when the time-dependent correction is not performed on the first tilt coordinate θ1 (tilt coordinate θ) in this step, subsequent processing is performed with the first time-dependent corrected tilt coordinate θ1t replaced by the first tilt coordinate θ1 (i.e., using the first tilt coordinate θ1 before changed by the time-dependent correction into the first time-dependent corrected tilt coordinate θ1t).

It should be noted that, in the case of not performing this step (first time-dependent tilt correction process), the first time-dependent corrected tilt coordinate θ1t is not set and therefore the tilt coordinate θ remains unchanged as the first tilt coordinate θ1. Accordingly, the first tilt detection start coordinate is the tilt coordinate (θ1−dθ1), instead of the tilt coordinate (θ1t−dθ1) (position P6), and the first tilt detection end coordinate is the tilt coordinate (θ1+dθ1), instead of the tilt coordinate (θ1t+dθ1) (position P7).

### Step S6 (Process S6):

With the first directly-facing turning coordinate φ1m (φ1m=−25°) fixed, the tilt coordinate θ is moved from the first time-dependent corrected tilt coordinate θ1t (θ1t=52°) in the negative direction by a first tilt displacement angle dθ1 (dθ1=5°) and changed into the first tilt detection start coordinate (θ1t−dθ1))(=52−5=47°).

Specifically, the tilt coordinate θ is moved from position P5 (first time-dependent corrected tilt coordinate θ1t) to position P6 (first tilt detection start coordinate (θ1t−dθ1)). Here, time T6 when the tilt coordinate θ has moved to position P6 is 10:02:30, for example.

### Step S7 (Process S7):

With the first directly-facing turning coordinate φ1m (φ1m=−25°) fixed, the tilt coordinate θ is sequentially changed from the first tilt detection start coordinate (θ1t−dθ1) (=52−5=47°) to the first tilt detection end coordinate (θ1t+dθ1) (=52+5=57°).

Specifically, the tilt coordinate θ is moved from position P6 (first tilt detection start coordinate (θ1t−dθ1)) to position P7 (first tilt detection end coordinate (θ1t+dθ1)). Here, time T7 when the tilt coordinate θ has moved to position P7 is 10:03:30, for example.

In this step, a first directly-facing tilt coordinate θ1m at which the panel output (the output of the photovoltaic panel 10) transmitted from the A/D conversion portion 26 reaches its maximum value is also detected concurrently with changes in the tilt coordinate θ (first directly-facing tilt coordinate detection process). For example, it is assumed that the first directly-facing tilt coordinate θ1m is detected as 53°.

It should be noted that the first directly-facing tilt coordinate θ1m at which the panel output reaches its maximum value can be determined by, for example, the turning coordinate φ at which the voltage detected by the voltage detection resistor 24 reaches its maximum value. Alternatively, it may be determined by the turning coordinate φ at which the current detected by the current detecting resistor 23 reaches its maximum value. The method for detecting voltage or current is similar to that in the case of step S3, and therefore descriptions thereof have been omitted (the same applies for the following descriptions).

In this step, the first directly-facing tilt coordinate θ1m at which the panel output reaches its maximum value is detected by moving the tilt position of the photovoltaic panel while sequentially changing the tilt coordinate θ in a first tilt detection range (e.g., from (θ1t−dθ1) to (θ1t+dθ1)) that is defined in connection with the first tilt coordinate θ1 corresponding to the solar altitude θs.

It should be noted that, when the time-dependent correction (step S5) is not performed on the tilt coordinate θ, processing is performed with the tilt coordinate θ1t replaced by the tilt coordinate θ1 (i.e., using the tilt coordinate θ1 before changed by the time-dependent correction into the first time-dependent corrected tilt coordinate θ1t) as described in step S5. In other words, the first tilt detection range in which the tilt coordinate θ is moved is from a first tilt detection start coordinate (θ1−dθ1) to a first tilt detection end coordinate (θ1+dθ1).

Accordingly, the first tilt detection range is defined from the first tilt detection start coordinate (e.g., position P6 (θ1t−dθ1) or a position (θ1−dθ1) (not shown) corresponding to position P6) to the first tilt detection end coordinate (e.g., position P7 (θ1t+dθ1) or a position (θ1+dθ1) (not shown) corresponding to position P7) by using either the first tilt coordinate θ1 (=50°) or the first time-dependent corrected tilt coordinate θ1t (=52°) obtained through the time-dependent correction of the first tilt coordinate θ1 as a first tilt detection reference coordinate and applying a predetermined first tilt displacement angle dθ1 (=5°) in both positive and negative directions of the first tilt detection reference coordinate. This step (first directly-facing tilt coordinate detection process) is performed after execution of the first directly-facing turning coordinate alignment process S4 in which the turning coordinate φ is aligned with the first directly-facing turning coordinate φ1m detected in the first directly-facing turning coordinate detection process S3.

This configuration makes it possible to detect a shift in the position of the tilt coordinate θ (first tilt coordinate θ1) in a state in which the photovoltaic panel directly faces the solar trajectory in the turning direction, thus enabling precise detection of the first directly-facing tilt coordinate θ1m.

### Step S8 (Process S8):

With the first directly-facing turning coordinate φ1m (φ1m=−25°) fixed, the tilt coordinate θ is aligned with the first directly-facing tilt coordinate θ1m (θ1m=53°) at which the panel output reaches its maximum value and that was detected in the first directly-facing tilt coordinate detection process (first directly-facing tilt coordinate alignment process). Specifically, the tilt coordinate θ is moved from position P7 to position P8 (first directly-facing tilt coordinate θ1m). Here, time T8 (first directly-facing tilt coordinate setting time) when the tilt coordinate θ has moved to position P8 is 10:04:00, for example.

### Step S9 (Process S9):

A first time-dependent corrected turning coordinate φ1mt (φ1mt=−23°) is calculated by performing time-dependent correction on the first directly-facing turning coordinate φ1m (φ1m=−25°). Then, with the first directly-facing tilt coordinate θ1m (θ1m=53°) fixed, the turning coordinate φ is changed from the first directly-facing turning coordinate φ1m into the first time-dependent corrected turning coordinate φ1mt (first time-dependent turning correction process).

Specifically, with the tilt coordinate θ fixed at the first directly-facing tilt coordinate θ1m, the turning coordinate φ is changed and moved from position P8 to position P9. Here, time T9 when the turning coordinate φ has moved to position P9 is 10:04:05, for example.

That is, elapsed-time-dependent correction is performed on the first directly-facing turning coordinate φ1m, taking into consideration a change in the solar azimuth angle φs over time from time T1 (10:00:00) when the turning coordinate φ has been set to the first tilt coordinate φ1 to time T8 (10:04:00) when the tilt coordinate θ has been aligned with the first directly-facing tilt coordinate θ1m (see Footnote 3 in FIG. 5B).

Accordingly, the first directly-facing turning coordinate φ1m is changed into the first time-dependent corrected turning coordinate φ1mt (position P9 at time T9), taking into consideration the amount of change dφs in the solar azimuth angle φs@T8 (e.g., −28°) relative to the solar azimuth angle φs@T1 (e.g., −30°). It should be noted that the first time-dependent corrected turning coordinate φ1mt to which the turning coordinate is to be changed is calculated by determining the amount of solar azimuth angle change dφs as dφs=φs@T8−φs@T1=−28−(−30)=2° and adding the amount of solar azimuth angle change clips to the first directly-facing turning coordinate φ1m (φ1mt=φ1m+dφs=−25+2=−23°).

As described above, in this step, before execution of a later-described second directly-facing turning coordinate detection process S22, the first time-dependent corrected turning coordinate φ1mt is calculated by performing the time-dependent correction of the first directly-facing turning coordinate φ1m that reflects the amount of change dφs (=2°) in the solar azimuth angle φs over time, and a second turning detection reference coordinate (see step S22) is displaced in advance from the first directly-facing turning coordinate φ1m to the first time-dependent corrected turning coordinate φ1mt.

This configuration makes it possible to perform subsequent processing (second operation pattern) by applying the first time-dependent corrected turning coordinate φ1mt that has been calculated with the amount of change dφs in the solar azimuth angle φs over time being reflected in the first directly-facing turning coordinate φ1m, thus enabling the second directly-facing turning coordinate φ2m to be detected in a short time with high precision.

When the time-dependent correction is performed on the turning coordinate φ in this step, the second turning detection reference coordinate is displaced from the first directly-facing turning coordinate φ1m (corresponding to position P8) to the first time-dependent corrected turning coordinate φ1mt (corresponding to position P9), so that a second turning detection start coordinate is changed from the turning coordinate (φ1m−dφ2) to a turning coordinate (φ1mt−dφ2) (position P21) and a second turning detection end coordinate is changed from a turning coordinate (φ1m+dφ2) to a turning coordinate (φ1mt+dφ2) (position P22).

In other words, when the time-dependent correction is not performed on the first directly-facing turning coordinate φ1m (turning coordinate φ) in this step, subsequent processing is performed with the first time-dependent corrected turning coordinate φ1mt replaced by the first directly-facing turning coordinate φ1m (i.e., using the first directly-facing turning coordinate φ1m before changed by the time-dependent correction into the first time-dependent corrected turning coordinate φ1mt).

It should be noted that, when this step (first time-dependent turning correction process) is not performed, the first time-dependent corrected turning coordinate φ1mt is not set and therefore the turning coordinate φ remains unchanged as the first directly-facing turning coordinate φ1m. Accordingly, the second turning detection start coordinate is the turning coordinate (φ1m−dφ2), instead of the turning coordinate (φ1mt−dφ2) (position P21), and the second turning detection end coordinate is the turning coordinate (φ1m+dφ2), instead of the turning coordinate (φ1mt+dφ2) (position P22).

It is possible through the steps S1 to S9 described above to detect the first directly-facing turning coordinate φ1m and the first directly-facing tilt coordinate θ1m and associate the turning coordinate φ and the tilt coordinate θ respectively with the first directly-facing turning coordinate φ1m and the first directly-facing tilt coordinate θ1m. After step S9, if the detection of a shift in position is ended and the system is to be placed in the operating state, the processing proceeds to step S10.

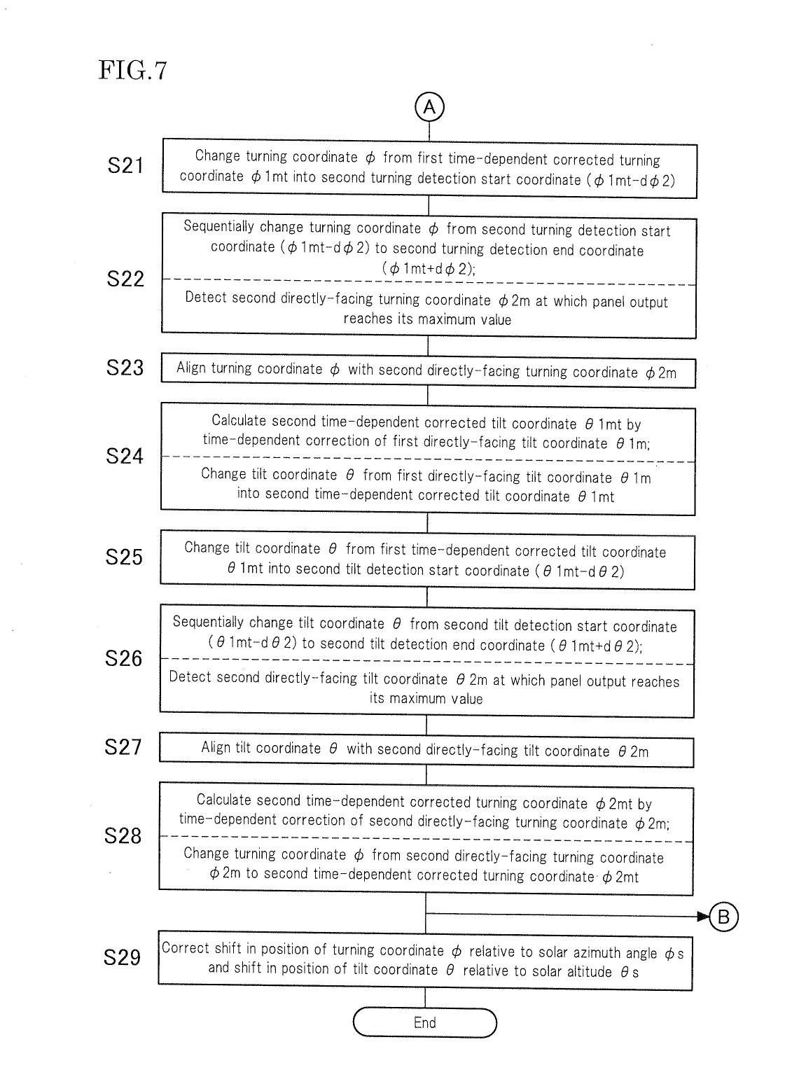

In the case of detecting a shift in position with higher precision, on the other hand, the processing proceeds to a procedure including steps S21 to S29 (see a second operation pattern in FIGS. 7 to 9). Such a mode of performing the second operation pattern following the first operation pattern can be implemented as appropriate by a menu selection method.

### Step S10 (Process S10):

The photovoltaic panel 10 is driven after correcting a shift in the position of the turning coordinate φ relative to the solar azimuth angle φs and correcting a shift in the position of the tilt coordinate θ relative to the solar altitude θs (correction and drive process). Since correction is performed based on the first directly-facing turning coordinate φ1m and the first directly-facing tilt coordinate θ1m before driving the photovoltaic panel 10, it is possible to correct the shifts in positions with ease and high precision before driving the photovoltaic panel 10.

Note that a specific computation process will be described in Embodiment 5.

When time-dependent correction is not performed on the first directly-facing turning coordinate φ1m (turning coordinate φ) in step S9, processing is performed with the first time-dependent corrected turning coordinate φ1mt replaced by the first directly-facing turning coordinate φ1m. That is, a shift in the position of the turning coordinate φ is corrected based on a difference between the solar azimuth angle φs at time T8 and the first directly-facing turning coordinate φ1m.

It should be noted that the first operation pattern, if performed during installation or maintenance control, can provide high-precision alignment with the photovoltaic panel 10 with ease and at low cost. In the case where the first operation pattern is applied during installation, installation work can be simplified considerably, which results in a considerable reduction in the cost of the installation process.

A configuration is also possible in which the first operation pattern is performed repeatedly at fixed intervals, not only during installation or maintenance control. In the case where the first operation pattern is performed repeatedly at fixed intervals, it is possible to easily detect the occurrence of abnormalities and accordingly provide higher precision control, thus increasing the reliability of the tracking drive solar photovoltaic power generator 1.

A computer program for executing the first operation pattern (positional shift detection/correction program) may be installed in combination with an operation program in advance. By combining that program with the operation program in advance, a selection menu method that provides interconnection between the operation program and the first operation pattern interconnected becomes available, and therefore it is possible to perform the first operation pattern by simple instructions and to easily place the system in the operating state after the first operation pattern is completed.

According to the present embodiment, the first directly-facing tilt coordinate θ1m is set to position P8 at time T8 (=10:04:05), and the first time-dependent corrected turning coordinate φ1mt is set to position P9 at time T9 (=10:04:05). That is, the control coordinates can be aligned in a very short time to the tilt position and the turning position at which the panel output reaches its maximum value. Accordingly, extremely high-precision alignment can be accomplished in a short time with ease.

Moreover, in the present embodiment, the duration of time from time T1 (10:00:00) in step S1 to time T9 (10:04:05) in step S9 is 4:05. That is, the detection and further correction of a shift in position can be performed in a short time on the order of four minutes.

As described above, the tracking control method (first operation pattern) for the tracking drive solar photovoltaic power generator 1 according to the present embodiment is a tracking control method for the tracking drive solar photovoltaic power generator 1 that includes the photovoltaic panel 10 that converts sunlight into electric power, and the tracking control portion 13 that provides tracking control over the turning and tilt positions of the photovoltaic panel 10 so that the photovoltaic panel can track the solar trajectory based on the turning coordinate φ and the tilt coordinate θ that have been set corresponding to the solar azimuth angle φs and the solar altitude θs.

The tracking control method for the tracking drive solar photovoltaic power generator 1 according to the present embodiment includes the first directly-facing turning coordinate detection process S3 in which the first directly-facing turning coordinate φ1m at which the panel output reaches its maximum value is detected by moving the turning position of the photovoltaic panel while sequentially changing the turning coordinate φ in the first turning detection range (e.g., from (φ1−dφ1) to (φ1+dφ1)) that is defined in connection with the first turning coordinate φ1 corresponding to the solar azimuth angle φs, and the first directly-facing tilt coordinate detection process S7 in which the first directly-facing tilt coordinate θ1m at which the panel output reaches its maximum value is detected by moving the tilt position of the photovoltaic panel while sequentially changing the tilt coordinate θ in the first tilt detection range (e.g., from (θ1t−dθ1) to (θ1t+dθ1)) that is defined in connection with the first tilt coordinate θ1 corresponding to the solar altitude θs.

This configuration makes it possible to detect a shift in the position of the turning coordinate φ (first turning coordinate φ1) relative to the solar azimuth angle φs with use of the first directly-facing turning coordinate φ1m and a shift in the position of the tilt coordinate θ (first tilt coordinate θ1) relative to the solar altitude θs with use of the first directly-facing tilt coordinate θ1m and to thereby correct a shift in the position of the turning coordinate φ (first directly-facing turning coordinate φ1m) relative to the solar azimuth angle φs and a shift in the position of the tilt coordinate θ (first directly-facing tilt coordinate θ1m) relative to the solar altitude θs, thus enabling the turning position and the tilt position of the photovoltaic panel 10 to be adjusted with ease and high precision so that the photovoltaic panel directly faces the solar trajectory (solar azimuth angle φs and solar altitude θs).

In the tracking control method for the tracking drive solar photovoltaic power generator 1 according to the present embodiment, the first turning detection range is defined from the first turning detection start coordinate (e.g., position P2 (φ1−dφ1)) to the first turning detection end coordinate (e.g., position P3 (φ1+dφ1)) by using the first turning coordinate φ1 (=−30°) as a first turning detection reference coordinate and applying a predetermined first turning displacement angle dφ1 (=15°) in both positive and negative directions of the first turning detection reference coordinate. Also, the first tilt detection range is defined from the first tilt detection start coordinate (e.g., position P6 (θ1t−dθ1) or a position (θ1−dθ1) (not shown) corresponding to position P6) to the first tilt detection end coordinate (e.g., position P7 (θ1t+dθ1) or a position (θ1+dθ1) (not shown) corresponding to position P7) by using either the first tilt coordinate θ1 (=50°) or the first time-dependent corrected tilt coordinate θ1t (=52°) obtained through the time-dependent correction of the first tilt coordinate θ1 as a first tilt detection reference coordinate and applying a predetermined first tilt displacement angle dθ1 (=5°) in both positive and negative directions of the first tilt detection reference coordinate.

This configuration makes it possible to define the first turning detection range (=30°) and the first tilt detection range (=10°) with ease and high precision, thus enabling the first directly-facing turning coordinate φ1m and the first directly-facing tilt coordinate θ1m to be detected with ease and high precision.

In addition, it is possible in the first operation pattern to set the first turning displacement angle φ1 and the first tilt displacement angle θ1 to relatively large angles, such as ±15° and ±5° respectively, and it is sufficient that the accuracy in installing the photovoltaic panel 10 via the column 11 and the driving portion 12 is to such an extent as to allow detection of the first directly-facing turning coordinate φ1m in the first turning detection range defined by the first turning displacement angle φ1 and detection of the first directly-facing tilt coordinate θ1m in the first tilt detection range defined by the first tilt displacement angle θ1. It is thus possible to significantly reduce time and manpower required for installation work. In other words, even if alignment accuracy is low during installation, high-precision alignment can be achieved, which significantly simplifies installation work and significantly reduces installation cost.

In the tracking control method for the tracking drive solar photovoltaic power generator 1 according to the present embodiment, the first directly-facing tilt coordinate detection process S7 is performed after execution of the first directly-facing turning coordinate alignment process S4 in which the turning coordinate φ is aligned with the first directly-facing turning coordinate φ1m detected in the first directly-facing turning coordinate detection process S3.

This configuration makes it possible to detect a shift in the position of the tilt coordinate θ (first tilt coordinate θ1) in a state in which the photovoltaic panel 10 directly faces the solar trajectory in the turning direction, thus enabling precise detection of the first directly-facing tilt coordinate θ1m.

In the tracking control method for the tracking drive solar photovoltaic power generator 1 according to the present embodiment, before execution of the first directly-facing tilt coordinate detection process S7, the first time-dependent corrected tilt coordinate θ1t is calculated through the time-dependent correction of the first tilt coordinate θ1 that reflects the amount of change dθs in the solar altitude θs over time (=2°), and the first tilt detection reference coordinate is displaced in advance from the first tilt coordinate θ1 to the first time-dependent corrected tilt coordinate θ1t (first time-dependent tilt correction process S5).

This configuration makes it possible to perform the first directly-facing tilt coordinate detection process S7 by applying the first time-dependent corrected tilt coordinate θ1t that has been calculated with the amount of change dθs in the solar altitude θs over time being reflected in the tilt coordinate θ1, thus enabling the first directly-facing tilt coordinate θ1m to be detected in a short time with high precision.

The tracking control method for the tracking drive solar photovoltaic power generator 1 according to the present embodiment includes the correction and drive process S10 in which the photovoltaic panel 10 is driven after correcting a shift in the position of the turning coordinate φ relative to the solar azimuth angle φs and correcting a shift in the position of the tilt coordinate θ relative to the solar altitude θs. Since the correction is performed based on the first directly-facing turning coordinate φ1m and the first directly-facing tilt coordinate θ1m before driving the photovoltaic panel 10, it is possible to correct the shifts in positions with ease and high precision before driving the photovoltaic panel 10.

In the tracking control method for the tracking drive solar photovoltaic power generator 1 according to the present embodiment, a configuration may be adopted in which voltage is used to detect the panel output in the first directly-facing turning coordinate detection process S3 and the first directly-facing tilt coordinate detection process S7. Accordingly, even if a tracking shift is relatively large, the panel output can be detected easily with a simple structure.

In the tracking control method for the tracking drive solar photovoltaic power generator 1 according to the present embodiment, a configuration may be adopted in which current is used to detect the panel output in the first directly-facing turning coordinate detection process S3 and the first directly-facing tilt coordinate detection process S7. Accordingly, the panel output can be detected with high precision with a simple structure.

### Third Embodiment

Next is a description of a tracking control method for a tracking solar photovoltaic power generation system (tracking control method adopting a positional shift detection/correction program) according to Embodiment 3 of the present invention, given with reference to FIGS. 7 to 9.

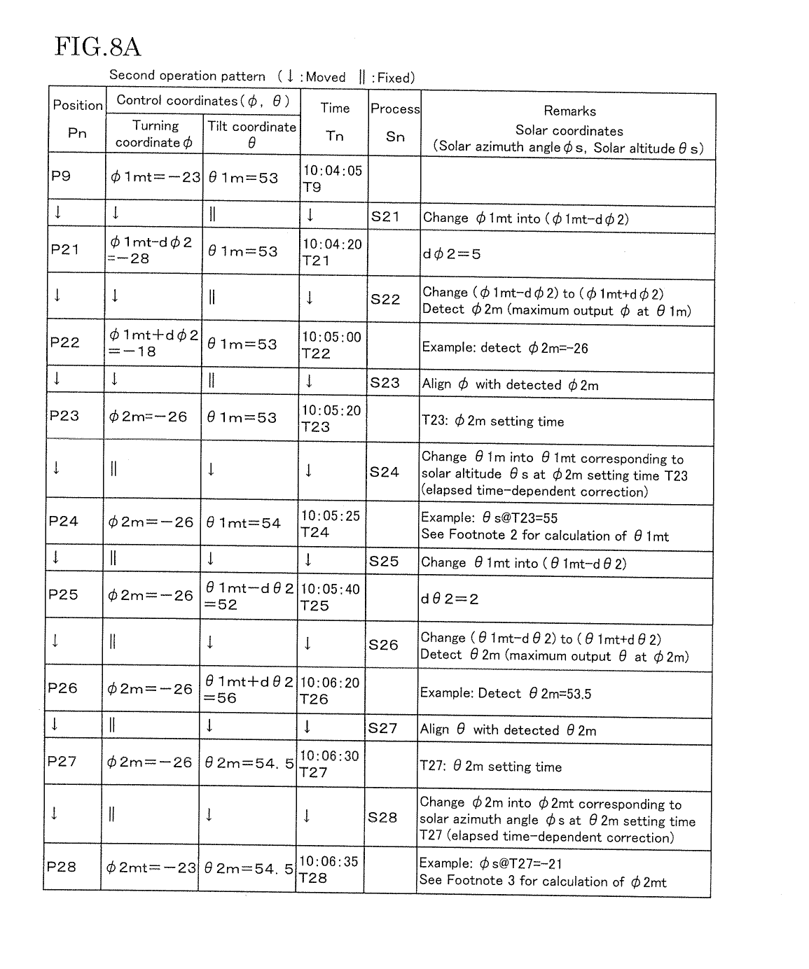

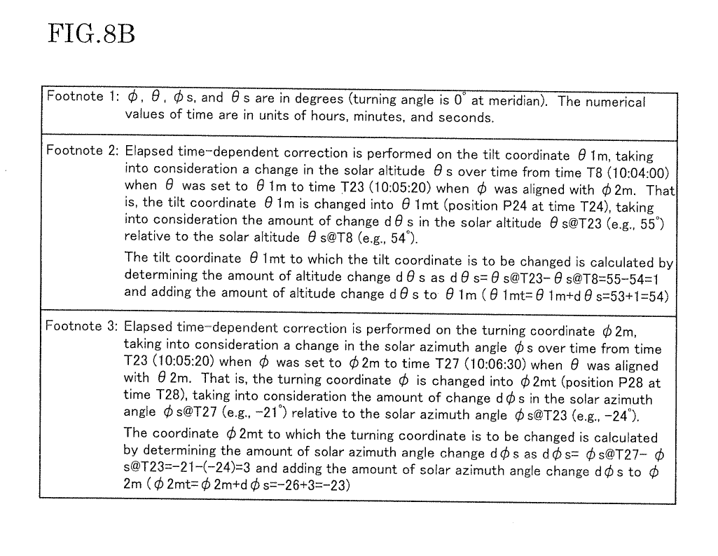

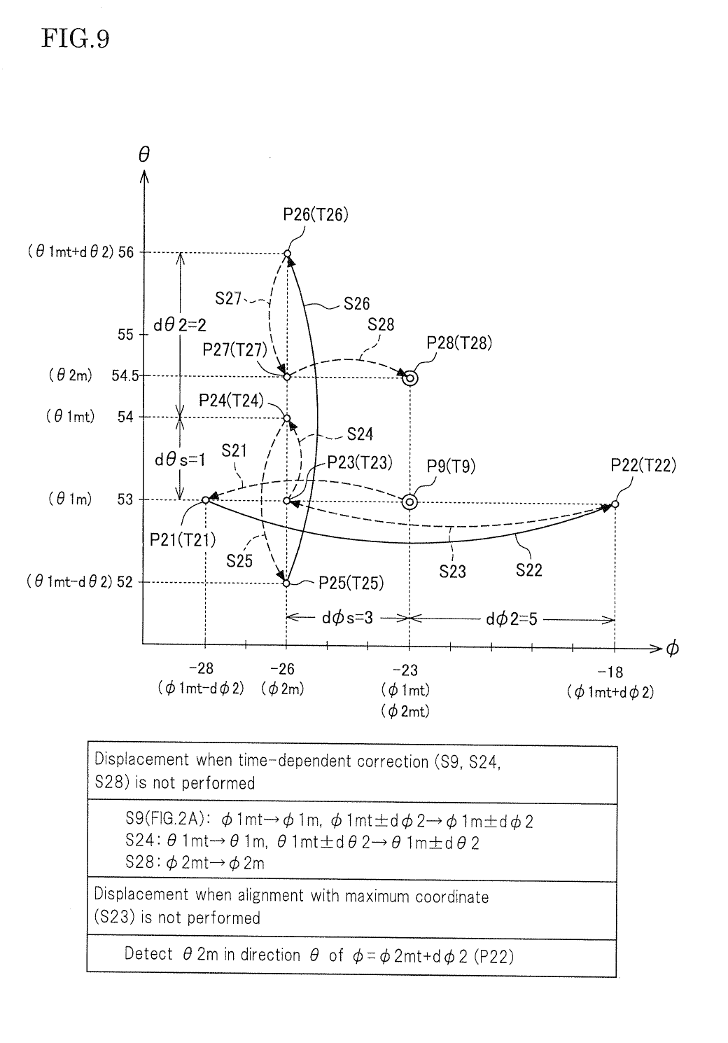

FIG. 7 is a flowchart showing the procedure performed according to the second operation pattern when detecting and correcting a shift in the position of a tracking drive solar photovoltaic power generator in accordance with the tracking control method for the tracking solar photovoltaic power generation system according to Embodiment 3. FIG. 8A is a reference chart containing detailed information about the transition of the control coordinates according to the second operation pattern shown in FIG. 7, and FIG. 8B is an explanatory chart containing footnotes to FIG. 8A. FIG. 9 is a coordinate diagram plotting the transition of the control coordinates according to the second operation pattern shown in FIG. 7.

The tracking control method for the tracking solar photovoltaic power generation system (tracking control method adopting a positional shift detection/correction program) according to the present embodiment is configured to be implemented, for example according to a procedure including steps S21 to S29 (second operation pattern). Note that the following steps S21 to S29 are executed in accordance with a computer program installed on the PC 30 as described above.

It should be noted that the second operation pattern is performed following step S9 (position P9 at time T9) in the first operation pattern of Embodiment 2. Such a form of performing the second operation pattern following the first operation pattern can be implemented as appropriate by a menu selection method. Furthermore, the basic configuration as well as the functions and effects of the second operation pattern are similar to those of the first operation pattern, and therefore descriptions are primarily given regarding different points.

### Step S21 (Process S21):

With the first directly-facing tilt coordinate θ1m (θ1m=53°) fixed, the turning coordinate φ is moved from the first time-dependent corrected turning coordinate φ1mt (φ1mt=−23°) in the negative direction by a second turning displacement angle dφ2 (dφ2=5°) and changed into a second turning detection start coordinate (φ1mt−dφ2) (φ1mt−dφ2=−23−5=−28°).

Specifically, the turning coordinate φ is moved from position P9 (first time-dependent corrected turning coordinate φ1mt) to position P21 (second turning detection start coordinate (φ1mt−dφ2)). Here, time T21 when the turning coordinate φ has moved to position P21 is 10:04:20, for example.

### Step S22 (Process S22):

With the first directly-facing tilt coordinate θ1m (θ1m=53°) fixed, the turning coordinate φ is sequentially changed from the second turning detection start coordinate (φ1mt−dφ2) (φ1mt−dφ2=−28°) to a second turning detection end coordinate (φ1mt+dφ2) (φ1mt+dφ2=−23+5=−18°).

Specifically, the turning coordinate φ is moved from position P21 (second turning detection start coordinate (φ1mt−dφ2)) to position P22 (second turning detection end coordinate (φ1mt+dφ2)). Here, time T22 when the turning coordinate φ has moved to position P22 is 10:05:00, for example.

In this step, a second directly-facing turning coordinate φ2m at which the panel output (the output of the photovoltaic panel 10) transmitted from the A/D conversion portion 26 reaches its maximum value is also detected concurrently (second directly-facing turning coordinate detection process).

For example, it is assumed that the second directly-facing turning coordinate φ2m is detected as −26°. It should be noted that the second directly-facing turning coordinate φ2m at which the panel output reaches its maximum value can be determined by, for example, the turning coordinate φ at which the current detected by the current detecting resistor 23 reaches its maximum value. Since the turning coordinate φ is obtained at a maximum value of current that is sensitive to a shift in the position of the photovoltaic panel 10 relative to sunlight, the turning coordinate φ can be determined with high precision.

Specifically, in this step, the second directly-facing turning coordinate φ2m at which the panel output reaches its maximum value is detected by moving the turning position of the photovoltaic panel while sequentially changing the turning coordinate φ in a second turning detection range (e.g., from (φ1mt−dφ2) to (φ1mt+dφ2)) that is defined in connection with the first directly-facing turning coordinate φ1m.

It should be noted that the second turning detection range is defined from the second turning detection start coordinate (e.g., position P21 (φ1mt−dφ2) or a position (φ1m−dφ2) (not shown) corresponding to position P21) to the second turning detection end coordinate (e.g., position P22 (φ1mt+dφ2) or a position (φ1m+dφ2) (not shown) corresponding to position P22) by using either the first directly-facing turning coordinate φ1m (=−25°) or the first time-dependent corrected turning coordinate φ1mt (=−23°) obtained through the time-dependent correction of the first directly-facing turning coordinate φ1m as a second turning detection reference coordinate and applying a predetermined second turning displacement angle dφ2 (=5°) that is smaller than the first turning displacement angle dφ1 (=15°), in both positive and negative directions of the second turning detection reference coordinate.

When time-dependent correction is not performed on the first directly-facing turning coordinate φ1m (turning coordinate φ) in step S9, processing is performed with the first time-dependent corrected turning coordinate φ1mt replaced by the first directly-facing turning coordinate φ1m as described above.

### Step S23 (Process S23):

With the second directly-facing tilt coordinate θ2m (θ1m=53°) fixed, the turning coordinate φ is aligned with the second directly-facing turning coordinate φ2m (φ2m=−26°) detected in the second directly-facing turning coordinate detection process S22 (second directly-facing turning coordinate alignment process).

Specifically, the turning coordinate φ is moved from position P22 to position P23 (second directly-facing turning coordinate φ2m). Here, time T23 (second directly-facing turning coordinate setting time) when the turning coordinate φ has moved to position P23 is 10:05:20, for example.

It should be noted that step S24 may be performed without moving the turning coordinate φ to position P23, i.e., with the turning coordinate φ unchanged (position P22). In other words, when the turning coordinate φ is not aligned with the coordinate (second directly-facing turning coordinate φ2m) at which the panel output reaches its maximum value, a second directly-facing tilt coordinate θ2m (see step S26) will be detected in the direction of the tilt coordinate θ in position P22, using the turning coordinate φ=φ1mt+dφ2.

### Step S24 (Process S24):

A second time-dependent corrected tilt coordinate θ1mt (θ1mt=54°) is calculated by performing time-dependent correction on the first directly-facing tilt coordinate θ1m (θ1m=53°). Then, with the second directly-facing turning coordinate φ2m (φ2m=−26°) fixed, the tilt coordinate θ is changed from the first directly-facing tilt coordinate θ1m to the second time-dependent corrected tilt coordinate θ1mt (second time-dependent tilt correction process).

Specifically, with the turning coordinate φ fixed at the second directly-facing turning coordinate φ2m, the tilt coordinate θ is changed and moved from position P23 to position P24. Here, time T24 when the tilt coordinate θ has moved to position P24 is 10:05:25, for example.

That is, elapsed-time-dependent correction is performed on the first directly-facing tilt coordinate θ1m, taking into consideration a change in the solar altitude θs over time from time T8 (10:04:00) when the tilt coordinate θ has been set to the first directly-facing tilt coordinate θ1m to time T23 (10:05:20) when the turning coordinate φ has been aligned with φ=φ2m (see Footnote 2 in FIG. 8B).

Accordingly, the first directly-facing tilt coordinate θ1m is changed into the second time-dependent corrected tilt coordinate θ1mt (position P24 at time T24), taking into consideration the amount of change dθs in the solar altitude θs@T23 (e.g., 55°) relative to the solar altitude θs@T8 (e.g., 54°). It should be noted that the second time-dependent corrected tilt coordinate θ1mt to which the tilt coordinate is to be changed is calculated by determining the amount of altitude change dθs as dθs=θs@T23−θs@T8=55−54=1° and adding the amount of altitude change dθs to the first directly-facing tilt coordinate θ1m (θ1mt=θ1m+dθs=53+1=54°).

As described above, in this step, before execution of a later-described second directly-facing tilt coordinate detection process S26, the second time-dependent corrected tilt coordinate θ1mt is calculated through the time-dependent correction of the first directly-facing tilt coordinate θ1m that reflects the amount of change dθs (=1°) in the solar altitude θs over time, and a second tilt detection reference coordinate (see step S26) is displaced in advance from the first directly-facing tilt coordinate θ1m to the second time-dependent corrected tilt coordinate θ1mt.

This configuration makes it possible to perform the second directly-facing tilt coordinate detection process S26 by applying the second time-dependent corrected tilt coordinate θ1mt that has been calculated with the amount of change dθs in the solar altitude θ over time being reflected in the first directly-facing tilt coordinate θ1m, thus enabling the second directly-facing tilt coordinate θ2m to be detected in a short time with high precision.

When time-dependent correction is performed on the tilt coordinate θ in this step, the second tilt detection reference coordinate is displaced from the first directly-facing tilt coordinate θ1m (e.g., position P23) to the second time-dependent corrected tilt coordinate θ1mt (e.g., position P24), so that a second tilt detection start coordinate is changed from the tilt coordinate (θ1m−dθ2) to a tilt coordinate (θ1mt−dθ2) (position P25) and a second tilt detection end coordinate is changed from the tilt coordinate (θ1m+dθ2) to a tilt coordinate (θ1mt+dθ2) (position P26).

In other words, when time-dependent correction is not performed on the first directly-facing tilt coordinate θ1m (tilt coordinate θ) in this step, subsequent processing is performed with the second time-dependent corrected tilt coordinate θ1mt replaced by the first directly-facing tilt coordinate θ1m (i.e., using the first directly-facing tilt coordinate θ1m before changed by the time-dependent correction into the second time-dependent corrected tilt coordinate θ1mt).

It should be noted that, when this step (second time-dependent tilt correction process) is not performed, the second time-dependent corrected tilt coordinate θ1mt is not set and therefore the tilt coordinate θ remains unchanged as the first directly-facing tilt coordinate θ1m. Accordingly, the second tilt detection start coordinate is the tilt coordinate (θ1m−dθ2), instead of the tilt coordinate (θ1mt−dθ2) (position P25), and the second tilt detection end coordinate is the tilt coordinate (θ1m+dθ2), instead of the tilt coordinate (θ1mt+dθ2) (position P26).

### Step S25 (Process S25):

With the second directly-facing turning coordinate φ2m (φ2m=−26°) fixed, the tilt coordinate θ is moved from the second time-dependent corrected tilt coordinate θ1mt (θ1mt=54°) in the negative direction by a second tilt displacement angle dθ2 (dθ2=2°) and changed into the second tilt detection start coordinate (θ1mt−dθ2) (θ1mt−dθ2=54−2=52).

Specifically, the tilt coordinate θ is moved from position P24 (second time-dependent corrected tilt coordinate θ1mt) to position P25 (second tilt detection start coordinate (θ1mt−dθ2)). Here, time T25 when the tilt coordinate θ has moved to position P25 is 10:05:40, for example.

### Step S26 (Process S26):

With the second directly-facing turning coordinate φ2m (φ2m=−26°) fixed, the tilt coordinate θ is sequentially changed from the second tilt detection start coordinate (θ1mt−dθ2) (=54−2=52°) to the second tilt detection end coordinate (θ1mt+dθ2) (θ1mt+dθ2=54+2=56).

Specifically, the tilt coordinate θ is moved from position P25 (second tilt detection start coordinate (θ1mt−dθ2)) to position P26 (second tilt detection end coordinate (θ1mt+dθ2)). Here, time T26 when the tilt coordinate θ has moved to position P26 is 10:06:20, for example.

In this step, a second directly-facing tilt coordinate θ2m at which the panel output (the output of the photovoltaic panel 10) transmitted from the A/D conversion portion 26 reaches its maximum value is also detected concurrently with changes in the tilt coordinate θ (second directly-facing tilt coordinate detection process). For example, it is assumed that the second directly-facing tilt coordinate θ2m is detected as 54.5°.

It should be noted that the second directly-facing tilt coordinate θ2m at which the panel output reaches its maximum value can be determined by, for example, the turning coordinate φ at which the current detected by the current detecting resistor 23 reaches its maximum value. By detecting current that is sensitive to a shift in position, the accuracy of detection can be increased as compared with the case of detecting voltage.

In this step, the second directly-facing tilt coordinate θ2m at which the panel output reaches its maximum value is detected by moving the tilt position of the photovoltaic panel while sequentially changing the tilt coordinate θ in a second tilt detection range (e.g., from (θ1mt−dθ2) to (θ1mt+dθ2)) that is defined in connection with the first directly-facing tilt coordinate θ1m corresponding to the solar altitude θs.

It should be noted that, when the time-dependent correction (step S24) is not performed on the tilt coordinate θ, processing is performed with the tilt coordinate θ1mt replaced by the first directly-facing tilt coordinate θ1m (i.e., using the first directly-facing tilt coordinate θ1m before changed by the time-dependent correction into the second time-dependent corrected tilt coordinate θ1mt) as described in step S24. That is, the second tilt detection range in the second directly-facing tilt coordinate detection process, in which the tilt coordinate θ is moved, is from the second tilt detection start coordinate (θ1m−dθ2) to the second tilt detection end coordinate (θ1m+dθ2).

Accordingly, the second tilt detection range is defined from the second tilt detection start coordinate (e.g., position P25 (θ1mt−dθ2) or a position (θ1m−dθ2) (not shown) corresponding to position P25) to the second tilt detection end coordinate (e.g., position P26 (θ1mt+dθ2) or a position (θ1m+dθ2) (not shown) corresponding to position P26) by using either the first directly-facing tilt coordinate θ1m (=53°) or the second time-dependent corrected tilt coordinate θ1mt (=54°) obtained through the time-dependent correction of the first directly-facing tilt coordinate θ1m as a second tilt detection reference coordinate and applying a predetermined second tilt displacement angle dθ2 (=2°) that is smaller than the first tilt displacement angle dθ1 (=5°), in both positive and negative directions of the second tilt detection reference coordinate.

This step (second directly-facing tilt coordinate detection process) is performed after execution of the second directly-facing turning coordinate alignment process S23 in which the turning coordinate φ is aligned with the second directly-facing turning coordinate φ2m detected in the second directly-facing turning coordinate detection process S22.

This configuration makes it possible to detect a shift in the position of the tilt coordinate θ in a state in which the photovoltaic panel directly faces the solar trajectory in the turning direction, thus enabling precise detection of the second directly-facing tilt coordinate θ2m.

### Step S27 (Process S27):

With the second directly-facing turning coordinate φ2m (φ2m=−26°) fixed, the tilt coordinate θ is aligned with the second directly-facing tilt coordinate θ2m (θ2m=54.5°) at which the panel output reaches its maximum value and that was detected in the second directly-facing tilt coordinate detection process S26 (second directly-facing tilt coordinate alignment process). Specifically, the tilt coordinate θ is moved from position P26 to position P27 (second directly-facing tilt coordinate θ2m). Here, time T27 (second directly-facing tilt coordinate setting time) when the tilt coordinate θ has moved to position P27 is 10:06:30, for example.

### Step S28 (Process S28):

A second time-dependent corrected turning coordinate φ2mt (φ2mt=−23°) is calculated by performing time-dependent correction on the second directly-facing turning coordinate φ2m (φ2m=−26°). Then, with the second directly-facing tilt coordinate θ2m (θ2m=54.5°) fixed, the turning coordinate φ is changed from the second directly-facing turning coordinate φ2m to the second time-dependent corrected turning coordinate φ2mt (second time-dependent turning correction process).

Specifically, with the tilt coordinate θ fixed at the second directly-facing tilt coordinate θ2m, the turning coordinate φ is changed and moved from position P27 to position P28. Here, time T28 when the turning coordinate φ has moved to position P28 is 10:06:35, for example.

That is, elapsed-time-dependent correction is performed on the second directly-facing turning coordinate φ2m, taking into consideration a change in the solar azimuth angle φs over time from time T23 (10:05:20) when the turning coordinate φ has been set to the second directly-facing turning coordinate φ2m to time T27 (10:06:30) when the tilt coordinate θ has been aligned with the second directly-facing tilt coordinate θ2m (see Footnote 3 in FIG. 8B).

Accordingly, the second directly-facing turning coordinate φ2m is changed into the second time-dependent corrected turning coordinate φ2mt (position P28 at time T28), taking into consideration the amount of change dφs in the solar azimuth angle φs@T27 (e.g., −21°) relative to the solar azimuth angle φs@T23 (e.g., −24°). It should be noted that the second time-dependent corrected turning coordinate φ2mt to which the turning coordinate is to be changed is calculated by determining the amount of solar azimuth angle change dφs as dφs=φs@T27−φs@T23=−21−(−24)=3° and adding the amount of solar azimuth angle change dφs to the second directly-facing turning coordinate φ2m (φ2mt=φ2m+dφs=−26+3=−23°).

As described above, in this step, before execution of a later described third directly-facing turning coordinate detection process S32, the second time-dependent corrected turning coordinate φ2mt is calculated through the time-dependent correction of the second directly-facing turning coordinate φ2m that reflects the amount of change dφs (=3°) in the solar azimuth angle φs over time, and a third turning detection reference coordinate (see step S32) is displaced in advance from the second directly-facing turning coordinate φ1m to the second time-dependent corrected turning coordinate φ2mt.

This configuration makes it possible to perform subsequent processing (third operation pattern) by applying the second time-dependent corrected turning coordinate φ2mt that has been calculated with the amount of change dφs in the solar azimuth angle φs over time being reflected in the second directly-facing turning coordinate φ2m, thus enabling the third directly-facing turning coordinate φ3m to be detected in a short time with high precision.

When time-dependent correction is performed on the turning coordinate φ in this step, the third turning detection reference coordinate is displaced from the second directly-facing turning coordinate φ2m (corresponding to position P27) to the second time-dependent corrected turning coordinate φ2mt (corresponding to position P28), so that the third turning detection start coordinate is changed from the turning coordinate (φ2m−dφ3) to a turning coordinate (φ2mt−dφ3) (position P31) and the third turning detection end coordinate is changed from the turning coordinate (φ2m+dφ3) to a turning coordinate (φ2mt+dφ3) (position P32).

In other words, when time-dependent correction is not performed on the second directly-facing turning coordinate φ2m (turning coordinate φ) in this step, subsequent processing is performed with the second time-dependent corrected turning coordinate φ2mt replaced by the second directly-facing turning coordinate φ2m (i.e., using the second directly-facing turning coordinate φ2m before changed by the time-dependent correction into the second time-dependent corrected turning coordinate φ2mt).

It should be noted that, when this step (second time-dependent turning correction process) is not performed, the second time-dependent corrected turning coordinate φ2mt is not set and therefore the turning coordinate φ remains unchanged as the second directly-facing turning coordinate φ2m. Accordingly, a third turning detection start coordinate is the turning coordinate (φ2m−dφ3), instead of the turning coordinate (φ2mt−dφ3) (position P31), and the third turning detection end coordinate is the turning coordinate (φ2m+dφ3), instead of the turning coordinate (φ2mt+dφ3) (position P32).

It is possible through the steps S21 to S28 described above to detect the second directly-facing turning coordinate φ2m and the second directly-facing tilt coordinate θ2m and associate the turning coordinate φ and the tilt coordinate θ respectively with the second directly-facing turning coordinate φ2m and the second directly-facing tilt coordinate θ2m. After step S28, if the detection of a shift in position is ended and the system is placed in the operating state, the processing proceeds to step S29.

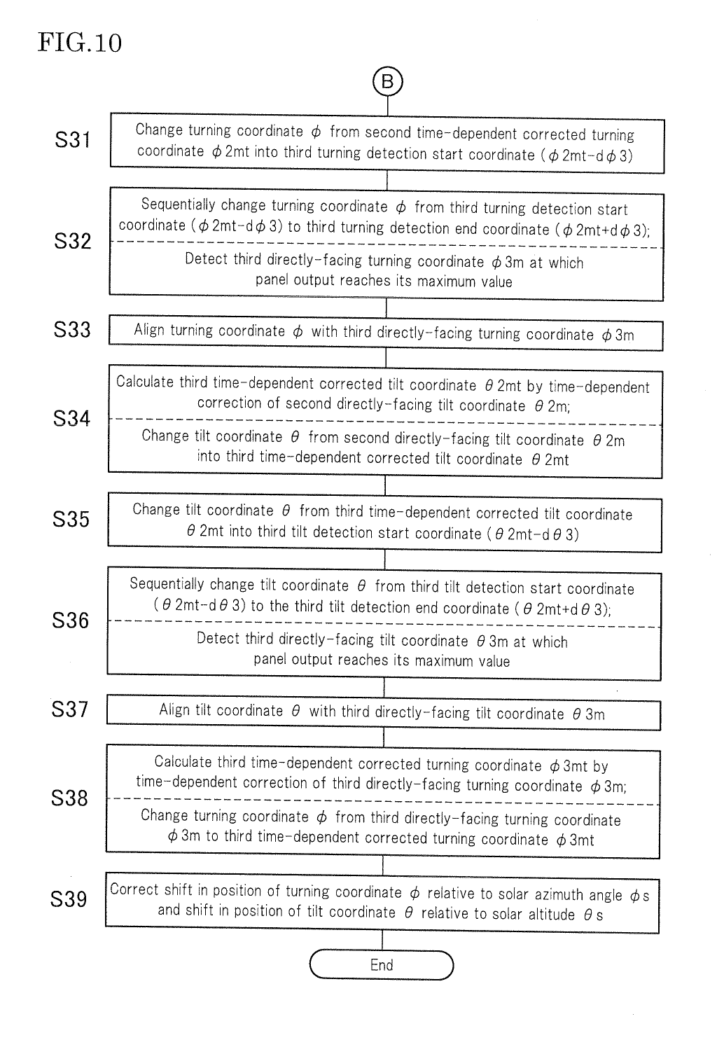

In the case of detecting a shift in position with higher precision, on the other hand, the processing proceeds to a procedure including steps S31 to S39 (see a third operation pattern in FIGS. 10 to 12). Such a form of performing the third operation pattern following the second operation pattern can be implemented as appropriate by a menu selection method.

### Step S29 (Process S29):

The photovoltaic panel 10 is driven after correcting a shift in the position of the turning coordinate φ relative to the solar azimuth angle φs and correcting a shift in the position of the tilt coordinate θ relative to the solar altitude θs (correction and drive process). Since the correction is performed based on the second directly-facing turning coordinate φ2m and the second directly-facing tilt coordinate θ2m before driving the photovoltaic panel 10, it is possible to correct the shifts in positions with ease and high precision before driving the photovoltaic panel 10.

Note that a specific computation process will be described in Embodiment 5.

When time-dependent correction is not performed on the second directly-facing turning coordinate φ2m (turning coordinate φ) in step S28, processing is performed with the second time-dependent corrected turning coordinate φ2mt replaced by the second directly-facing turning coordinate φ2m. Specifically, a shift in the position of the turning coordinate φ is corrected based on a difference between the solar azimuth angle φs at time T27 and the second directly-facing turning coordinate φ2m.

According to the present embodiment, the second directly-facing tilt coordinate θ2m is set to position P27 at time T27 (=10:06:30) and the second time-dependent corrected turning coordinate φ2mt is set to position P28 at time T28 (=10:06:35). That is, the control coordinates can be aligned in a very short time to the tilt position and the turning position at which the panel output reaches its maximum value. Accordingly, extremely high-precision alignment can be accomplished in a short time with ease.

Moreover, in the present embodiment, the duration of time from time T9 (10:04:05) in step S9 to time T28 (10:06:35) in step S28 is 2:30. That is, the detection and further correction of a shift in position can be performed in a short time of the order of 2:30, which enables higher precision alignment to be accomplished in a shorter time than in Embodiment 1.

As described above, the tracking control method (second operation pattern) for the tracking drive solar photovoltaic power generator 1 according to the present embodiment is performed following Embodiment 2 (first operation pattern), and includes the second directly-facing turning coordinate detection process S22 in which the second directly-facing turning coordinate φ2m at which the panel output reaches its maximum value is detected by moving the turning position of the photovoltaic panel while sequentially changing the turning coordinate φ in the second turning detection range (e.g., from (φ1mt−dφ2) to (φ1mt+dφ2)) that is defined in connection with the first directly-facing turning coordinate φ1m, and the second directly-facing tilt coordinate detection process S26 in which the second directly-facing tilt coordinate θ2m at which the panel output reaches its maximum value is detected by moving the tilt position of the photovoltaic panel while sequentially changing the tilt coordinate θ in the second tilt detection range (e.g., from (θ1mt−dθ2) to (θ1mt+dθ2)) that is defined in connection with the first directly-facing tilt coordinate θ1m.

This configuration makes it possible to detect a shift in the position of the first directly-facing turning coordinate φ1m relative to the solar azimuth angle φs with high precision with use of the second directly-facing turning coordinate φ2m, which has been detected in the second turning detection range (e.g., from (φ1mt−dφ2) to (φ1mt+dφ2)=10°) smaller than the first turning detection range (e.g., from (φ1−dφ1) to (φ1+dφ1)=30°), and a shift in the position of the first directly-facing tilt coordinate θ1m relative to the solar altitude θs with high precision with use of the second directly-facing tilt coordinate θ2m, which has been detected in the second tilt detection range (e.g., from (θ1mt−dθ2) to (θ1mt+dθ2)=4°) smaller than the first tilt detection range (e.g., from (θ1t−dθ1) to (θ1t+dθ1)=10°), and thereby to correct a shift in the position of the turning coordinate φ (second directly-facing turning coordinate φ2m) relative to the solar azimuth angle φs and a shift in the position of the tilt coordinate θ (second directly-facing tilt coordinate θ2m) relative to the solar altitude θs, thus enabling the turning position and the tilt position of the photovoltaic panel to be adjusted with ease and high precision so that the photovoltaic panel can directly face the solar trajectory.

In the tracking control method for the tracking drive solar photovoltaic power generator 1 according to the present embodiment, the second turning detection range is defined from the second turning detection start coordinate (e.g., position P21 (φ1mt−dφ2) or a position (φ1m−dφ2) (not shown) corresponding to position P21) to the second turning detection end coordinate (e.g., position P22 (φ1mt+dφ2) or a position (φ1m+dφ2) (not shown) corresponding to position P22) by using either the first directly-facing turning coordinate φ1m (=−25°) or the first time-dependent corrected turning coordinate φ1mt (=−23°) obtained through the time-dependent correction of the first directly-facing turning coordinate φ1m as a second turning detection reference coordinate and applying a predetermined second turning displacement angle dφ2 (=5°) that is smaller than the first turning displacement angle dφ1 (=15°), in both positive and negative directions of the second turning detection reference coordinate. Also, the second tilt detection range is defined from the second tilt detection start coordinate (e.g., position P25 (θ1mt−dθ2) or a position (θ1m−dθ2) (not shown) corresponding to position P25) to the second tilt detection end coordinate (e.g., position P26 (θ1mt+dθ2) or a position (θ1m+dθ2) (not shown) corresponding to position P26) by using either the first directly-facing tilt coordinate θ1m (=53°) or the second time-dependent corrected tilt coordinate θ1mt (=54°) obtained through the time-dependent correction of the first directly-facing tilt coordinate θ1m as a second tilt detection reference coordinate and applying a predetermined second tilt displacement angle dθ2 (=2°) that is smaller than the first tilt displacement angle dθ1 (=5°), in both positive and negative directions of the second tilt detection reference coordinate.

This configuration makes it possible to set the second turning detection range (=10°) and the second tilt detection range (=4°) to be smaller than the first turning detection range (=30°) and the first tilt detection range (=10°), thus enabling the second directly-facing turning coordinate φ2m and the second directly-facing tilt coordinate θ2m to be detected with higher precision than the first directly-facing turning coordinate φ1m and the first directly-facing tilt coordinate θ1m.

Note that although descriptions have been given regarding the tracking solar photovoltaic power generation system in which the photovoltaic panel tracks the solar trajectory in both the turning direction Roth and in the tilt direction Rotv, the contents of the present invention may be applied to a method for controlling either one of the turning direction Roth and the tilt direction Rotv. Alternatively, similar effects can of course be achieved with a tracking solar photovoltaic power generation system of such a type that the photovoltaic panel can track the sun in only either the turning direction Roth or the tilt direction Rotv.

In addition, the range of a shift in position can sequentially be narrowed down because, according to the second operation pattern (subsequent operation pattern), a shift in position is detected in a narrower range than the first operation pattern (previous operation pattern), and therefore efficient alignment is possible. In other words, the accuracy in detecting a shift in position can be improved with reliability by repeating operation patterns depending on the degree of light gathering accuracy (light gathering magnification). Therefore, even if the method is applied to a high-magnification solar photovoltaic power generator, alignment according to high magnifications can be accomplished.

In the tracking control method for the tracking drive solar photovoltaic power generator 1 according to the present embodiment, before execution of the second directly-facing turning coordinate detection process S22, the first time-dependent corrected turning coordinate φ1mt is calculated through time-dependent correction of the first directly-facing turning coordinate φ1m that reflects the amount of change dφs (=2°) in the solar azimuth angle φs over time, and the second turning detection reference coordinate is displaced in advance from the first directly-facing turning coordinate φ1m to the first time-dependent corrected turning coordinate φ1mt (first time-dependent turning correction process S9).

This configuration makes it possible to perform subsequent processing (second operation pattern) by applying the first time-dependent corrected turning coordinate φ1mt that has been calculated with the amount of change dφs in the solar azimuth angle φs over time being reflected in the first directly-facing turning coordinate φ1m, thus enabling the second directly-facing turning coordinate φ2m to be detected in a short time with high precision.

In the tracking control method for the tracking drive solar photovoltaic power generator 1 according to the present embodiment, the second directly-facing tilt coordinate detection process S26 is performed after execution of the second directly-facing turning coordinate alignment process S23 in which the turning coordinate φ is aligned with the second directly-facing turning coordinate φ2m detected in the second directly-facing turning coordinate detection process S22.

This configuration makes it possible to detect a shift in the position of the tilt coordinate θ in a state in which the photovoltaic panel 10 directly faces the solar trajectory in the turning direction, thus enabling precise detection of the second directly-facing tilt coordinate θ2m.

In the tracking control method for the tracking drive solar photovoltaic power generator 1 according to the present embodiment, before execution of the second directly-facing tilt coordinate detection process S26, the second time-dependent corrected tilt coordinate θ1mt is calculated through time-dependent correction of the first directly-facing tilt coordinate θ1m that reflects the amount of change dθs (=1°) in the solar altitude θs over time, and the second tilt detection reference coordinate is displaced in advance from the first directly-facing tilt coordinate θ1m to the second time-dependent corrected tilt coordinate θ1mt (second time-dependent tilt correction process S24).

This configuration makes it possible to perform the second directly-facing tilt coordinate detection process S26 by applying the second time-dependent corrected tilt coordinate θ1mt that has been calculated with the amount of change dθs in the solar altitude θ over time being reflected in the first directly-facing tilt coordinate θ1m, thus enabling the second directly-facing tilt coordinate θ2m to be detected in a short time with high precision.

The tracking control method for the tracking drive solar photovoltaic power generator 1 according to the present embodiment includes the correction and drive process S29 in which the photovoltaic panel 10 is driven after correcting a shift in the position of the turning coordinate φ relative to the solar azimuth angle φs and correcting a shift in the position of the tilt coordinate θ relative to the solar altitude θs. Since the correction is performed based on the second directly-facing turning coordinate φ2m and the second directly-facing tilt coordinate θ2m before driving the photovoltaic panel 10, it is possible to correct the shifts in positions with ease and high precision before driving the photovoltaic panel 10.

The tracking control method for the tracking drive solar photovoltaic power generator 1 according to the present embodiment may adopt a configuration in which voltage is used to detect the panel output in the first directly-facing turning coordinate detection process S3 and the first directly-facing tilt coordinate detection process S7, and current is used to detect the panel output in the second directly-facing turning coordinate detection process S22 and the second directly-facing tilt coordinate detection process S26.

This configuration makes it possible to detect the panel output with ease by voltage in the previous process (first directly-facing turning coordinate detection process S3 and first directly-facing tilt coordinate detection process S7) and detect the panel output with high precision by current in the subsequent process (second directly-facing turning coordinate detection process S22 and second directly-facing tilt coordinate detection process S26), thus enabling a shift in the position of the turning coordinate relative to the solar azimuth angle and a shift in the position of the tilt coordinate to be detected with ease and high precision.

The tracking control method for the tracking drive solar photovoltaic power generator 1 according to the present embodiment may adopt a configuration in which current is used to detect the panel output in the first directly-facing turning coordinate detection process S3 and the first directly-facing tilt coordinate detection process S7 and to detect the panel output in the second directly-facing turning coordinate detection process S22 and the second directly-facing tilt coordinate detection process S26.

This configuration makes it possible to detect the panel output with high precision by current in both of the previous process (first directly-facing turning coordinate detection process S3 and first directly-facing tilt coordinate detection process S7) and the subsequent process (second directly-facing turning coordinate detection process S22 and second directly-facing tilt coordinate detection process S26), thus enabling a shift in the position of the turning coordinate relative to the solar azimuth angle and a shift in the position of the tilt coordinate relative to the solar altitude to be detected with ease and high precision.

### Fourth Embodiment

Next is a description of a tracking control method for a tracking solar photovoltaic power generation system (tracking control method adopting a positional shift detection/correction program) according to Embodiment 4 of the present invention, given with reference to FIGS. 10 to 12.

FIG. 10 is a flowchart showing the procedure performed according to the third operation pattern when detecting and correcting a shift in the position of a tracking drive solar photovoltaic power generator in accordance with the tracking control method for the tracking solar photovoltaic power generation system according to Embodiment 4.

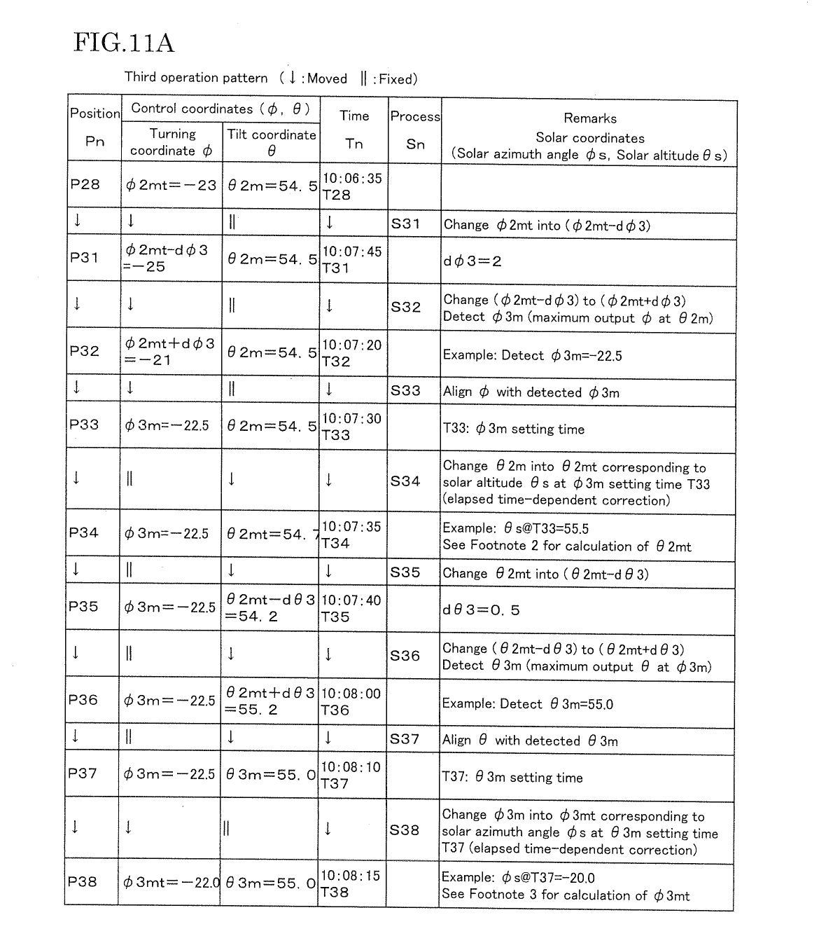

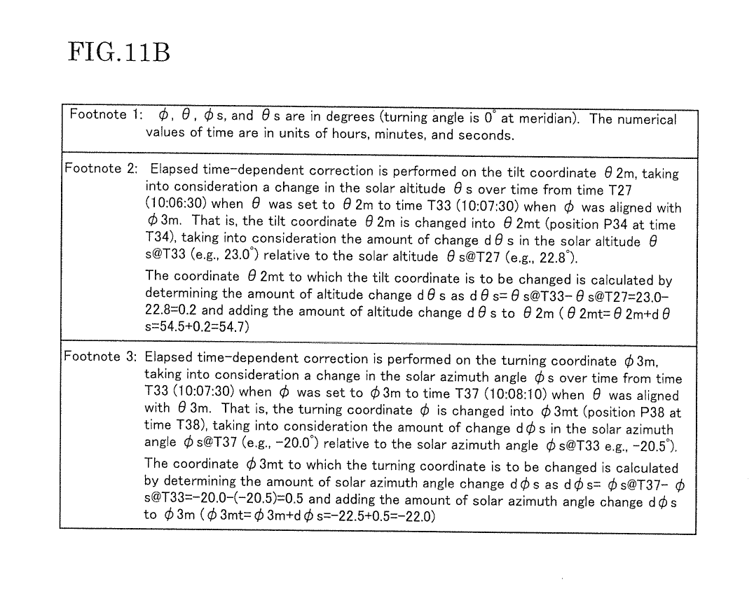

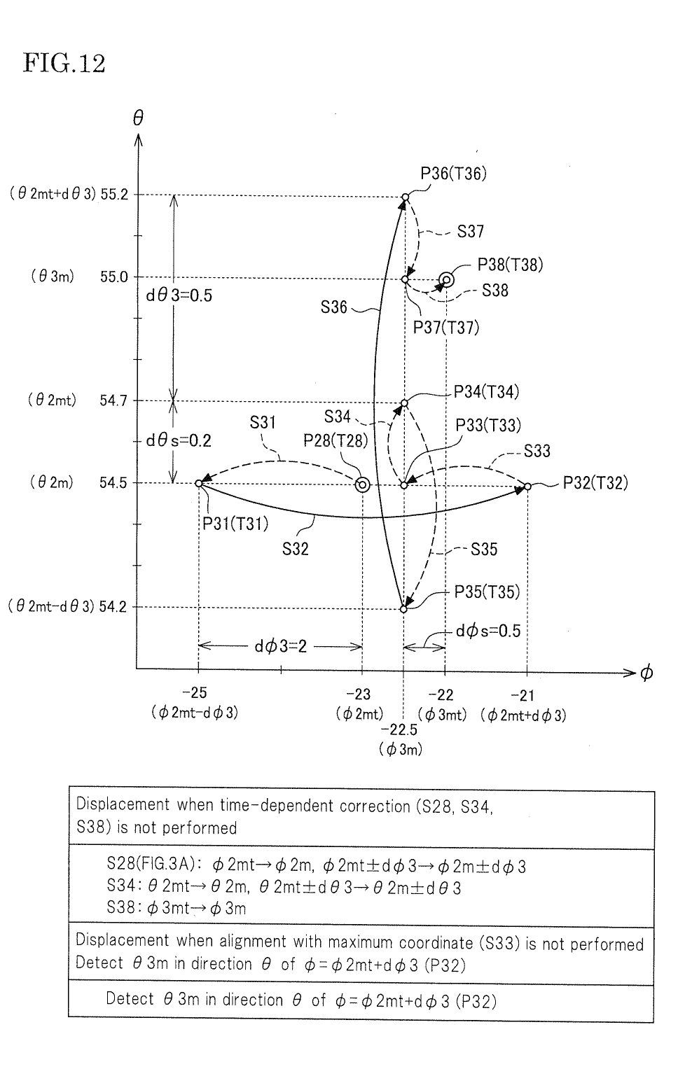

FIG. 11A is a reference chart containing detailed information about the transition of the control coordinates according to the third operation pattern shown in FIG. 10, and FIG. 11B is an explanatory chart containing footnotes to FIG. 11A. FIG. 12 is a coordinate diagram plotting the transition of the control coordinates according to the third operation pattern shown in FIG. 10.

The tracking control method (tracking control method adopting a program for detecting and correcting a shift in position) for the tracking solar photovoltaic power generation system according to the present embodiment is implemented according to, for example, a procedure including steps S31 to S39 (third operation pattern). Note that the following steps S31 to S39 are performed in accordance with a computer program installed on the PC 30 as described above.

It should be noted that the third operation pattern is performed following step S28 (position P28 at time T28) in the second operation pattern of Embodiment 3. Such a form of performing the third operation pattern following the second operation pattern can be implemented as appropriate by a menu selection method. Furthermore, the basic configuration as well as the functions and effects of the third operation pattern are similar to those of the first operation pattern and the second operation pattern, and therefore descriptions are primarily given regarding different points.

According to the third operation pattern, a third directly-facing turning coordinate φ3m and a third directly-facing tilt coordinate θ3m are detected in ranges smaller than the second turning detection range and the second tilt detection range by applying a third displacement angle dφ3 and a third tilt displacement angle dθ3 that are smaller than the second turning displacement angle dφ2 and the second tilt displacement angle dθ2 of the second operation pattern. It is thus possible to detect shifts in the positions of the turning coordinate φ and the tilt coordinate θ with higher precision than in the second operation pattern. That is, the third operation pattern is applied to make finer adjustments than the second operation pattern by repeating processing similar to that of the second operation pattern.

### Step S31 (Process S31):

With the second directly-facing tilt coordinate θ2m (θ2m=54.5°) fixed, the turning coordinate φ is moved from the second time-dependent corrected turning coordinate φ2mt (φ2mt=−23°) in the negative direction by the second turning displacement angle dφ3 (dφ3=2°) and changed into a third turning detection start coordinate (φ2mt−dφ3) (φ2mt−dφ3=−23−2=−25°).

Specifically, the turning coordinate φ is moved from position P28 (second time-dependent corrected turning coordinate φ2mt) to position P31 (third turning detection start coordinate (φ2mt−dφ3)). Here, time T31 when the turning coordinate φ has moved to position P31 is 10:07:45, for example.

### Step S32 (Process S32):

With the second directly-facing tilt coordinate θ2m (θ2m=54.5°) fixed, the turning coordinate φ is sequentially changed from the third turning detection start coordinate (φ2mt−dφ3) (φ2m−dφ3=−25°) to the third turning detection end coordinate (φ2mt+dφ3) (φ2mt+dφ3=−23+2=−21°).

Specifically, the turning coordinate φ is moved from position P31 (third turning detection start coordinate (φ2mt−dφ3)) to position P32 (third turning detection end coordinate (φ2mt+dφ3)). Here, time T32 when the turning coordinate φ has moved to position P32 is 10:07:20, for example.

In this step, a third directly-facing turning coordinate φ3m at which the panel output (the output of the photovoltaic panel 10) transmitted from the A/D conversion portion 26 reaches its maximum value is also detected concurrently (third directly-facing turning coordinate detection process).

For example, it is assumed that the third directly-facing turning coordinate φ3m is detected as −22.5°. It should be noted that, as in the case of the second operation pattern, the third directly-facing turning coordinate φ3m at which the panel output reaches its maximum value can be determined by, for example, the turning coordinate φ at which the current detected by the current detecting resistor 23 reaches its maximum value. Since the turning coordinate φ is obtained at a maximum value of current that is sensitive to a shift in the position of the photovoltaic panel 10 relative to sunlight, the turning coordinate φ can be determined with high precision.

That is, in this step, the third directly-facing turning coordinate φ3m at which the panel output reaches its maximum value is detected by moving the turning position of the photovoltaic panel while sequentially changing the turning coordinate φ in the third turning detection range (e.g., from (φ2mt−dφ3) to (φ2mt+dφ3)) that is defined in connection with the second directly-facing turning coordinate φ2m.

It should be noted that the third turning detection range is defined from the third turning detection start coordinate (e.g., position P31 (φ2mt−dφ3) or a position (φ2m−dφ3) (not shown) corresponding to position P31) to the third turning detection end coordinate (e.g., position P32 (φ2mt+dφ3) or a position (φ2m+dφ3) (not shown) corresponding to position P32) by using either the second directly-facing turning coordinate φ2m (=−26°) or the second time-dependent corrected turning coordinate φ2mt (=−23°) obtained through time-dependent correction of the second directly-facing turning coordinate φ2m as a third turning detection reference coordinate and applying a predetermined third turning displacement angle dφ3 (=2°) that is smaller than the second turning displacement angle dφ2 (=5°), in both positive and negative directions of the third turning detection reference coordinate.

When time-dependent correction is not performed on the first directly-facing turning coordinate φ2m (turning coordinate φ) in step S28, processing is performed with the second time-dependent corrected turning coordinate φ2mt replaced by the second directly-facing turning coordinate φ2m as described above.

### Step S33 (Process S33):

With the second directly-facing tilt coordinate θ2m (θ2m=54.5°) fixed, the turning coordinate φ is aligned with the third directly-facing turning coordinate φ3m (φ3m=−22.5°) at which the panel output reaches its maximum value and that was detected in the third directly-facing turning coordinate detection process S32 (third directly-facing turning coordinate alignment process).

Specifically, the turning coordinate φ is moved from position P32 to position P33 (third directly-facing turning coordinate φ3m). Here, time T33 (third directly-facing turning coordinate setting time) when the turning coordinate φ has moved to position P33 is 10:07:30, for example.

It should be noted that step S34 may be performed without moving the turning coordinate φ to position P33, i.e., with the turning coordinate φ unchanged (position P32). That is, when the turning coordinate φ is not aligned with the coordinate (third directly-facing turning coordinate φ3m) at which the panel output reaches its maximum value, a third directly-facing tilt coordinate θ3m (see step S36) is detected in the direction of the tilt coordinate θ in position P32, using turning coordinate φ=φ2mt+dφ3.

### Step S34 (Process S34):

A third time-dependent corrected tilt coordinate θ2mt (θ2mt=54.7°) is calculated by performing time-dependent correction on the second directly-facing tilt coordinate θ2m (θ2m=54.5°). Also, with the third directly-facing turning coordinate φ3m (φ3m=−22.5°) fixed, the tilt coordinate θ is changed from the second directly-facing tilt coordinate θ2m into the third time-dependent corrected tilt coordinate θ2mt (third time-dependent tilt correction process).

Specifically, with the turning coordinate φ fixed at the third directly-facing turning coordinate φ3m, the tilt coordinate θ is changed and moved from position P33 to position P34. Here, time T34 when the tilt coordinate θ has moved to position P34 is 10:07:35, for example.

That is, elapsed-time-dependent correction is performed on the second directly-facing tilt coordinate θ2m, taking into consideration a change in the solar altitude θs over time, from time T27 (10:06:30) when the tilt coordinate θ has been set to the second directly-facing tilt coordinate θ2m to time T33 (10:07:30) when the turning coordinate φ has been aligned with φ=φ3m (see Footnote 2 in FIG. 11B).

Accordingly, the second directly-facing tilt coordinate θ2m is changed into the third time-dependent corrected tilt coordinate θ2mt (position P34 at time T34), taking into consideration the amount of change dθs in the solar altitude θs@T33 (e.g., 23.0°) relative to the solar altitude θs@T27 (e.g., 22.8°). Note that the third time-dependent corrected tilt coordinate θ2mt to which the tilt coordinate is to be changed is calculated by determining the amount of altitude change dθs as dθs=θs@T33−θs@T27=23.0−22.8=0.2° and adding the amount of altitude change dθs to the second directly-facing tilt coordinate θ2m (θ2mt=θ2m+dθs=54.5+0.2=54.7°).

As described above, in this step, before execution of a later-described third directly-facing tilt coordinate detection process S36, the third time-dependent corrected tilt coordinate θ2mt is calculated through the time-dependent correction of the second directly-facing tilt coordinate θ2m that reflects the amount of change dθs in the solar altitude θs over time (=0.2°), and a third tilt detection reference coordinate (see step S36) is displaced in advance from the second directly-facing tilt coordinate θ2m to the third time-dependent corrected tilt coordinate θ2mt.

This configuration makes it possible to perform the third directly-facing tilt coordinate detection process S36 by applying the third time-dependent corrected tilt coordinate θ2mt that has been calculated with the amount of change dθs in the solar altitude θ over time being reflected in the second directly-facing tilt coordinate θ2m, thus enabling the third directly-facing tilt coordinate θ3m to be detected in a short time with high precision.

When time-dependent correction is performed on the tilt coordinate θ in this step, the third tilt detection reference coordinate is displaced from the second directly-facing tilt coordinate θ2m (e.g., position P33) to the third time-dependent corrected tilt coordinate θ2mt (e.g., position P34), so that the third tilt detection start coordinate is changed from a tilt coordinate (θ2m−dθ3) to a tilt coordinate (θ2mt−dθ3) (position P35) and the third tilt detection end coordinate is changed from a tilt coordinate (θ2m+dθ3) to a tilt coordinate (θ2mt+dθ3) (position P36).

In other words, when time-dependent correction is not performed on the second directly-facing tilt coordinate θ2m (tilt coordinate θ) in this step, subsequent processing is performed with the third time-dependent corrected tilt coordinate θ2mt replaced by the second directly-facing tilt coordinate θ2m (i.e., using the second directly-facing tilt coordinate θ2m before changed by the time-dependent correction into the third time-dependent corrected tilt coordinate θ2mt).

It should be noted that, when this step (third time-dependent tilt correction process) is not performed, the third time-dependent corrected tilt coordinate θ2mt is not set and therefore the tilt coordinate θ remains unchanged as the second directly-facing tilt coordinate θ2m. Thus, the third tilt detection start coordinate is the tilt coordinate (θ2m−dθ3), instead of the tilt coordinate (θ2mt−dθ3) (position P35), and the third tilt detection end coordinate is the tilt coordinate (θ2m+dθ3), instead of the tilt coordinate (θ2mt+dθ3) (position P36).

### Step S35 (Process S35):

With the third directly-facing turning coordinate φ3m (φ3m=−22.5°) fixed, the tilt coordinate θ is moved from the third time-dependent corrected tilt coordinate θ2mt (θ2mt=54.7°) in the negative direction by a third tilt displacement angle dθ3 (dθ3=0.5°) and changed into the third tilt detection start coordinate (θ2mt−dθ3) (θ2mt−dθ3=54.7−0.5=54.2°).

Specifically, the tilt coordinate θ is moved from position P34 (third time-dependent corrected tilt coordinate θ2mt) to position P35 (third tilt detection start coordinate (θ2mt−dθ3)). Here, time T35 when the tilt coordinate θ has moved to position P35 is 10:07:40, for example.

### Step S36 (Process S36):

With the third directly-facing turning coordinate φ3m (φ3m=−22.5°) fixed, the tilt coordinate θ is sequentially changed from the third tilt detection start coordinate (θ2mt−dθ3) (θ2mt−dθ3=54.2°) to the third tilt detection end coordinate (θ2mt+dθ3) (θ2mt+dθ3=54.7+0.5=55.2°).

Specifically, the tilt coordinate θ is moved from position P35 (third tilt detection start coordinate (θ2mt−dθ3)) to position P36 (third tilt detection end coordinate (θ2mt+dθ3)). Here, time T36 when the tilt coordinate θ has moved to position P36 is 10:08:00, for example.

In this step, a third directly-facing tilt coordinate θ3m at which the panel output (the output of the photovoltaic panel 10) transmitted from the A/D conversion portion 26 reaches its maximum value is also detected concurrently with changes in the tilt coordinate θ (third directly-facing tilt coordinate detection process). For example, it is assumed that the third directly-facing tilt coordinate θ3m is detected as 55.0°.

It should be noted that the third directly-facing tilt coordinate θ3m at which the panel output reaches its maximum value can be determined by, for example, the turning coordinate φ at which the current detected by the current detecting resistor 23 reaches its maximum value.

In this step, the third directly-facing tilt coordinate θ3m at which the panel output reaches its maximum value is detected by moving the tilt position of the photovoltaic panel while sequentially changing the tilt coordinate θ in a third tilt detection range (e.g., from (θ2mt−dθ3) to (θ2mt+dθ3)) that is defined in connection with the second directly-facing tilt coordinate θ2m corresponding to the solar altitude θs.

It should be noted that, when the time-dependent correction (step S34) is not performed on the tilt coordinate θ, processing is performed with the tilt coordinate θ2mt replaced by the second directly-facing tilt coordinate θ2m (i.e., using the second directly-facing tilt coordinate θ2m before changed by the time-dependent correction into the third time-dependent corrected tilt coordinate θ2mt) as described in step S34. That is, the third tilt detection range in the third directly-facing tilt coordinate detection process, in which the tilt coordinate θ is moved, is from a third tilt detection start coordinate (θ2m−dθ3) to a third tilt detection end coordinate (θ2m+dθ3).

Accordingly, the third tilt detection range is defined from the third tilt detection start coordinate (e.g., position P35 (θ2mt−dθ3) or a position (θ2m−dθ3) (not shown) corresponding to position P35) to the third tilt detection end coordinate (e.g., position P36 (θ2mt+dθ3) or a position (θ2m+dθ3) (not shown) corresponding to position P36) by using either the second directly-facing tilt coordinate θ2m (=54.5°) or the third time-dependent corrected tilt coordinate θ2mt (=54.7°) obtained through the time-dependent correction of the second directly-facing tilt coordinate θ2m as a third tilt detection reference coordinate and applying the predetermined third tilt displacement angle dθ3 (=0.5°) that is smaller than the second tilt displacement angle dθ2 (=2°), in both positive and negative directions of the third tilt detection reference coordinate.

This step (third directly-facing tilt coordinate detection process) is performed after execution of the third directly-facing turning coordinate alignment process S33 in which the turning coordinate φ is aligned with the third directly-facing turning coordinate φ3m detected in the third directly-facing turning coordinate detection process S32.

This configuration makes it possible to detect a shift in the position of the tilt coordinate θ in a state in which the photovoltaic panel directly faces the solar trajectory in the turning direction, thus enabling precise detection of the third directly-facing tilt coordinate θ3m.

### Step S37 (Process S37):

With the third directly-facing turning coordinate φ3m (φ3m=−22.5°) fixed, the tilt coordinate θ is aligned with the third directly-facing tilt coordinate θ3m (θ3m=55.0°) at which the panel output reaches its maximum value and that was detected in the third directly-facing tilt coordinate detection process S36 (third directly-facing tilt coordinate alignment process). Specifically, the tilt coordinate θ is moved from position P36 to position P37 (third directly-facing tilt coordinate θ3m). Here, time T37 (third directly-facing tilt coordinate setting time) when the tilt coordinate θ has moved to position P37 is 10:08:10, for example.

### Step S38 (Process S38):

A third time-dependent corrected turning coordinate φ3mt (φ3mt=−22°) is calculated by performing time-dependent correction on the third directly-facing turning coordinate φ3m (φ3m=−22.5°). Also, with the third directly-facing tilt coordinate θ3m (θ3m=55.0°) fixed, the turning coordinate φ is changed from the third directly-facing turning coordinate φ3m to the third time-dependent corrected turning coordinate φ3mt (third time-dependent turning correction process).

Specifically, with the tilt coordinate θ fixed at the third directly-facing tilt coordinate θ3m, the turning coordinate φ is changed and moved from position P37 to position P38. Here, time T38 when the turning coordinate φ has moved to position P38 is 10:08:15, for example.

That is, elapsed-time-dependent correction is performed on the third directly-facing turning coordinate φ3m, taking into consideration a change in the solar azimuth angle φs over time from time T33 (10:05:20) when the turning coordinate φ has been set to the third tilt coordinate φ3m to time T37 (10:08:10) when the tilt coordinate θ has been aligned with the third directly-facing tilt coordinate θ3m (see Footnote 3 in FIG. 11B).

Accordingly, the third directly-facing turning coordinate φ3m is changed into the third time-dependent corrected turning coordinate φ3mt (position P38 at time T38), taking into consideration the amount of change dφs in the solar azimuth angle φs@T37 (e.g., −20.0°) relative to the solar azimuth angle φs@T33 (e.g., −20.5°). It should be noted that the third time-dependent corrected turning coordinate φ3mt to which the turning coordinate φ is to be changed is calculated by determining the amount of solar azimuth angle change dφs as dφs=φs@T37−φs@T33=−20.0−(−20.5)=0.5° and adding the amount of solar azimuth angle change dφs to the third directly-facing turning coordinate φ3m (φ3mt=φ3m+dφs=−22.5+0.5=−22.0°).

When time-dependent correction is not performed on the third directly-facing turning coordinate φ3m (turning coordinate φ) in this step, subsequent processing is performed with the third time-dependent corrected turning coordinate φ3mt replaced by third directly-facing turning coordinate φ3m (i.e., using the third directly-facing turning coordinate φ3m before changed by the time-dependent correction into the third time-dependent corrected turning coordinate φ3mt).

In the case of detecting a shift in position with higher precision, a similar procedure may further be repeated. If the detection of a shift in position is ended and the system is placed in the operating state, the processing proceeds to step S39.

According to the present embodiment, the third directly-facing tilt coordinate θ3m is set to position P37 at 10:08:10 and the third time-dependent corrected turning coordinate φ3mt is set to position P38 at 10:08:15. That is, the tilt position and the turning position can be aligned in an extremely short time to those at which the panel output reaches its maximum value. Accordingly, extremely high precision alignment can be accomplished with ease by repeating procedures such as the first to third operation patterns.

### Step S39 (Process S39):

The photovoltaic panel 10 is driven after correcting a shift in the position of the turning coordinate φ relative to the solar azimuth angle φs and correcting a shift in the position of the tilt coordinate θ relative to the solar altitude θs (correction and drive process). Since the correction is performed based on the third directly-facing turning coordinate φ3m and the third directly-facing tilt coordinate θ3m before driving the photovoltaic panel 10, it is possible to correct the shifts in positions with ease and high precision before driving the photovoltaic panel 10.

Note that a specific computation process will be described in Embodiment 5.

Also, when time-dependent correction is not performed on the third directly-facing turning coordinate φ3m (turning coordinate φ) in step S38, processing is performed with the third time-dependent corrected turning coordinate φ3mt replaced by the third directly-facing turning coordinate φ3m. That is, a shift in the position of the turning coordinate φ is corrected based on a difference between the solar azimuth angle φs at time T37 and the third directly-facing turning coordinate φ3m.

According to the present embodiment, the third directly-facing tilt coordinate θ3m is set to position P37 at time T37 (=10:08:10), and the third time-dependent corrected turning coordinate φ3mt is set to position P38 at time T38 (=10:08:15). That is, the control coordinates can be aligned in an extremely short time to the tilt position and the turning position at which the panel output reaches its maximum value. Accordingly, extremely high-precision alignment can be accomplished with ease in a short time.

In the present embodiment, the duration of time from time T28 (10:06:35) in step S28 to time T38 (10:08:15) in step S38 is 1:40. That is, the detection and further correction of a shift in position can be performed in a short time on the order of 1:40, which enables higher-precision alignment to be accomplished in a shorter time than in Embodiment 2.

As described above, the tracking control method (third operation pattern) for the tracking drive solar photovoltaic power generator 1 according to the present embodiment is performed following Embodiment 3 (second operation pattern), and includes the third directly-facing turning coordinate detection process S32 in which the third directly-facing turning coordinate φ3m at which the panel output reaches its maximum value is detected by moving the turning position of the photovoltaic panel while sequentially changing the turning coordinate φ in the third turning detection range (e.g., from (φ2mt−dφ3) to (φ2mt+dφ3)) that is defined in connection with the second directly-facing turning coordinate φ2m, and the third directly-facing tilt coordinate detection process S36 in which the third directly-facing tilt coordinate θ3m at which the panel output reaches its maximum value is detected by moving the tilt position of the photovoltaic panel while sequentially changing the tilt coordinate θ in the third tilt detection range (e.g., from (θ2mt−dθ3) to (θ2mt+dθ3)) that is defined in connection with the second directly-facing tilt coordinate θ2m.

This configuration makes it possible to detect a shift in the position of the turning coordinate φ (second directly-facing turning coordinate φ2m) relative to the solar azimuth angle φs with high precision with use of the third directly-facing turning coordinate φ3m, which has been detected in the third turning detection range (e.g., from (φ2mt−dφ3) to (φ2mt+dφ3)=4°) smaller than the second turning detection range (e.g., from (φ1mt−dφ2) to (φ1mt+dφ2)=10°), and a shift in the position of the second directly-facing tilt coordinate θ2m relative to the solar altitude θs with high precision with use of the third directly-facing tilt coordinate θ3m, which has been detected in the third tilt detection range (e.g., from (θ2mt−dθ3) to (θ2mt+dθ3)=1°) smaller than the second tilt detection range (e.g., from (θ1mt−dθ2) to (θ1mt+dθ2)=4°), and to thereby correct a shift in the position of the turning coordinate φ relative to the solar azimuth angle φs and a shift in the position of the tilt coordinate θ relative to the solar altitude θs with high precision, thus enabling the turning position and the tilt position of the photovoltaic panel 10 to be adjusted with ease and high precision so that the photovoltaic panel can directly face the solar trajectory.

In the tracking control method for the tracking drive solar photovoltaic power generator 1 according to the present embodiment, the third turning detection range is defined from the third turning detection start coordinate (e.g., position P31 (φ2mt−dφ3) or a position (φ2m−dφ3) (not shown) corresponding to position P31) to the third turning detection end coordinate (e.g., position P32 (φ2mt+dφ3) or a position (φ2m+dφ3) (not shown) corresponding to position P32) by using either the second directly-facing turning coordinate φ2m (=−26°) or the second time-dependent corrected turning coordinate φ2mt (=−23°) obtained through the time-dependent correction of the second directly-facing turning coordinate φ2m as a third turning detection reference coordinate and applying a predetermined third turning displacement angle dφ3 (=2°) that is smaller than the second turning displacement angle dφ2 (=5°), in both positive and negative directions of the third turning detection reference coordinate. Also, the third tilt detection range is defined from the third tilt detection start coordinate (e.g., position P35 (θ2mt−dθ3) or a position (θ2m−dθ3) (not shown) corresponding to position P35) to the third tilt detection end coordinate (e.g., position P36 (θ2mt+dθ3) or a position (θ2m+dθ3) (not shown) corresponding to position P36) by using either the second directly-facing tilt coordinate θ2m (=54.5°) or the third time-dependent corrected tilt coordinate θ2mt (=54.7°) obtained through the time-dependent correction of the second directly-facing tilt coordinate θ2m as a third tilt detection reference coordinate and applying a predetermined third tilt displacement angle dθ3 (=0.5°) that is smaller than the second tilt displacement angle dθ2 (=2°), in both positive and negative directions of the third tilt detection reference coordinate.

This configuration makes it possible to set the third turning detection range (=4°) and the third tilt detection range (=1°) to be smaller than the second turning detection range (=10°) and the second tilt detection range (=4°), thus enabling the third directly-facing turning coordinate φ3m and the third directly-facing tilt coordinate θ3m to be detected with higher precision than the second directly-facing turning coordinate φ2m and the second directly-facing tilt coordinate θ2m.

Accordingly, it is possible to correct a shift in the position of the turning coordinate φ (third directly-facing turning coordinate φ3m) relative to the solar azimuth angle φs and a shift in the position of the tilt coordinate θ (third directly-facing tilt coordinate θ3m) relative to the solar altitude θs with high precision, which enables the turning position and the tilt position of the photovoltaic panel 10 to be adjusted with ease and high precision so that the photovoltaic panel can directly face the solar trajectory.

In addition, the range of a shift in position can sequentially be narrowed down because, according to the third operation pattern (subsequent operation pattern) a shift in position is detected in a narrower range than in the second operation pattern (previous operation pattern), and therefore efficient alignment is possible. That is, it is possible to further improve the accuracy in detecting a shift in position depending on the degree of light gathering accuracy (light gathering magnification).

In the tracking control method for the tracking drive solar photovoltaic power generator 1 according to the present embodiment, before execution of the third directly-facing turning coordinate detection process S32, the second time-dependent corrected turning coordinate φ2mt is calculated through the time-dependent correction of the second directly-facing turning coordinate φ2m that reflects the amount of change dφs (3°) in the solar azimuth angle φs over time, and the third turning detection reference coordinate is displaced in advance from the second directly-facing turning coordinate φ2m to the second time-dependent corrected turning coordinate φ2mt (second time-dependent turning correction process S28).

This configuration makes it possible to perform subsequent processing (third operation pattern) by applying the second time-dependent corrected turning coordinate φ2mt that has been calculated with the amount of change in the solar azimuth angle φ over time being reflected in the second directly-facing turning coordinate φ2m, thus enabling the third directly-facing turning coordinate φ3m to be detected in a short time with high precision.

In the tracking control method for the tracking drive solar photovoltaic power generator 1 according to the present embodiment, the third directly-facing tilt coordinate detection process S36 is performed after execution of the third directly-facing turning coordinate alignment process S33 in which the turning coordinate φ is aligned with the third directly-facing turning coordinate φ3m detected in the third directly-facing turning coordinate detection process S32.

This configuration makes it possible to detect a shift in the position of the tilt coordinate θ in a state in which the photovoltaic panel 10 directly faces the solar trajectory in the turning direction, thus enabling precise detection of the third directly-facing tilt coordinate θ3m.

In the tracking control method for the tracking drive solar photovoltaic power generator 1 according to the present embodiment, before execution of the third directly-facing tilt coordinate detection process S36, the third time-dependent corrected tilt coordinate θ2mt is calculated through the time-dependent correction of the second directly-facing tilt coordinate θ2m that reflects the amount of change dθs in the solar altitude θs over time (=0.2°), and the third tilt detection reference coordinate is displaced in advance from the second directly-facing tilt coordinate θ2m to the third time-dependent corrected tilt coordinate θ2mt (third time-dependent tilt correction process S34).

This configuration makes it possible to perform the third directly-facing tilt coordinate detection process S36 by applying the third time-dependent corrected tilt coordinate θ2mt that has been calculated with the amount of change dθs in the solar altitude θ over time being reflected in the second directly-facing tilt coordinate θ2m, thus enabling the third directly-facing tilt coordinate θ3m to be detected in a short time with high precision.

The tracking control method for the tracking drive solar photovoltaic power generator 1 according to the present embodiment includes the correction and drive process S39 in which the photovoltaic panel 10 is driven after correcting a shift in the position of the turning coordinate φ relative to the solar azimuth angle φs and correcting a shift in the position of the tilt coordinate θ relative to the solar altitude θs. Since the correction is performed based on the third directly-facing turning coordinate φ3m and the third directly-facing tilt coordinate θ3m before driving the photovoltaic panel 10, it is possible to correct the shifts in positions with ease and high precision before driving the photovoltaic panel 10.

The tracking control method for the tracking drive solar photovoltaic power generator 1 according to the present embodiment adopts a configuration in which current is used to detect the panel output in the third directly-facing turning coordinate detection process S32 and the third directly-facing tilt coordinate detection process S36. It is thus possible, by means of current that is sensitive to a shift in the position of the photovoltaic panel 10 relative to sunlight, to detect, multiple times, the turning coordinate φ and the tilt coordinate θ at which the panel output reaches its maximum value, and therefore the panel output can be detected with ease and high precision even in a state in which there is only a slight shift in the position of the turning coordinate relative to the solar azimuth angle and a slight shift in the position of the tilt coordinate relative to the solar altitude.

As can be seen from the comparisons of the operation patterns described in Embodiments 2 to 4, a shift in position can be detected in a shorter time as the precision increases according to the present invention, which enables a shift in position to be detected and corrected with efficiency and effectiveness.

### Fifth Embodiment

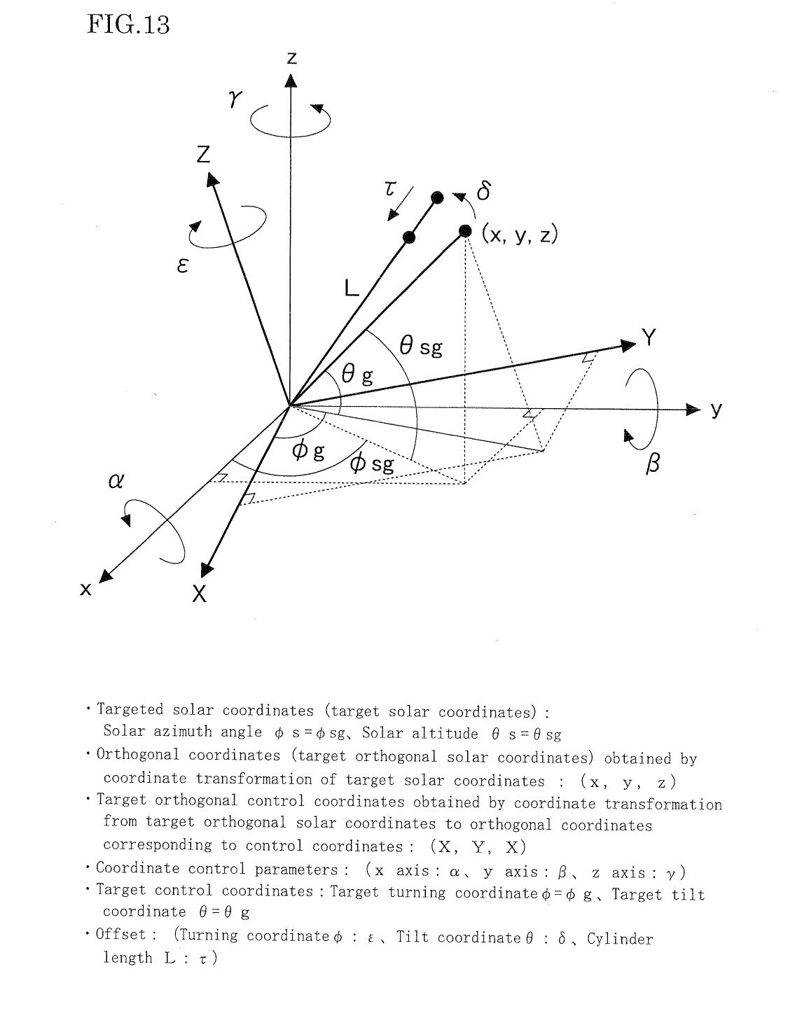

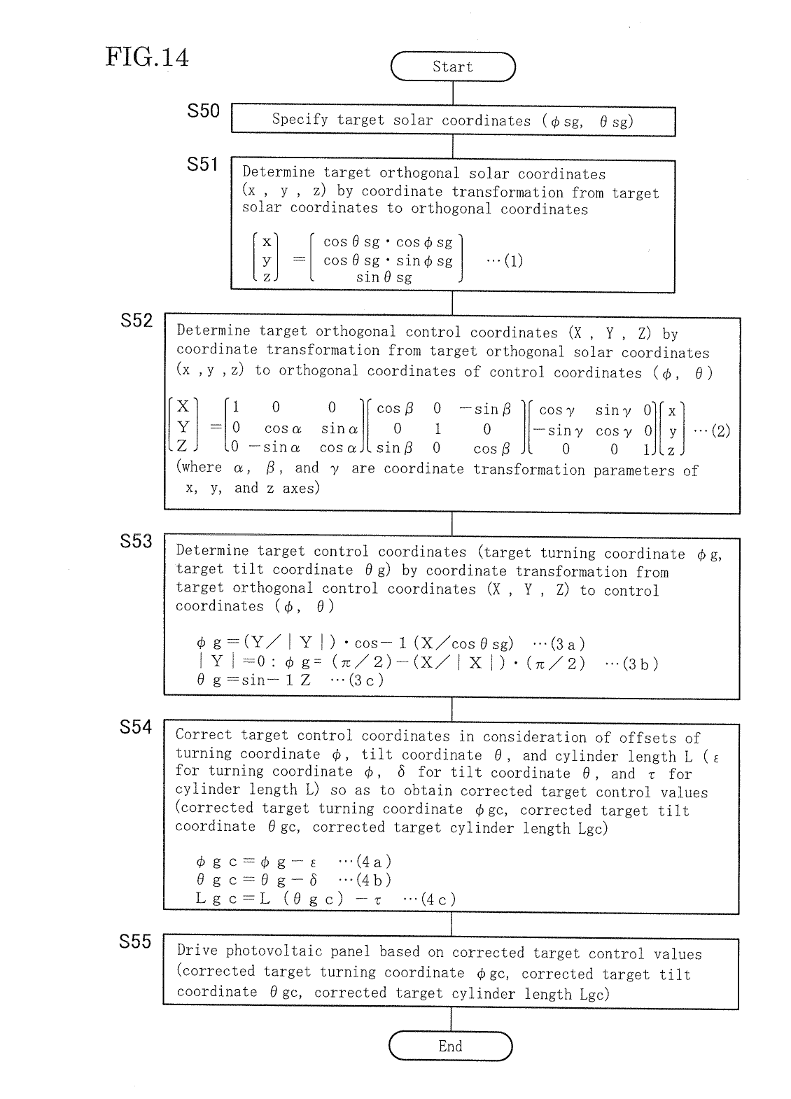

Next is a description of a tracking control method for a tracking solar photovoltaic power generation system according to Embodiment 5, given with reference to FIGS. 13 and 14. In the present embodiment, a correction and drive process is described in which a photovoltaic panel is driven after correcting a shift in the position of the panel (i.e., detailed descriptions of step S10 in Embodiment 2, step S29 in Embodiment 3, and step S39 in Embodiment 4).

FIG. 13 shows a coordinate graphic showing the correlation between a coordinate system applied to a tracking drive solar photovoltaic power generator and control parameters, in the tracking control method for the tracking solar photovoltaic power generation system according to Embodiment 5.

Solar coordinates (solar azimuth angle φs and solar altitude θs) that indicate the position of the sun targeted for tracking are represented by target solar coordinates (target solar azimuth angle φsg and target solar altitude θsg). Orthogonal coordinates obtained by coordinate transformation from the target solar coordinates are represented by target orthogonal solar coordinates (x, y, z).

The target orthogonal solar coordinates (x, y, z) are transformed into target orthogonal control coordinates (X, Y, Z) that are orthogonal coordinates corresponding to the control coordinates (turning coordinate φ and tilt coordinate θ). Coordinate transformation parameters used at this time are denoted by α for the x axis, β for the y axis, and γ for the z axis.

The target orthogonal control coordinates (X, Y, Z) are transformed into target control coordinates (target turning coordinate φg and target tilt coordinate θg) for the control coordinates (turning coordinate φ and tilt coordinate θ). Then, an offset (shift in position) of the target control coordinates (target turning coordinate φg and target tilt coordinate θg) is corrected.

An offset is set as follows. An offset ε of the turning coordinate φ is determined based on a difference between the solar azimuth angle φs and a detected Nth directly-facing turning coordinate φNm, and an offset δ of the tilt coordinate θ is determined based on a difference between the solar altitude and a detected Nth directly-facing tilt coordinate θNm.

Note that N denotes the final number of times each coordinate is detected. For example, in the case of the first operation pattern of Embodiment 2, the Nth directly-facing turning coordinate φNm is the first time-dependent corrected turning coordinate φ1mt (or the first directly-facing turning coordinate φ1m), and the Nth directly-facing tilt coordinate θNm is the first directly-facing tilt coordinate θ1m. In the case of the second operation pattern of Embodiment 3, the Nth directly-facing turning coordinate φNm is the second time-dependent corrected turning coordinate φ2mt (or the second directly-facing turning coordinate φ2m), and the Nth directly-facing tilt coordinate θNm is the second directly-facing tilt coordinate θ2m. In the case of the third operation pattern of Embodiment 4, the Nth directly-facing turning coordinate φNm is the third time-dependent corrected turning coordinate φ3mt (or the third directly-facing turning coordinate φ3m), and the Nth directly-facing tilt coordinate θNm is the third directly-facing tilt coordinate θ3m.

Moreover, in the present embodiment, the driving portion 12 is constituted by, for example, a turntable turning drive mechanism or a jack cylinder tilt drive mechanism. Therefore, an offset τ of a cylinder length L is taken into consideration.

Specifically, values obtained by correcting the target control coordinates (target turning coordinate φg and target tilt coordinate θg) in consideration of offsets are determined as corrected target control values (corrected target turning coordinate φgc, corrected target tilt coordinate θgc, and corrected target cylinder length Lgc (not shown), which are calculated by computation processing of step S54 in FIG. 14).

It should be noted that various modifications in the form of offsets are conceivable depending on the configuration of the driving portion 12.

FIG. 14 is a flowchart showing the procedure of computation processing that is performed based on the coordinate graphic shown in FIG. 13 when correcting shifts in the positions of the control coordinates and driving a photovoltaic panel.

Correction processing for correcting shifts in the positions of the control coordinates (turning coordinate φ and tilt coordinate θ) and driving the photovoltaic panel 10, according to the present embodiment, can be implemented, for example according to a procedure including steps S50 to S55. Note that, like other procedures, the procedure of steps S50 to S55 is performed by a computer program installed on the PC 30.

### Step S50:

Targeted solar coordinates (solar azimuth angle φs and solar altitude θs) are specified as target solar coordinates (target solar azimuth angle φsg and target solar altitude θsg).

### Step S51:

Coordinate transformation from the solar coordinates to orthogonal coordinates is performed. Specifically, the target solar coordinates are transformed into orthogonal coordinates so as to obtain target orthogonal solar coordinates (x, y, z). The details thereof are as given by Equation 1 (FIG. 14).

### Step S52:

The target orthogonal solar coordinates (x, y, z) are transformed into orthogonal coordinates that correspond to the control coordinates (turning coordinate φ and the tilt coordinate θ), so as to obtain target orthogonal control coordinates (X, Y, Z). The details thereof are as given by Equation 2 (FIG. 14). Note that α, β, and γ are applied respectively to the x, y, and z axes as coordinate transformation parameters for the coordinate transformation.

### Step S53:

The target orthogonal control coordinates (X, Y, Z) are transformed into control coordinates (turning coordinate φ and the tilt coordinate θ) so as to obtain target control coordinates (target turning coordinate φg and target tilt coordinate θg). The details thereof are as given by Equations 3a, 3b, and 3c (FIG. 14).

### Step S54:

The target control coordinates (target turning coordinate φg and target tilt coordinate θg) are corrected in consideration of the offsets of the turning coordinate φ and the tilt coordinate θ (i.e., shifts in positions, the offset ε of the turning coordinate φ being defined based on a difference between the solar azimuth angle φs and the Nth directly-facing turning coordinate φNm, and the offset δ of the tilt coordinate θ being defined based on a difference between the solar altitude θs and the Nth directly-facing tilt coordinate θNm, where N denotes the final number of times each coordinate is detected), so as to obtain corrected target control values (corrected target turning coordinate φgc and corrected target tilt coordinate θgc). The details thereof are as given by Equations 4a and 4b (FIG. 14).

It should be noted that, since a jack-cylinder tilt drive mechanism is used in the present embodiment, a target cylinder length L (θgc) is corrected in consideration of the offset τ of the cylinder length L, so as to obtain a corrected target cylinder length Lgc. The details thereof are as given by Equation 4c (FIG. 14).

That is, in the present embodiment, the values obtained by adding the corrected target cylinder length Lgc to the corrected target turning coordinate φgc and the corrected target tilt coordinate θgc are defined as corrected target control values.

As described above, in the present embodiment, the corrected target turning coordinate φgc, the corrected target tilt coordinate θgc, and the corrected target cylinder length Lgc are defined as corrected target control values by applying six correction parameters (target turning coordinate φg, target tilt coordinate θg, target cylinder length L(θgc), offset ε of the turning coordinate φ, offset δ of the tilt coordinate θ, and offset τ of the cylinder length L).

The correction parameters are to be set as appropriate by a drive system constituting the driving portion 12. In addition, it is desirable that multiple sets (data sets) of directly-facing coordinates (directly-facing turning coordinate and directly-facing tilt coordinate) and solar coordinates (solar azimuth angle and solar altitude) are obtained. Such multiple data sets are desirably obtained at appropriate time intervals. Specifically, the time interval is approximately two hours, for example.

The above-described six correction parameters can be derived by two operations. In order to derive the correction parameters with higher precision, the number of operations is desirably increased.

It should be noted that Equations 1 to 4c described above are preset equations.

### Step S55:

The photovoltaic panel is driven via the driving portion 12 based on the corrected target control values (corrected target turning coordinate φgc, corrected target tilt coordinate θgc, and corrected target cylinder length Lgc).

The following is a description of the case where the present embodiment is applied to the first operation pattern (step S10) of Embodiment 2.

The process for correcting a shift in the position of the photovoltaic panel 10 and driving the photovoltaic panel 10 (tracking control method for the tracking solar photovoltaic power generation system) according to Embodiment 2 is configured such that the photovoltaic panel 10 is driven by application of the corrected target turning coordinate φgc and the corrected target tilt coordinate θgc that have been set by specifying a targeted solar azimuth angle φs as a target solar azimuth angle φsg and a targeted solar altitude θs as a target solar altitude θsg, performing coordinate transformation using preset equations from the target solar azimuth angle φsg and the target solar altitude θsg to a target turning coordinate φg for the turning coordinate φ and a target tilt coordinate θg for the tilt coordinate θ, and correcting the target turning coordinate φg and the target tilt coordinate θg based on the first directly-facing turning coordinate φ1m and the first directly-facing tilt coordinate θ1m.

With this configuration, since the photovoltaic panel 10 is driven by applying the corrected target turning coordinate φgc and the corrected target tilt coordinate θgc that have been set through the correction based on the first directly-facing turning coordinate φ1m and the directly facing tilt coordinate θ1m, it is possible to correct a shift in position with ease and high precision before driving the photovoltaic panel 10.

Also, the following is a description of the case where the present embodiment is applied to the second operation pattern (step S29) of Embodiment 3.

The process for correcting a shift in the position of the photovoltaic panel 10 and driving the photovoltaic panel 10 (tracking control method for the tracking solar photovoltaic power generation system) according to Embodiment 3 is configured such that the photovoltaic panel 10 is driven by application of the corrected target turning coordinate φgc and the corrected target tilt coordinate θgc that have been set by specifying a targeted solar azimuth angle φs as a target solar azimuth angle φsg and a targeted solar altitude θs as a target solar altitude θsg, performing coordinate transformation using preset equations from the target solar azimuth angle φsg and the target solar altitude θsg to a target turning coordinate φg for the turning coordinate and a target tilt coordinate θg for the tilt coordinate, and correcting the target turning coordinate φg and the target tilt coordinate θg based on the second directly-facing turning coordinate φ2m and the second directly-facing tilt coordinate θ2m.

With this configuration, since the photovoltaic panel 10 is driven by applying the corrected target turning coordinate φgc and the corrected target tilt coordinate θgc that have been set through the correction based on the second directly-facing turning coordinate φ2m and the second directly-facing tilt coordinate θ2m, it is possible to correct a shift in position with ease and high precision before driving the photovoltaic panel 10.

Also, the following is a description of the case where the present embodiment is applied to the third operation pattern (step S39) of Embodiment 4.

The process for correcting a shift in the position of the photovoltaic panel 10 and driving the photovoltaic panel 10 (tracking control method for the tracking solar photovoltaic power generation system) according to Embodiment 4 is configured such that the photovoltaic panel 10 is driven by application of the corrected target turning coordinate φgc and the corrected target tilt coordinate θgc that have been set by specifying a targeted solar azimuth angle φs as a target solar azimuth angle φsg and a targeted solar altitude θs as a target solar altitude θsg, performing coordinate transformation using preset equations from the target solar azimuth angle φsg and the target solar altitude θsg into the target turning coordinate φg for the turning coordinate and the target tilt coordinate φg for the tilt coordinate, and correcting the target turning coordinate φg and the target tilt coordinate θg based on the third directly-facing turning coordinate φ3m and the third directly-facing tilt coordinate θ3m.

With this configuration, since the photovoltaic panel 10 is driven by applying the corrected target turning coordinate φgc and the corrected target tilt coordinate θgc that have been set through the correction based on the third directly-facing turning coordinate φ3m and the third directly-facing tilt coordinate θ3m, it is possible to correct a shift in position with ease and high precision before driving the photovoltaic panel 10.

### Sixth Embodiment

Next is a description of a tracking control method for a tracking solar photovoltaic power generation system according to Embodiment 6, given with reference to FIGS. 15 and 16.

FIG. 15 is a block diagram illustrating a schematic configuration of a tracking solar photovoltaic power generation system during operation, according to Embodiment 6.

A tracking solar photovoltaic power generation system is according to the present embodiment includes multiple tracking drive solar photovoltaic power generators 1 described in Embodiments 1 to 5. Specifically, the tracking solar photovoltaic power generation system is according to the present embodiment includes multiple tracking drive solar photovoltaic power generators 1, each of which includes a photovoltaic panel 10 that converts sunlight into electric power and a tracking control portion 12 that provides tracking control over the turning position and the tilt position of the photovoltaic panel 10 so that the photovoltaic panel can track the solar trajectory based on the turning coordinate φ and the tilt coordinate θa that have been set corresponding to the solar azimuth angle φs and the solar altitude θs.

The details of the tracking drive solar photovoltaic power generators 1 are similar to those of Embodiment 1, and therefore descriptions are primarily given regarding different points. A configuration is adopted in which the outputs of the multiple tracking drive solar photovoltaic power generators 1 are collected before entering the output side circuit breaker 25, and electric power is supplied via the electric power line 20c to the inverter 40. Specifically, the electric power monitoring board 20 is configured to provide centralized control by collecting electric power generated by the multiple photovoltaic panels 10.

A detection circuit 22 connected to each of the photovoltaic panels 10 is connected via the detection line 22b to the PC 30. Also, the tracking control portion 13 is configured to control each of the photovoltaic panels 10.

FIG. 16 is a block diagram illustrating a schematic configuration when performing the tracking control method for the tracking solar photovoltaic power generation system according to Embodiment 6.

The tracking control method for the tracking solar photovoltaic power generation system is according to the present embodiment is applied individually to each of the tracking drive solar photovoltaic power generators 1. Specifically, a configuration is adopted in which switches 21 are controlled so that only a tracking drive solar photovoltaic power generator 1 that is targeted for execution of the tracking control method is connected, so that the tracking control method described in any one of Embodiments 1 to 5 is performed sequentially on each of the tracking drive solar photovoltaic power generators 1.

The switches 21 can be controlled directly via the electric power monitoring board 20. A configuration is also possible in which a computer program for controlling the switches 21 is pre-installed on the PC 30 and a menu is displayed on the display screen of the PC 30, so that a targeted switch 21 can be selected from the menu (menu button). In addition, a simulated load 41 is connected via the output side circuit breaker 25, instead of the inverter 40.

That is, the tracking control method for the tracking solar photovoltaic power generation system is according to the present embodiment is configured such that the tracking control method for the tracking drive solar photovoltaic power generator 1 described in any one of Embodiments 1 to 5 is applied individually to each of the tracking drive solar photovoltaic power generators 1.

This configuration makes it possible to adjust a shift in position for each of the tracking drive solar photovoltaic power generators 1 and accordingly provide optimum tracking control over each of the tracking drive solar photovoltaic power generators 1, and therefore the overall tracking solar photovoltaic power generation system is can generate maximum electric power with high efficiency.

Moreover, in the case where the tracking control method for the tracking solar photovoltaic power generation system is according to the present embodiment is applied to each of the tracking drive solar photovoltaic power generators 1 (photovoltaic panels 10), no adverse effect is caused by the movement of the sun (sunlight conditions). Therefore, installation work for a tracking solar photovoltaic power generation system 1s, in which a large number of tracking drive solar photovoltaic power generators 1 are arranged, can be performed with considerable ease and high precision.

### Tracking Solar Photovoltaic Power Generation System and Tracking Shift Correction Method for Tracking Solar Photovoltaic Power Generation System

In the tracking solar photovoltaic power generation system, if an inverter operates under maximum power point tracking control (MPPT control), the output operating point of a photovoltaic panel 10 is caused to follow an optimum operating point. In the above-described embodiment illustrated in FIG. 1, the photovoltaic panel 10 is interconnected in one-to-one correspondence with the inverter, under which condition the output operating point is controlled. The inverter is configured to control output voltage Vp and output current Ip of the photovoltaic panel 10 in accordance with variations in the output of the photovoltaic panel 10. However, if tracking shift correction is performed with such a configuration of FIG. 1, the output current Ip or the output voltage Vp will not follow the correction operation because of under MPPT control. Thus, in order to avoid such a phenomenon and correct a tracking shift, the configuration as illustrated in FIG. 2 may be adopted. In the case of the above-described configuration in FIG. 2, however, since correction operations cannot be performed during interconnection, it is more preferable to adopt a configuration in which tracking shift correction can be performed while maintaining system interconnection without the need to use dedicated equipment such as a simulated load and eliminating the need to stop the tracking solar photovoltaic power generation system associated with tracking shift correction as well as causing no loss in the amount of generated electric power.

Accordingly, in the following embodiments, a tracking solar photovoltaic power generation system and a configuration for implementing a tracking shift correction method for that system will be described with reference to the drawings.

### Seventh Embodiment

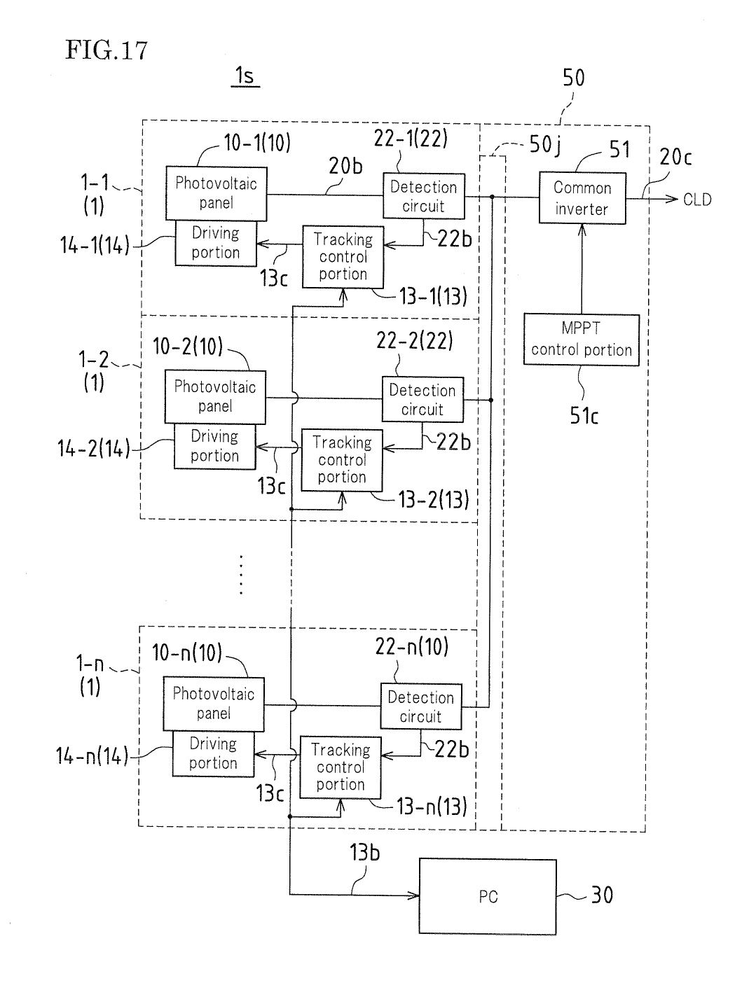

FIGS. 17 to 19 show a tracking solar photovoltaic power generation system according to Embodiment 7, and a tracking shift correction method for correcting a tracking shift occurring in a tracking drive solar photovoltaic power generator.

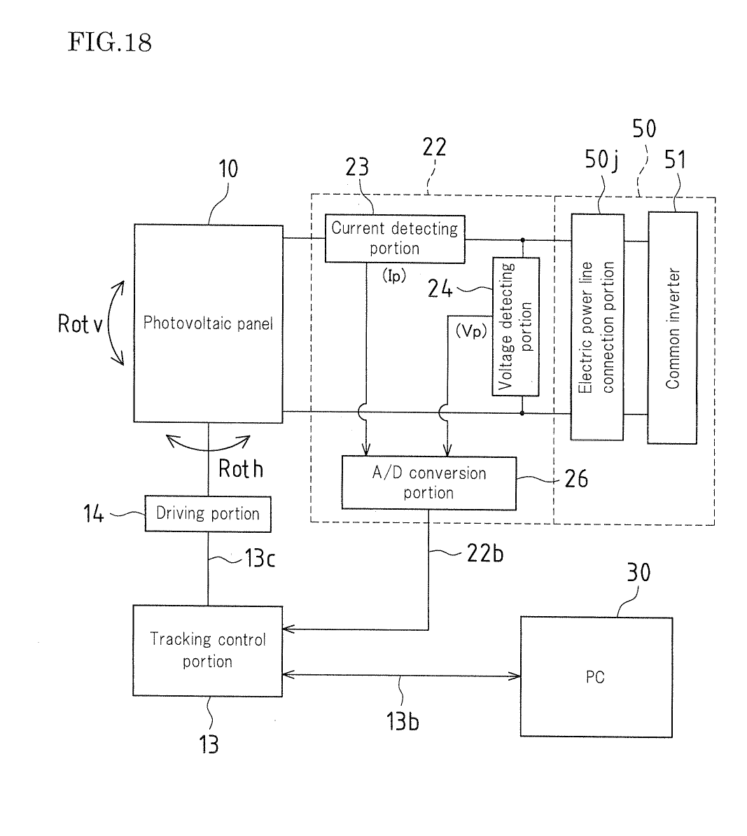

FIG. 17 is a block diagram illustrating a schematic configuration of the tracking solar photovoltaic power generation system according to Embodiment 7. FIG. 18 is a block diagram illustrating a schematic configuration of a tracking drive solar photovoltaic power generator constituting the tracking solar photovoltaic power generation system shown in FIG. 17.

The tracking shift correction method for the tracking solar photovoltaic power generation system according to the present embodiment is a method for correcting a tracking shift (shift in position during tracking control) relative to the solar trajectory in a tracking drive solar photovoltaic power generator 1 in a tracking solar photovoltaic power generation system is that includes multiple tracking drive solar photovoltaic power generators 1 that are arranged in parallel connection and a power conversion portion 50 that converts direct-current electric power generated by the tracking drive solar photovoltaic power generators 1 into alternating-current electric power and supplies the alternating-current electric power to an interconnection load CLD.

It should be noted that, as the multiple tracking drive solar photovoltaic power generators 1, tracking drive solar photovoltaic power generators 1-1, 1-2, . . . , and 1-n are arranged in parallel connection. Hereinafter, the tracking drive solar photovoltaic power generators 1-1, 1-2, . . . , and 1-n each may be simply referred to as a “tracking drive solar photovoltaic power generator 1” when there is no particular need to distinguish between those generators.

Each of the tracking drive solar photovoltaic power generators 1 (tracking drive solar photovoltaic power generators 1-1, 1-2, . . . , and 1-n) includes a photovoltaic panel 10 that converts sunlight into direct-current electric power and a driving portion 14 that drives the photovoltaic panel 10 based on tracking information that causes the photovoltaic panel 10 to track the solar trajectory.

Each of the tracking drive solar photovoltaic power generators 1 also includes a tracking control portion 13 that outputs the tracking information. In a steady state, information is transmitted and received between a PC 30 and the tracking control portion 13, based on indirect tracking information (e.g., indirect information about tracking, such as time information used as a reference and overall operation information) that has been pre-installed on the PC 30. The tracking control portion 13 transmits the tracking information (e.g., turning information and tilt information about the photovoltaic panel 10 based on the time information) to the driving portion 14 based on the indirect tracking information from the PC 30, and the driving portion 14 drives the photovoltaic panel 10 in the turning direction Roth and the tilt direction Rotv based on the tracking information (turning information and tilt information) so that the photovoltaic panel 10 can track the solar trajectory.

It should be noted that a photovoltaic panel 10-1 of the tracking drive solar photovoltaic power generator 1-1, a photovoltaic panel 10-2 of the tracking drive solar photovoltaic power generator 1-2, . . . , and a photovoltaic panel 10-n of the tracking drive solar photovoltaic power generator 1-n are arranged as photovoltaic panels 10. Hereinafter, each of the photovoltaic panels 10-1, 10-2, . . . , and 10-n may be simply referred to as a “photovoltaic panel 10” when there is no particular need to distinguish between those panels.

It should also be noted that a tracking control portion 13-1 of the tracking drive solar photovoltaic power generator 1-1, a tracking control portion 13-2 of the tracking drive solar photovoltaic power generator 1-2, . . . , and a tracking control portion 13-n of the tracking drive solar photovoltaic power generator 1-n are arranged as tracking control portions 13. Hereinafter, each of the tracking control portions 13-1, 13-2, . . . , and 13-n may be simply referred to as a “tracking control portion 13” when there is no particular need to distinguish between those portions.

Note that a configuration is also possible in which the tracking control portions 13-1, 13-2, . . . , and 13-n are organized into appropriate groups and arranged as tracking control portions 13 outside the tracking drive solar photovoltaic power generators 1. In this case, wiring needs to be provided as appropriate between the tracking drive solar photovoltaic power generators 1 and the appropriately organized tracking control portions 13. It should be noted that the tracking information itself is, of course, generated corresponding to each of the tracking drive solar photovoltaic power generators 1 and transmitted via wiring to each of the tracking drive solar photovoltaic power generators 1.

Moreover, a driving portion 14-1 of the tracking drive solar photovoltaic power generator 1-1, a driving portion 14-2 of the tracking drive solar photovoltaic power generator 1-2, . . . , and a driving portion 14-n of the tracking drive solar photovoltaic power generator 1-n are arranged as driving portions 14. Hereinafter, each of the driving portions 14-1, 14-2, . . . , and 14-n may be simply referred to as a “driving portion 14” when there is no particular need to distinguish between those driving portions.

In the present embodiment, a configuration is adopted in which a tracking shift of a photovoltaic panel 10 that is targeted for tracking shift correction is detected in a state in which the corresponding tracking drive solar photovoltaic power generator 1 is running by being connected to the power conversion portion 50.

For example, a tracking control portion 13 (any one of the tracking control portions 13-1, 13-2, . . . , and 13-n corresponding to the photovoltaic panels 10-1, 10-2, . . . , and 10-n) corresponding to a photovoltaic panel 10 (any one of the photovoltaic panels 10-1, 10-2, . . . , and 10-n) that is targeted for tracking shift correction is configured to detect a tracking shift of the photovoltaic panel 10 in a state in which the corresponding tracking drive solar photovoltaic power generator 1 (photovoltaic panel 10) is running by being connected to the power conversion portion 50 (which will be described in more detail in Embodiment 8). That is, a tracking shift is detected by a tracking control portion 13.

In other words, since a tracking shift of a photovoltaic panel 10 can be detected with the photovoltaic panel 10 being connected to the power conversion portion 50, a tracking shift of the photovoltaic panel 10 can be corrected in a state in which system interconnection is maintained while continuing electric power generation by the corresponding tracking drive solar photovoltaic power generator 1 and electric power supply from the power conversion portion 50 to the interconnection load CLD. It is thus possible to provide a highly reliable and productive tracking shift correction method that eliminates the need to stop the tracking solar photovoltaic power generation system is associated with tracking shift correction and causes no loss in the amount of generated electric power.

As described above, each of the tracking drive solar photovoltaic power generators 1 is provided with a tracking control portion 13 that outputs tracking information, and a tracking shift is detected by the tracking control portion 13.

Accordingly, a tracking shift can be detected and corrected individually for each of the tracking drive solar photovoltaic power generators 1. This enables the tracking control portions 13 to be dispersed in the tracking solar photovoltaic power generation system 1s, thereby simplifying a wiring structure of a control system and accordingly simplifying installation work. It is thus possible to provide a highly reliable tracking solar photovoltaic power generation system is at low cost.

It should be noted that the driving portion 14 is configured to correct a tracking shift of the photovoltaic panel 10 in accordance with a tracking shift detected by the tracking control portion 13 (which will be described in more detail in Embodiment 8).

The output (direct-current electric power) of each photovoltaic panel 10 is supplied via an electric power line 20b and the detection circuit 22 to the power conversion portion 50. Note that a detection circuit 22-1 that detects the output of the photovoltaic panel 10-1, a detection circuit 22-2 that detects the output of the photovoltaic panel 10-2, . . . , and a detection circuit 22-n that detects the output of the photovoltaic panel 10-n are arranged as detection circuits 22. Hereinafter, each of the detection circuits 22-1, 22-2, . . . , and 22-n may be simply referred to as a “detection circuit 22” when there is no particular need to distinguish between those circuits.

Each of the tracking drive solar photovoltaic power generators 1 includes the detection circuit 22 that detects the output (output current Ip, output voltage Vp) of the photovoltaic panel 10, and the tracking control portion 13 is configured to detect a tracking shift based on the output of the photovoltaic panel 10 detected by the detection circuit 22. This configuration makes it possible to detect the output of the photovoltaic panel 10 with ease and high precision, thus enabling a tracking shift of the photovoltaic panel 10 to be detected and corrected with ease and high precision.

In a steady state, the tracking control portion 13 controls the driving portion 14 by acquiring tracking information (indirect tracking information) from the PC 30 and transmitting the tracking information to the driving portion 14. However, when correcting a tracking shift, the tracking control portion 13 has the function of detecting a tracking shift based on the output (output current Ip and output voltage Vp) detected by the detection circuit 22.

The power conversion portion 50 according to the present embodiment includes an electric power line connection portion 50j that collects the outputs (direct-current electric power) of the multiple tracking drive solar photovoltaic power generators 1 by connecting them in parallel, and a common inverter 51 that converts the direct-current electric power received from the electric power line connection portion 50j collectively into alternating-current electric power. The common inverter 51 (power conversion portion 50) supplies the generated alternating-current electric power to the interconnection load CLD via an electric power line 20c.

That is, the power conversion portion 50 includes the common inverter 51 that is connected so as to convert direct-current electric power that is output from each of the photovoltaic panels 10 collectively into alternating-current electric power and supply the resultant alternating-current electric power to the interconnection load CLD.

Accordingly, the multiple tracking drive solar photovoltaic power generators 1 are operated by being connected to the single common inverter 51. This simplifies the configuration of the power conversion portion 50 and stabilizes the operating voltage with direct-current electric power, thus enabling a tracking shift to be detected with ease and high precision.

It should be noted that a backflow preventing component (not shown; e.g., an anti-backflow diode or a fuse) is connected between the output line detecting portion 22 of each photovoltaic panel 10 and the electric power line connection portion 50j. It is thus possible to provide output at a common voltage (optimum output voltage Vpj), irrespective of variations in the output of the photovoltaic panel 10.

The common inverter 51 includes an MPPT control portion 51c (not shown in FIG. 18) that provides MPPT (maximum power point tracking) control over the photovoltaic panels 10. It should be noted that the MPPT control portion 51c is configured to operate integrally with the common inverter 51.

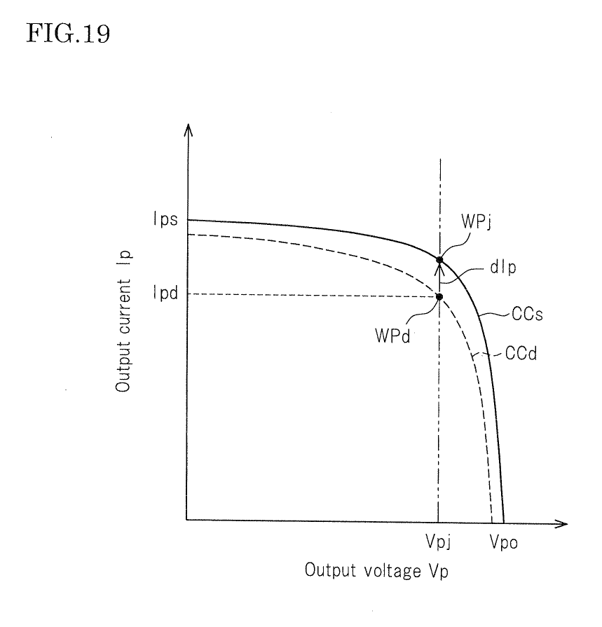

MPPT control is a control method in which the output electric power (output voltage Vp×output current Ip; see FIG. 19 for the characteristics of the output electric power) of a photovoltaic panel 10 is measured at fixed time intervals and compared with the previous measured value, and the output voltage Vp is changed always in a direction toward greater output electric power, so that the operating point of the photovoltaic panel can follow a maximum power point (see optimum operating point WPj in FIG. 19). In the present embodiment, conventionally known MPPT control can be applied as-is, and therefore detailed descriptions thereof have been omitted.

Specifically, the common inverter 51 is configured to cause the output operating points of the parallel-connected photovoltaic panels 10 (tracking drive solar photovoltaic power generators 1) to follow the optimum operating point WPj under maximum power point tracking control (MPPT control). This configuration makes it possible to correct a tracking shift at the optimum operating point WPj (optimum output voltage Vpj) in the tracking solar photovoltaic power generation system 1s, thus enabling a tracking shift to be corrected with ease and high precision under stable operating conditions.

Each detection circuit 22 includes a current detecting portion 23 that detects the output current Ip of the photovoltaic panel 10. This makes it possible to detect the output current Ip of the photovoltaic panel 10 with ease and high precision, thus enabling a tracking shift of the photovoltaic panel 10 to be corrected with ease and high precision.

Each detection circuit 22 also includes a voltage detecting portion that detects the output voltage of the photovoltaic panel 10. This makes it possible to detect the output voltage Vp of the photovoltaic panel 10 with ease and high precision, thus enabling a tracking shift of the photovoltaic panel 10 to be corrected with ease and high precision.

It should be noted that, since the output current Ip detected by the current detecting portion 23 and the output voltage Vp detected by the voltage detecting portion 24 are analog data, they are converted by an A/D conversion portion 26 into digital data that can be handled in the computation processing performed by the tracking control portion 13 and transmitted via a detection line 22b to the tracking control portion 13, in which data processing (computation processing) for correcting a tracking shift is then performed.

In the present embodiment, tracking drive and tracking shift correction are performed in a configuration in which a tracking control portion 13 is arranged corresponding to each of the tracking drive solar photovoltaic power generators 1 (photovoltaic panels 10), and tracking information (turning information and tilt information regarding a photovoltaic panel 10) generated by the tracking control portion 13 is transmitted to the driving portion 14. In other words, centralized control by the PC 30 is eliminated and each of the tracking drive solar photovoltaic power generators 1 (tracking control portions 13) performs distributed processing. This simplifies communication wiring among the tracking control portions 13, the detection circuits 22, and the PC 30, and reduces communication noise and the amount of communication data, thus enabling provision of highly reliable tracking control.

FIG. 19 is a characteristic graph showing a VI characteristic curve representative of the output state of a photovoltaic panel in the tracking solar photovoltaic power generation system shown in FIG. 17.

Note that the horizontal axis indicates the output voltage Vp of the photovoltaic panel 10, whereas the vertical axis indicates the output current Ip of the photovoltaic panel 10. Therefore, a VI characteristic curve CCs is specified in accordance with sunlight irradiation conditions on the photovoltaic panel 10.

In a normal operating state, the output operating point of the photovoltaic panel 10 is on the VI characteristic curve CCs, and the operating point is caused to follow the optimum operating point WPj under the control of the MPPT control portion 51c (MPPT control). Note that the output voltage Vp=Vpo indicates an open-circuit voltage, and the output current Ip=Ips indicates a short-circuit current.

Specifically, the output operating point of the photovoltaic panel 10 during normal operation, under MPPT control by the common inverter 51, is positioned at the optimum operating point WPj on the VI characteristic curve CCs that corresponds to the sunlight irradiation conditions at that time, and the output voltage Vp is controlled to be the optimum output voltage Vpj.

In the present embodiment, electric power is supplied to the common inverter 51 in a state in which multiple (e.g., 10 or more) tracking drive solar photovoltaic power generators 1 are connected in parallel. Therefore, the output voltages Vp of all tracking drive solar photovoltaic power generators 1 (photovoltaic panels 10) match the optimum output voltage Vpj under the control of the MPPT control portion 51c.

For example, when a tracking shift occurs during tracking control over the tracking drive solar photovoltaic power generator 1-1 (photovoltaic panel 10-1), the output of the photovoltaic panel 10-1 is reduced and the VI characteristic curve is changed into a tracking shift VI characteristic curve CCd. That is, the short circuit current on the VI characteristic curve CCd is is reduced to less than Ips, whereas the open-circuit voltage on the VI characteristic curve CCd is reduced to less than Vpo. Even with such a change of the VI characteristic curve into the tracking shift VI characteristic curve CCd, the output voltage Vp is maintained at the optimum output voltage Vpj because the overall tracking solar photovoltaic power generation system is under MPPT control.

From the above, the photovoltaic panel 10-1 operates at a tracking shift operating point WPd (output voltage Vp=optimum output voltage Vpj) on the tracking shift VI characteristic curve CCd because its output is reduced, and so the output current Ip is reduced to a tracking shift output current Ipd.

In other words, even if a single tracking drive solar photovoltaic power generator 1, out of 10 or more connected tracking drive solar photovoltaic power generators 1, causes a tracking shift, there is a small influence on the output voltage Vp (in short, one tenth or less; the influence becomes smaller if the number of connected generators increases), so that it is easy to maintain the optimum output voltage Vpj.

At the occurrence of a tracking shift, the tracking control portion 13 is capable of detecting the tracking shift by the output of the detection circuit 22. Since the common inverter 51 is under MPPT control, the output voltage Vp can be maintained at the optimum output voltage Vpj. Therefore, a tracking shift is usually detected from variations in the output current Ip. It should be noted that it is also possible to detect a tracking shift by detecting variations in the output voltage Vp, in the same way as detecting variations in the output current Ip.

The tracking control portion 13 performs computation processing on the output of the detection circuit 22 by using, for example, equations pre-installed on the PC 30, and detects a tracking shift (magnitude of tracking shift) from the output of the detection circuit 22. The driving portion 14 corrects a tracking shift of the photovoltaic panel 10 in accordance with the tracking shift obtained by the tracking control portion 13. A specific tracking shift method will be described in more detail in Embodiment 8.

That is, in the tracking solar photovoltaic power generation system is according to the present embodiment, it is possible to detect a tracking shift of each photovoltaic panel 10 individually based on the output data (output current Ip, output voltage Vp) detected by each detection circuit 22 and to correct the tracking shift of each photovoltaic panel 10 individually based on the detection results.

After tracking shift correction is performed on the tracking drive solar photovoltaic power generator 1-1 (photovoltaic panel 10-1), the output of the photovoltaic panel 10-1 returns from the tracking shift VI characteristic curve CCd to the VI characteristic curve CCs. Accordingly, the output current Ip of the photovoltaic panel 10-1 is increased as indicated by the arrow dIp with the output voltage Vp at the optimum output voltage Vpj, and the operating point returns from the tracking shift operating point WPd (tracking shift VI characteristic curve CCd) to the optimum operating point WPj (VI characteristic curve CCs).

As described above, in the tracking shift correction method for the tracking solar photovoltaic power generation system according to the present embodiment, a configuration is adopted in which the common inverter 51 (power conversion portion 50) and the tracking drive solar photovoltaic power generators 1 (photovoltaic panels 10) run, and a tracking shift of a photovoltaic panel 10 (e.g., photovoltaic panel 10-1) that is selected as a target for tracking shift correction is corrected while the photovoltaic panel kept connected to the common inverter 51.

With this configuration, since a tracking shift of a photovoltaic panel 10 targeted for correction is corrected while the photovoltaic panel kept connected to the common inverter 51, a tracking shift in the tracking solar photovoltaic power generation system 1s can be corrected in a state in which the system interconnection is maintained while continuing electric power generation by the tracking drive solar photovoltaic power generators 1 and electric power supply from the common inverter 51 to the interconnection load CLD. It is thus possible to provide a highly reliable and productive tracking shift correction method that eliminates the need to stop the system associated with tracking shift correction and causes no loss in the amount of generated electric power.

Moreover, as described above, the common inverter 51 is configured to cause the output operating points of the photovoltaic panels 10 to follow the optimum operating point WPj under MPPT control (maximum power point tracking control). This configuration makes it possible to correct a tracking shift in a state in which the tracking solar photovoltaic power generation system is (photovoltaic panels 10) is operated at the optimum operating point WPj (optimum output voltage Vpj corresponding to the optimum operating point WPj), thus enabling a tracking shift to be corrected with ease and high precision under stable operating conditions.

In other words, in the tracking shift correction method for the tracking solar photovoltaic power generation system according to the present embodiment, a tracking shift is corrected in a state in which the output voltage Vp of each photovoltaic panel 10 is maintained at the optimum output voltage Vpj under MPPT control of the common inverter 51. Since a tracking shift can be corrected in a state in which the output voltage Vp of each photovoltaic panel 10 is held at the optimum output voltage Vpj by the common inverter 51, it is possible to correct a tracking shift with ease and high precision.

As described above, the tracking solar photovoltaic power generation system is according to the present embodiment includes multiple tracking drive solar photovoltaic power generators 1 that are arranged in parallel connection, and the power conversion portion 50 that converts direct-current electric power generated by the tracking drive solar photovoltaic power generators 1 into alternating-current electric power and supplies the alternating-current electric power to the interconnection load CLD.

Also in the tracking solar photovoltaic power generation system 1s, each of the tracking drive solar photovoltaic power generators 1 includes the photovoltaic panel 10 that converts sunlight into direct-current electric power, and the driving portion 14 that drives the photovoltaic panel 10 based on the tracking information causing the photovoltaic panel 10 to track the solar trajectory, and a configuration is adopted in which a tracking shift of a photovoltaic panel 10 that is targeted for tracking shift correction is detected in a state in which the corresponding tracking drive solar photovoltaic power generator 1 is running by being connected to the power conversion portion 50.

Since a tracking shift of a photovoltaic panel 10 is detected in a state in which the corresponding tracking drive solar photovoltaic power generator 1 is running by being connected to the power conversion portion 50, it is possible to provide a highly reliable and productive tracking solar photovoltaic power generation system is that eliminates the need to be stopped associated with tracking shift correction and causes no loss in the amount of generated electric power.

Also, the power conversion portion 50 includes the common inverter 51 that is connected so as to convert direct-current electric power that is output from each of the photovoltaic panels 10 collectively into alternating-current electric power supply and supplies the resultant alternating-current electric power to the interconnection load CLD.

This simplifies the configuration of the power conversion portion 50 and stabilizes the operating voltage with direct-current electric power, thus enabling a tracking shift to be detected with ease and high precision.

### Eighth Embodiment

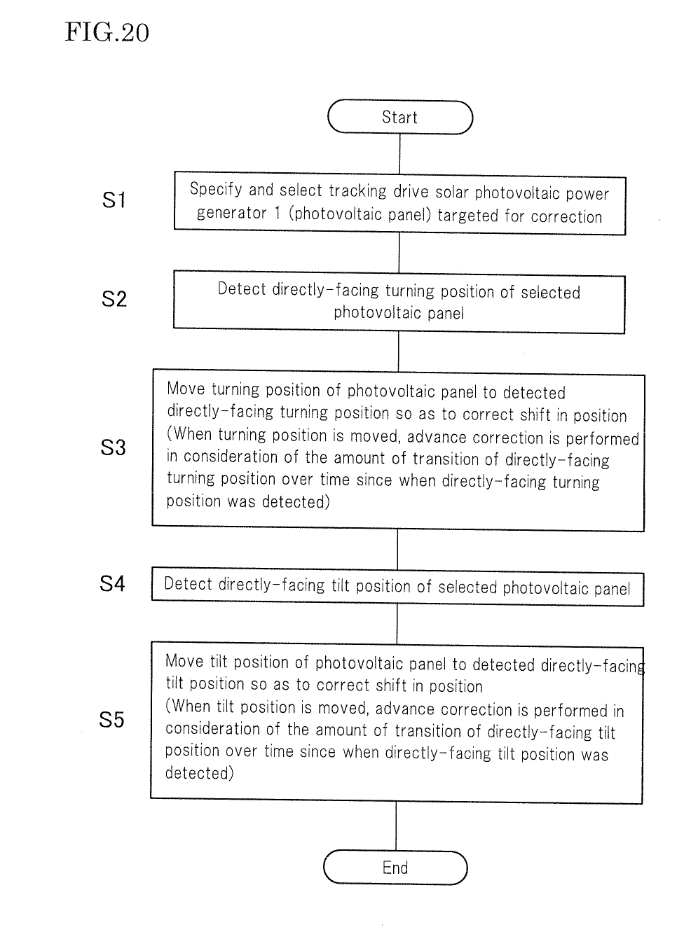

Next, the details of the tracking correction step and the operations of the tracking control portion 13 and the driving portion 14 in the tracking solar photovoltaic power generation system is, in the tracking shift correction method for the tracking solar photovoltaic power generation system according to the Embodiment 7, will be described with reference to FIGS. 20 to 22 as Embodiment 8 of the present invention. It should be noted that the procedure of the tracking correction step is not limited to the one described in the present embodiment and other procedures are also applicable.

FIG. 20 is a flowchart showing the procedure for correcting a tracking shift in a tracking shift correction method for a tracking solar photovoltaic power generation system according to Embodiment 8.

A tracking shift (shift in position during tracking control) of a tracking drive solar photovoltaic power generator 1 (photovoltaic panel 10) can be corrected through the following steps S1 to S5 in the tracking shift correction method according to the present embodiment.

Specifically, a tracking drive solar photovoltaic power generator 1 that is targeted for correction is selected in step S1. Next, a directly-facing turning position in the turning direction is detected (a tracking shift in a turning direction Roth is detected) in step S2, and the tracking shift in the turning direction is corrected (the turning position is moved to a directly-facing turning position Phj) in step S3. Thereafter, a directly-facing tilt position in the tilt direction is detected (a tracking shift in a tilt direction Rotv is detected) in step S4, and the tracking shift in the tilt direction is corrected (the tilt direction is moved to a directly-facing tilt position Phv) in step S5.

It should be noted that the directly-facing turning position indicates a position in which the photovoltaic panel 10 directly faces the solar trajectory in the turning direction Roth, and the directly-facing tilt position indicates a position in which the photovoltaic panel 10 directly faces the solar trajectory in the tilt direction Rotv. Hereinafter, each step will be described in more detail.

### Step S1:

A tracking drive solar photovoltaic power generator 1 (photovoltaic panel 10) that is targeted for correction is specified and selected. For example, the output current Ip detected by a current detecting portion 23 is sampled at regular intervals and compared with the output current Ip detected by another current detecting portion 23, and a tracking drive solar photovoltaic power generator 1 having a low current value can be selected as one with a tracking shift.

For example, a tracking shift on the order of 0.2° causes approximately a 10% drop in output, and such a drop in output appears intact as a reduction in the output current Ip because the output voltage Vp is adjusted at the optimum voltage Vpj under MPPT control. Therefore, the drop in output can be detected with ease and high precision by the current detecting portion 23.

That is, a photovoltaic panel 10 with a tracking shift (e.g., the photovoltaic panel 10-1, which is hereinafter simply referred to as a “photovoltaic panel 10”) can be detected with ease and high precision by inter-comparison of the output current Ip detected by a current detecting portion 23 with the output currents Ip detected by other multiple current detecting portions 23 of the tracking drive solar photovoltaic power generators 1.

It should be noted that, although the following description gives the case where the output current Ip is targeted for detection, similar processing may also be possible using the output voltage Vp as a target for detection. It should also be noted that, since variations in the output voltage Vp are weak under MPPT control, it is desirable that a higher-precision voltage detection method be employed.

### Step S2:

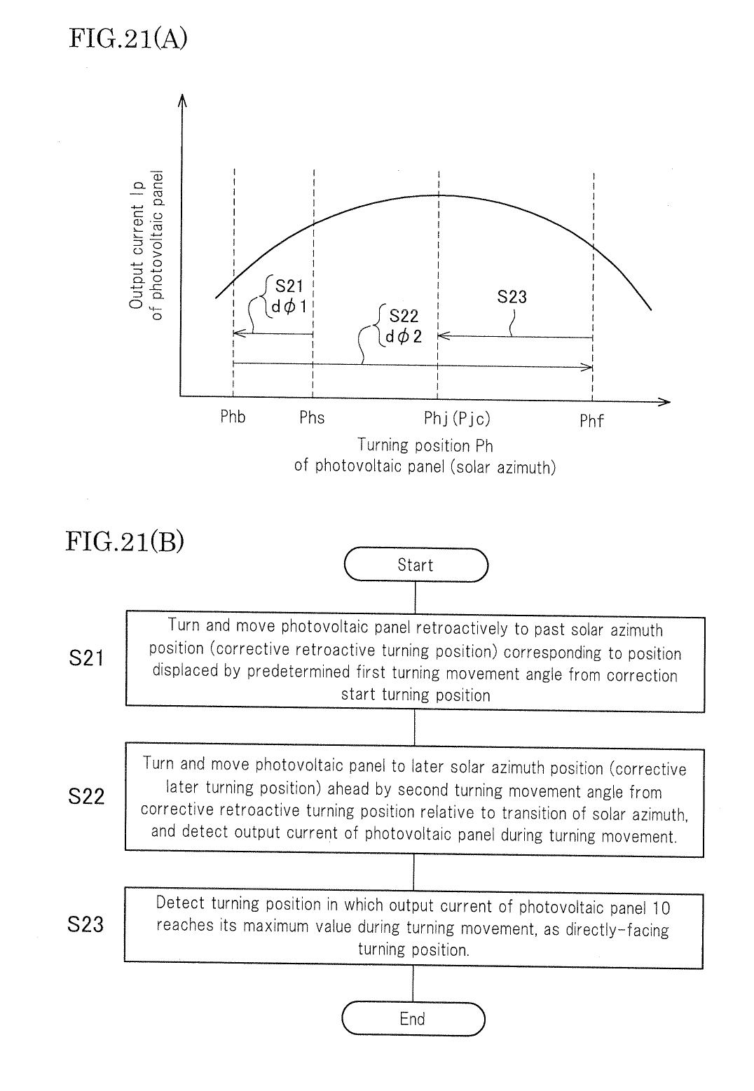

The directly-facing turning position Phj (see FIG. 21(A)) of the selected photovoltaic panel 10 is detected. Specifically, a tracking shift in the turning direction Roth is detected by detecting the directly-facing turning position Phj.

The tracking control portion 13 can detect a tracking shift (tracking shift amount, tracking shift direction) of the photovoltaic panel 10 by performing computation processing on the output current Ip detected by the current detecting portion 23.

As a method for detecting a tracking shift, various methods are applicable and one example is shown in FIGS. 21(A) and 21(B), which will be described later.

### Step S3:

The turning position of the photovoltaic panel 10 that is targeted for correction is moved to the detected directly-facing turning position Phj so as to correct a tracking shift (shift in position) in the turning direction Roth. Specifically, the driving portion 14 corrects a tracking shift of the photovoltaic panel 10 in accordance with the tracking shift (tracking shift amount, tracking shift direction) detected by the tracking control portion 13.

It should be noted that, when the turning position of the photovoltaic panel 10 is moved to the detected directly-facing turning position Phj, the accuracy in correcting a tracking shift can further be increased if the amount of transition of the directly-facing turning position Phj over time since the directly-facing turning position Phj was detected is corrected in advance.

### Step S4:

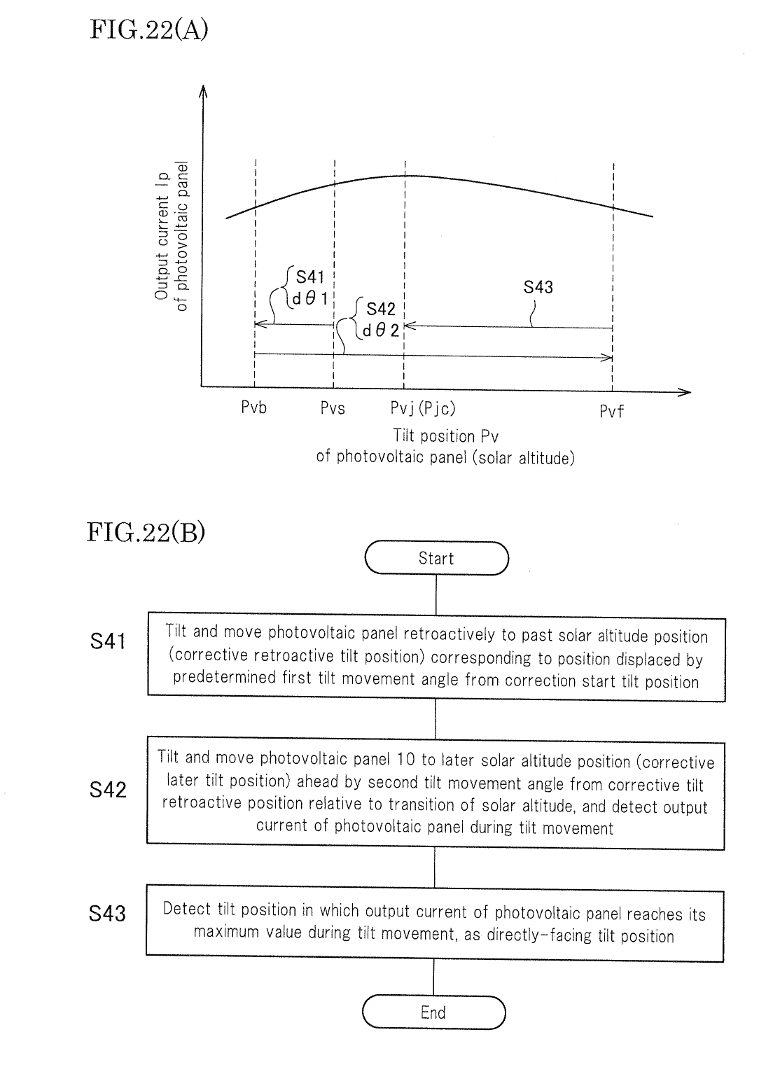

A directly-facing tilt position Pvj (see FIG. 22(A)) of the selected photovoltaic panel 10 is detected. Specifically, a tracking shift in the tilt direction Rotv is detected by detecting the directly-facing tilt position Pvj.

The tracking control portion 13 can detect a tracking shift of the photovoltaic panel 10 (tracking shift amount, tracking shift direction) by performing computation processing on the output current Ip detected by the current detecting portion 23.

As a method for detecting a tracking shift, various methods are applicable and one example is shown in FIGS. 22(A) and 22(B), which will be described later.

### Step S5:

The tilt position of the photovoltaic panel 10 that is targeted for correction is moved to the detected directly-facing tilt position Pvj so as to correct a tracking shift (shift in position) in the tilt direction Rotv. Specifically, the driving portion 14 corrects a tracking shift of the photovoltaic panel 10 in accordance with the tracking shift (tracking shift amount, tracking shift direction) detected by the tracking control portion 13.

It should be noted that, when the tilt position of the photovoltaic panel 10 is moved to the detected directly-facing tilt position Pvj, the accuracy in correcting a tracking shift can further be increased if the amount of transition of the directly-facing tilt position Pvj over time since the directly-facing tilt position Pvj was detected is corrected in advance.

As described above, tracking shift correction is implemented by determining a directly-facing position Pjc (directly-facing turning position Phj and directly-facing tilt position Pvj which may be simply referred to as a “directly-facing position Pjc” when there is no particular need to distinguish between the directly-facing turning position Phj and the directly-facing tilt position Pvj) in which the photovoltaic panel 10 directly faces the solar trajectory, through detection of the output current Ip (or output voltage Vp) of the photovoltaic panel 10, and causing the photovoltaic panel 10 to track and move to the determined directly-facing position Pjc.

Specifically, the tracking control portion 13 is configured to detect a tracking shift of the photovoltaic panel 10 based on the output current Ip (output voltage Vp) detected by the current detecting portion 23 (voltage detecting portion 24), and the driving portion 14 is configured to correct a tracking shift of the photovoltaic panel 10 in accordance with the tracking shift (shift in position relative to the directly-facing position Pjc) detected by the tracking control portion 13.

In the case where a tracking shift is detected based on the output current Ip, the tracking shift is corrected by applying variations in the output current IP that is responsive to a tracking shift. It is thus possible to determine the directly-facing position Pjc, in which the photovoltaic panel 10 directly faces the solar trajectory, with ease and high precision and to thereby correct a tracking shift with ease and high precision.

In the case where a tracking shift is detected based on the output voltage Vp, the tracking shift is corrected by applying variations in the output voltage Vp that is responsive to a wide range of tracking shifts. It is thus possible to determine the directly-facing position Pjc, in which the photovoltaic panel 10 directly faces the solar trajectory, with ease and high precision and to thereby correct a tracking shift with ease and high precision.

In addition, the directly-facing position Pjc is adaptable to either of the turning direction Roth and the tilt direction Rotv, as described above.

That is, the directly-facing position Pjc may be determined as a directly-facing turning position Phj that is the directly-facing position in the turning direction Roth. It is thus possible to correct a tracking shift in the turning direction Roth with ease and high precision.

Also, the directly-facing position Pjc may be determined as a directly-facing tilt position Pvj that is the directly-facing position in the tilt direction Rotv. It is thus possible to correct a tracking shift in the tilt direction Rotv with ease and high precision.

As described above, a tracking shift of the photovoltaic panel 10 that may occur during tracking control includes a tracking shift in the turning direction Roth and a tracking shift in the tilt direction Rotv. However, a tracking shift in the turning direction Roth is more likely to occur in general practice. Specifically, at the time of construction, although alignment in the tilt direction Rotv can be accomplished with relatively high precision, alignment in the turning direction Roth is more difficult to be accomplished than the alignment in the tilt direction Rotv. Therefore, a tracking shift is more likely to occur in the turning direction Roth.

For this reason, in the present embodiment a configuration may also be adopted in which the processing for correcting a tracking shift of a photovoltaic panel 10 is ended with only steps S1 to S3. Alternatively, steps S2 to S5 may be repeated for further improvement in accuracy.

It should be noted that a computer program for implementing the procedure of steps S1 to S5 may be pre-installed on the tracking control portion 13 and the PC 30 in order to ease the implementation.

FIG. 21 is a diagram for explaining the procedure for detecting a tracking shift in the turning direction, in the flowchart shown in FIG. 20, FIG. 21(A) being a graph showing the relationship between the turning position and the output current, FIG. 21(B) being a flowchart showing the procedure.

In FIG. 21(A), the horizontal axis indicates the turning position Ph of the photovoltaic panel 10, whereas the vertical axis indicates the output current Ip of the photovoltaic panel 10.

The directly-facing turning position Phj (directly-facing position Pjc) described in step S2 can be detected through steps S21 to S23. It should be noted that the method for detecting the directly-facing turning position Phj is not limited to the method described with reference to steps S21 to S23, and various methods are applicable as described in step S2.

### Step S21:

The photovoltaic panel 10 is turned and moved retroactively to a past solar azimuth position (corrective retroactive turning position Phb) that corresponds to a position displaced by a predetermined first turning movement angle dφ1 from a correction start turning position Phs. FIG. 21(A) shows the case where the output current Ip is reduced due to an increased tracking shift associated with the turning movement.

### Step S22:

The photovoltaic panel 10 is turned and moved to a later solar azimuth position (corrective later turning position Phf) ahead by a second turning movement angle dφ2 from the corrective retroactive turning position Phb relative to the transition of the solar azimuth, during which the output current Ip of the photovoltaic panel 10 is detected.

The output current Ip describes an angular curve having a maximum value in accordance with the turning movement. Specifically, a position having a maximum value is the solar azimuth angle at which the photovoltaic panel 10 directly faces the sun.

### Step S23:

A turning position Ph in which the output current Ip of the photovoltaic panel 10 during the turning movement reaches its maximum value is detected as a directly-facing turning position Phj. Specifically, the turning position Ph in which the output current Ip reaches its maximum value is determined as the directly-facing turning position Phj (directly-facing position Pjc).

The tracking control portion 13 is capable of detecting a shift in position from the relationship between the output current Ip detected by the current detecting portion 23 and the turning position Ph. That is, a tracking shift (tracking shift amount, tracking shift direction) is detected based on a difference (difference in position) between the directly-facing turning position Phj and the turning position Ph (e.g., the correction start turning position Phs or the corrective later turning position Phf).

The tracking control portion 13 also supplies information (turning position information and tilt position information) for correcting the detected tracking shift to the driving portion 14, and the driving portion 14 adjusts (drives) the turning position and tilt position of the photovoltaic panel 10 according to the information received from the tracking control portion 13.

It should be noted that, although the case where a tracking shift in the turning direction Roth is detected by detecting variations in the output current Ip has been described in FIG. 21, detecting variations in the output voltage Vp in order to detect a tracking shift in the turning direction Roth is also possible as well.

FIG. 22 is a diagram for explaining the procedure for detecting a tracking shift in the tilt direction, in the flowchart shown in FIG. 20, FIG. 22(A) being a graph showing the relationship between the tilt position and the output current, FIG. 22(B) being a flowchart showing the procedure.

In FIG. 22(A), the horizontal axis indicates the tilt position Pv of the photovoltaic panel 10, whereas the vertical axis indicates the output current Ip of the photovoltaic panel 10.

The directly-facing tilt position Pvj (directly-facing position Pjc) described in step S4 can be detected through the following steps S41 to S43. It should be noted that the method for detecting the directly-facing tilt position Pvj is not limited to the method including steps S31 to S43, and various methods are also applicable as described in step S4.

### Step S41:

The photovoltaic panel 10 is tilted and moved retroactively to a past solar altitude position (corrective retroactive tilt position Pvb) that corresponds to a position displaced by a predetermined first tilt movement angle dθ1 from a correction start tilt position Pvs. FIG. 22(A) shows the case where the output current Ip is reduced due to an increased tracking shift associated with the tilt movement.

### Step S42:

The photovoltaic panel 10 is tilted and moved to a later solar altitude position (corrective later tilt position Pvf) ahead by a second tilt movement angle dθ2 from the corrective tilt retroactive position Pvb relative to the transition of the solar altitude, during which the output current Ip of the photovoltaic panel 10 is detected.

The output current Ip describes an angular curve having a maximum value in accordance with the tilt movement. Specifically, a position in which the output current reaches its maximum value is the solar altitude at which the photovoltaic panel 10 is to face directly the sun.

### Step S43:

A tilt position Pv in which the output current Ip of the photovoltaic panel 10 reaches its maximum value during the tilt movement is detected as a directly-facing tilt position Pvj. That is, the tilt position Pv in which the output current Ip reaches its maximum value is determined as a directly-facing tilt position Pvj (directly-facing position Pjc).

The operations of the tracking control portion 13 and the driving portion 14 are similar to those in the case of FIG. 21.

It should be noted that, although the case where a tracking shift in the tilt direction Rotv is detected by detecting variations in the output current Ip has been described in FIG. 22, detecting variations in the output voltage Vp in order to detect a tracking shift in the tilt direction Rotv is also possible as well.

As described above, in the tracking shift correction method for the tracking solar photovoltaic power generation system according to the present embodiment, a shift in position is corrected by determining the directly-facing position Pjc in which the photovoltaic panel 10 directly faces the solar trajectory, based on the output current Ip detected by the current detecting portion 23 (computation processing performed by the tracking control portion 13), and then moving the photovoltaic panel 10 to the directly-facing position Pjc (control over the tracking direction of the photovoltaic panel 10, performed by the driving portion 14).

Thus, a tracking shift is corrected by applying variations in the output current Ip that is sensitively responsive to a tracking shift. It is thus possible to determine the directly-facing position Pjc, in which the photovoltaic panel 10 directly faces the solar trajectory, with ease and high precision and to thereby correct a tracking shift with ease and high precision.

Alternatively, in the tracking shift correction method for the tracking solar photovoltaic power generation system according to the present embodiment, a shift in position may be corrected by determining the directly-facing position Pjc in which the photovoltaic panel 10 directly faces the solar trajectory, based on the output voltage Vp detected by the voltage detecting portion 24, and then moving the photovoltaic panel 10 to the directly-facing position Pjc.

Thus, a tracking shift is corrected by applying variations in the output voltage that is responsive to a wide range of tracking shifts. It is thus possible to determine the directly-facing position Pjc, in which the photovoltaic panel 10 directly faces the solar trajectory, with ease and high precision and to thereby correct a tracking shift with ease and high precision.

### Ninth Embodiment

In Embodiments 7 and 8 described above, the common inverter 51 is operated under MPPT control by the MPPT control portion 51c. A tracking shift correction method for a tracking solar photovoltaic power generation system according to the present embodiment is a method for correcting a tracking shift regardless of the MPPT control portion 51c. It should be noted that the basic configuration is similar to those described in Embodiments 7 and 8, and therefor the same reference numerals are used as appropriate.

In accordance with the tracking shift correction method for the tracking solar photovoltaic power generation system according to the present embodiment, the common inverter 51 does not provide MPPT control. Specifically, the common inverter 51 is configured to be operated under constant voltage control, instead of under MPPT control by the MPPT control portion 51c, and hold the output operating point of a photovoltaic panel 10 at a constant voltage.

This configuration makes it possible to correct a tracking shift in a state in which a tracking solar photovoltaic power generation system 1 (photovoltaic panel 10) is operated at a constant voltage, thus enabling the tracking shift to be corrected with ease and high precision under stable operating conditions.

It should be noted that constant-voltage mode settings may be performed either automatically or manually in the common inverter 51. In addition, a known technique is applicable to the constant-voltage mode settings, and therefore detailed descriptions thereof have been omitted.

That is, in the tracking shift correction method for the tracking solar photovoltaic power generation system according to the present embodiment, a tracking shift can be corrected in the same manner as in Embodiments 7 and 8. Thus, in the case of correcting a tracking shift, a directly-facing position Pjc can be detected from variations in the output current Ip of a photovoltaic panel 10 as in step S2 (steps S21 to S23) and step S4 (steps S41 to S43), and a tracking shift can be corrected through turning or tilt movement of the photovoltaic panel 10 toward the detected directly-facing position Pjc.

According to the present embodiment, tracking shift correction can be implemented more easily because there is no need to use the MPPT control portion 51c. In addition, even in a tracking drive solar photovoltaic power generator 1s that includes a small number of tracking drive solar photovoltaic power generators 1, the operating voltage can be held at a constant voltage during tracking shift correction operations, and therefore it is possible to correct a tracking shift with ease and precision.

### Tenth Embodiment

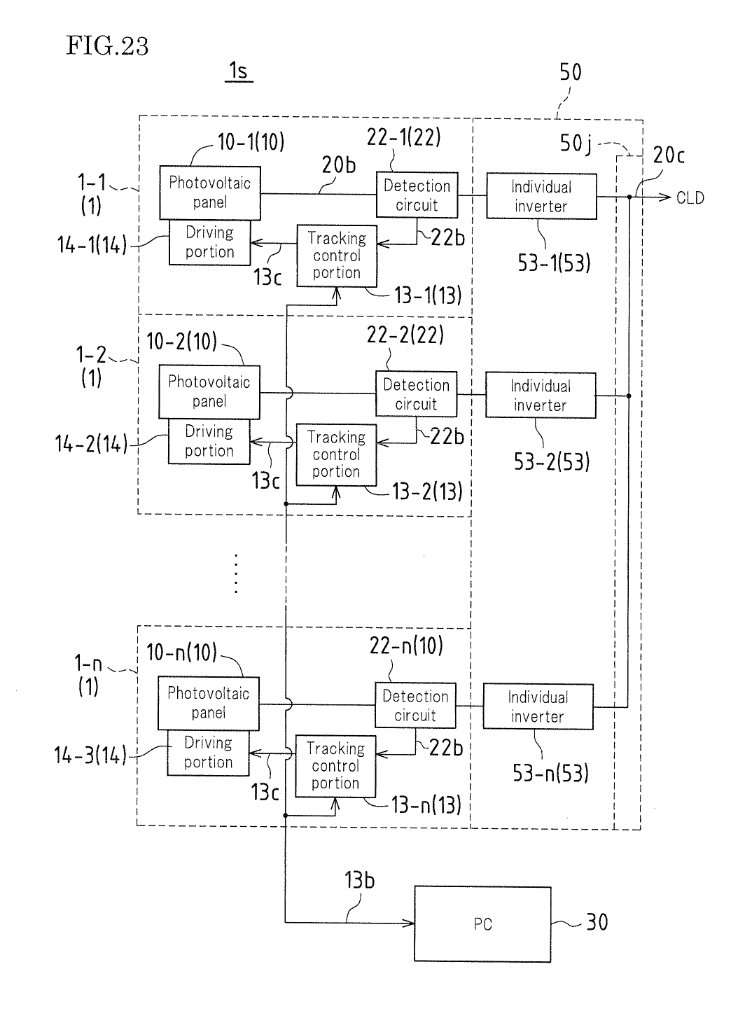

Next is a description of a tracking solar photovoltaic power generation system according to Embodiment 10 and a tracking shift correction method for the tracking solar photovoltaic power generation system in which a tracking shift of a tracking drive solar photovoltaic power generator is corrected, given with reference to FIG. 23.

It should be noted that the basic configuration is similar to those of the tracking drive solar photovoltaic power generators 1, the tracking solar photovoltaic power generation system 1s, and the tracking shift correction method described in Embodiments 7 to 9, and therefore descriptions are primarily given regarding different points.

FIG. 23 is a block diagram illustrating a schematic configuration of the tracking solar photovoltaic power generation system according to Embodiment 10.

The tracking shift correction method for the tracking solar photovoltaic power generation system according to the present embodiment is a method for correcting a tracking shift (shift in position during tracking control) of a tracking drive solar photovoltaic power generator 1 in the tracking solar photovoltaic power generation system is relative to the solar trajectory, the system is including multiple tracking drive solar photovoltaic power generators 1 that are arranged in parallel connection and a power conversion portion 50 that converts direct-current electric power generated by the tracking drive solar photovoltaic power generators 1 into alternating-current electric power and supplies the alternating-current electric power to an interconnection load CLD.

The tracking drive solar photovoltaic power generators 1 have a similar configuration (photovoltaic panel 10, tracking control portion 13, driving portion 14, and detection circuit 22) to those described in Embodiments 7 to 9.

In the present embodiment, the tracking control portion 13 corresponding to a photovoltaic panel 10 that is targeted for tracking shift correction is configured to detect a tracking shift of the photovoltaic panel 10 in a state in which the corresponding tracking drive solar photovoltaic power generator 1 (photovoltaic panel 10) is running by being connected to the power conversion portion 50. Also, the corresponding driving portion 14 is configured to correct a tracking shift of the photovoltaic panel 10 in accordance with the tracking shift detected by the tracking control portion 13. A specific configuration may be similar to that in the case of Embodiment 8.

The power conversion portion 50 according to the present embodiment includes multiple individual inverters 53 that are connected so as to each convert direct-current electric power that is output from each of the photovoltaic panels 10 individually into alternating-current electric power and supply the resultant alternating-current electric power collectively to the interconnection load CLD. The individual inverters 53 (power conversion portion 50) are connected in parallel by an electric power line connection portion 50j and supply generated alternating-current electric power to the interconnection load CLD via an electric power line 20c.

The power conversion portion 50 has arranged therein an individual inverter 53-1 that changes the output of a photovoltaic panel 10-1 into electric power, an individual inverter 53-2 that changes the output of a photovoltaic panel 10-2 into electric power, . . . , and an individual inverter 53-n that changes the output of a photovoltaic panel 10-n into electric power. Hereinafter, each of the inverters may be simply referred to as “individual inverters 53” when there is no particular need to distinguish between the individual inverters 53-1, 53-2, . . . , and 53-n.

That is, the power conversion portion 50 includes individual inverters 53 that are connected so as to each convert direct-current electric power that is output from each of the photovoltaic panels 10 individually into alternating-current electric power and supply the resultant alternating-current electric power collectively to the interconnection load CLD. It should be noted that the individual inverters 53 are operated under constant voltage control.

Thus, the photovoltaic panels 10 can be brought in direct correspondence with the individual inverters 53 each having a capacity corresponding to the capacity of each tracking drive solar photovoltaic power generator 1 (photovoltaic panel), and therefore it is possible to adjust the outputs of the photovoltaic panels 10 and stabilize the operating voltages, which enables a tracking shift to be detected with ease and high precision.

It should be noted that, since the output sides of the individual inverters 53 are connected in parallel by the electric power line connection portion 50j, the alternating-current electric power from each of the individual inverters 53 is collectively supplied by the electric power line connection portion 50j to the interconnection load CLD.

As described above, the tracking solar photovoltaic power generation system is according to the present embodiment includes multiple tracking drive solar photovoltaic power generators 1 that are arranged in parallel connection, and the power conversion portion 50 that converts direct-current electric power generated by the tracking drive solar photovoltaic power generators 1 into alternating-current electric power and supplies the resultant alternating-current electric power to the interconnection load CLD.

Also, in the tracking solar photovoltaic power generation system 1s, each of the tracking drive solar photovoltaic power generators 1 includes a photovoltaic panel 10 that converts sunlight into direct-current electric power, a tracking control portion 13 that outputs tracking information that causes the photovoltaic panel 10 to track the solar trajectory, and a driving portion 14 that drives the photovoltaic panel 10 based on the tracking information. In this system, a configuration is adopted in which the tracking control portion 13 corresponding to a photovoltaic panel 10 that is targeted for tracking shift correction is configured to detect a tracking shift of the photovoltaic panel 10 in a state in which the corresponding tracking drive solar photovoltaic power generator 1 is running by being connected to the power conversion portion 50.

Therefore, a tracking shift of the photovoltaic panel 10 is detected in a state in which the corresponding tracking drive solar photovoltaic power generator 1 is running by being connected to the power conversion portion 50. This enables providing a highly reliable and productive tracking solar photovoltaic power generation system 1s that eliminates the need to be stopped associated with tracking shift correction and causes no loss in the amount of generated electric power.

The tracking solar photovoltaic power generation system 1s according to the present embodiment enables the use of the individual inverters 53 each having a capacity corresponding to the capacity of each tracking drive solar photovoltaic power generator 1, and therefore the tracking solar photovoltaic power generation system 1s can be constructed with ease at low cost by application of small-capacity, low-cost individual inverters 53. Moreover, direct correspondence between the photovoltaic panels 10 and the individual inverters 53 makes it easy to adjust the outputs of the photovoltaic panels 10 and simplify output wiring, thus making the tracking solar photovoltaic power generation system 1s rational and economical.

As described above, the individual inverters 53 are configured to operate under constant voltage control and hold the output operating points of the photovoltaic panels 10 at a constant voltage. In other words, the individual inverters 53 function similarly to the common inverter 51 of Embodiment 9.

It is thus possible to correct a tracking shift in a state in which the photovoltaic panels 10 are operated at a constant voltage and to thereby correct a tracking shift with ease and high precision under stable operating conditions.

It should be noted that an inverter is generally configured to be able to observe direct input current and direct input voltage. In the tracking solar photovoltaic power generation system 1s according to the present embodiment, since the individual inverters 53 are connected corresponding individually to the photovoltaic panels 10, a configuration is also possible in which the outputs of the photovoltaic panels 10 are detected by the individual inverters 53, instead of being detected by the detection circuits 22. This configuration makes it possible to eliminate the need for the detection circuits 22 and to thereby simplify the circuit configuration of the tracking drive solar photovoltaic power generators 1.

### Eleventh Embodiment

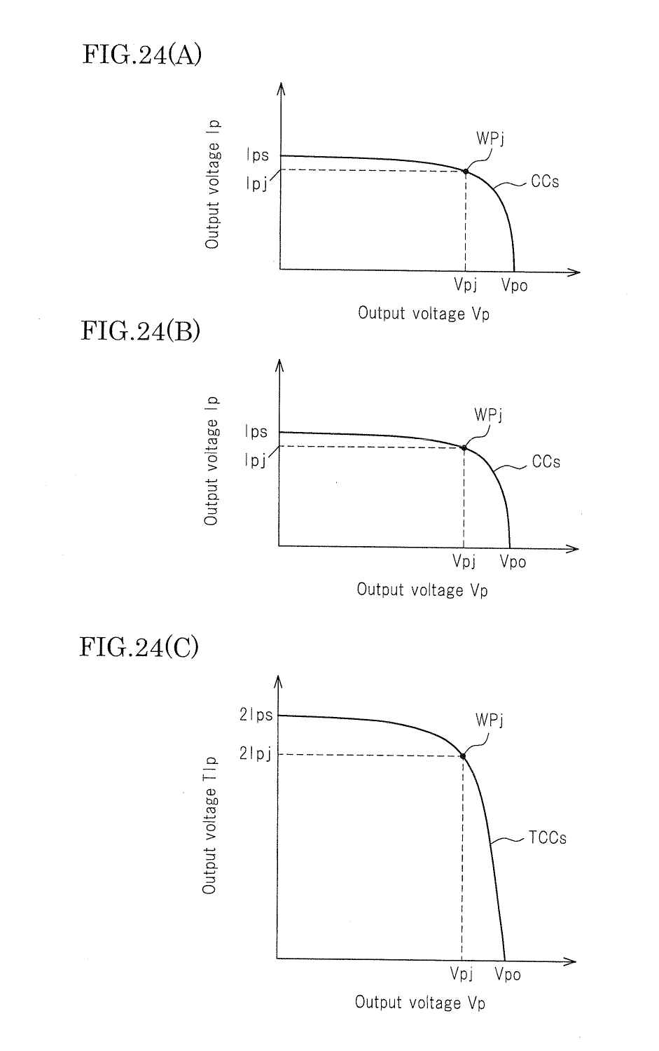

Next is a description of a tracking solar photovoltaic power generation system is (hereinafter which may be simply referred to as a “system”) as described in Embodiments 7 to 9, in which the photovoltaic panels 10 (tracking drive solar photovoltaic power generators 1) are connected in parallel, i.e., the output characteristics (VI characteristic curve) obtained when applying a common inverter 51, given with reference to FIGS. 24 to 26, as Embodiment 11 of the present invention.

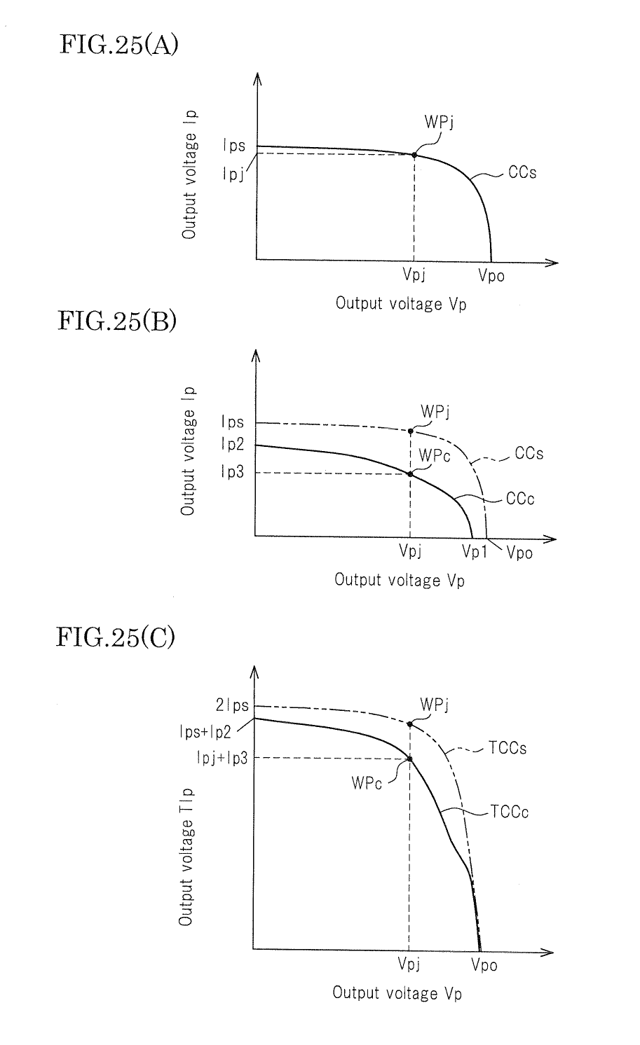

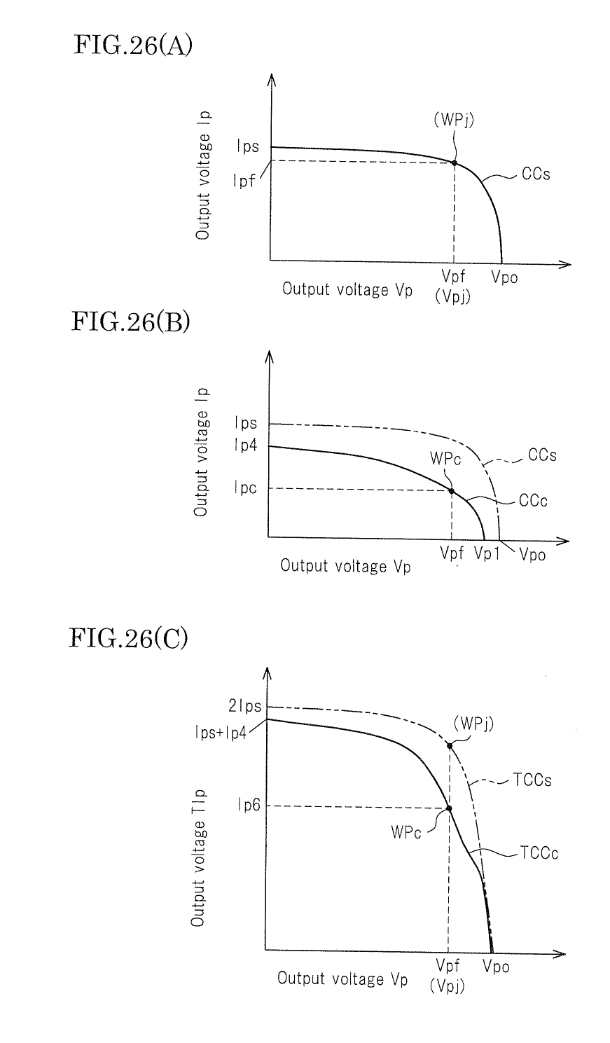

FIG. 24 shows the characteristics of a photovoltaic panel 10 during normal operation, FIG. 24(A) showing the case where the photovoltaic panel 10 is not targeted for correction, FIG. 24(B) showing the case where the photovoltaic panel 10 is targeted for correction, and FIG. 24(C) showing the combined case for the system. FIG. 25 shows the characteristics of a photovoltaic panel 10 when a shift in position occurs under MPPT control, FIG. 25(A) showing the case where the photovoltaic panel 10 is not targeted for correction, FIG. 25(B) showing the case where the photovoltaic panel 10 is targeted for correction, and FIG. 25(C) show the combined case for the system. FIG. 26 shows the characteristics of a photovoltaic panel 10 when a shift in position occurs under constant voltage control, FIG. 26(A) showing the case where the photovoltaic panel 10 is not targeted for correction, FIG. 26(B) showing the case where the photovoltaic panel 10 is targeted for correction, and FIG. 26(C) showing the combined case for the system.

It should be noted that the combined case for the system refers to, for example, a case where the characteristics of a total of two photovoltaic panels, namely a photovoltaic panel that is not targeted for correction (e.g., photovoltaic panel 10-1) and a photovoltaic panel that is targeted for correction (e.g., photovoltaic panel 10-2), are combined.

FIG. 24 is a graph showing the VI characteristic curve of a photovoltaic panel in the tracking solar photovoltaic power generation system according to Embodiment 11 of the present invention. As described above, FIG. 24(A) shows normal characteristics of a photovoltaic panel that is not targeted for correction, FIG. 24(B) shows normal characteristics of a photovoltaic panel that is targeted for correction, and FIG. 24(C) shows combined characteristics of a photovoltaic panel that is not targeted for correction and a photovoltaic panel that is targeted for correction.

It should be noted that the horizontal axis indicates the output voltage Vp of a photovoltaic panel 10, whereas the vertical axis indicates the output current Ip of the photovoltaic panel 10. Accordingly, a VI characteristic curve CCs is specified in accordance with sunlight irradiation conditions on the photovoltaic panel 10. Note that the same applies to FIGS. 25 and 26.

During normal operation of a tracking drive solar photovoltaic power generator 1 (photovoltaic panel 10), the output operating point of the photovoltaic panel 10 is on the VI characteristic curve CCs and is caused to follow an optimum operating point WPj under MPPT control.

Therefore, the optimum operating point WPj and an optimum output voltage Vpj are determined on a combined VI characteristic curve (combined VI characteristic curve TCCs) as shown in FIG. 24(C).

Under the condition that the optimum operating point WPj and the optimum output voltage Vpj are determined, the VI characteristic curve CCs (FIG. 24(A)) of the photovoltaic panel 10 that is not targeted for correction (e.g., photovoltaic panel 10-1) shows normal characteristics in accordance with sunlight irradiation conditions. Thus, an optimum output voltage Vpj corresponding to the optimum operating point WPj on the characteristic curve of the entire system, and its corresponding optimum output current Ipj are detected as outputs from the curve.

Also, under the condition that the optimum operating point WPj and the optimum output voltage Vpj are determined, the VI characteristic curve CCs (FIG. 24(B)) of the photovoltaic panel 10 that is targeted for correction (e.g., photovoltaic panel 10-2) shows, since during normal operation, normal characteristics similar to those of the photovoltaic panel 10-1. Thus, the optimum output voltage Vpj corresponding to the optimum operating point WPj on the characteristic curve, and its corresponding optimum output current Ipj are detectable as outputs from the curve.

The above outputs (output current Ip) are combined since the photovoltaic panel 10-1 and the photovoltaic panel 10-2 are in parallel connection, forming the combined VI characteristic curve TCCs (FIG. 24(C)) as described above. That is, a characteristic curve of an open-circuit voltage Vpo and a short circuit current 2Ips is obtained.

Because both the photovoltaic panel 10-1 and the photovoltaic panel 10-2 are combined under normal conditions, the output voltage Vp equals the optimum output voltage Vpj and the combined output current TIp equals 2Ipj at the optimum operating point WPj, i.e., those panels are run in parallel due to their parallel connection.

FIG. 25 is a graph showing the VI characteristic curve of a photovoltaic panel under MPPT control in the tracking solar photovoltaic power generation system according to Embodiment 11. FIG. 25(A) shows normal characteristics of a photovoltaic panel that is not targeted for correction, FIG. 25(B) shows characteristics under a condition in which a tracking position is moved in order to detect a shift in the position of a photovoltaic panel that is targeted for correction, and FIG. 25(C) shows combined characteristics of a photovoltaic panel that is not targeted for correction and a photovoltaic panel that is targeted for correction.

The VI characteristic curve CCs (FIG. 25(A)) of the photovoltaic panel 10-1 that is not targeted for correction is similar to that in FIG. 24(A). That is, it shows normal characteristics in correspondence with sunlight irradiation conditions, and an optimum output voltage Vpj corresponding to an optimum operating point WPj on the characteristic curve, and its corresponding optimum output current Ipj can be detected as outputs from the curve.

A photovoltaic panel 10-2 that is targeted for correction is shifted from a normal tracking state in order to detect a shift in position. Its characteristic curve thus corresponds to a detection VI characteristic curve CCc (FIG. 25(B)), giving an open-circuit voltage Vp1 (<normal open-circuit voltage Vpo) and a short circuit current Ip2 (<normal short circuit current Ips).

Since the system is under MPPT control, an optimum operating point WPc (detection operating point WPc) and its corresponding optimum output voltage Vpj are determined on the curve in FIG. 25(C). That is, the output voltage Vp of the photovoltaic panel 10-2 equals the optimum output voltage Vpj. Accordingly, the operating point is determined as a detection operating point WPc corresponding to the optimum output voltage Vpj, and the output current Ip is detected as an output current Ip3 (current detected by the current detecting portion 23) on the detection VI characteristic curve CCc.

It should be noted that, when a small number of photovoltaic panels 10 are in parallel connection, the output voltage Vp corresponding to the detection operating point WPc is affected by a shift in position and accordingly reduced from the optimum output voltage Vpj. In the present embodiment, however, the output voltage can be maintained at the optimum output voltage Vpj because, for example, 10 or more photovoltaic panels 10 are in connection.

A combined output of the photovoltaic panel 10-1 and the photovoltaic panel 10-2 forms a combined detection VI characteristic curve TCCc (FIG. 25(C)). Since the output of the photovoltaic panel 10-2 is lower than the output of the photovoltaic panel 10-1, a combined output current TIp at the time of short circuiting equals Ips+Ip2 (TIp<2Ips). A combined output current TIp at the operating point WPc equals Ipj+Ip3.

Therefore, the optimum output voltage Vpj can be maintained even in the case of correcting a shift in position. It is thus possible to detect the output current Ip (output current Ip3) with high precision and to thereby detect a shift in position with high precision.

FIG. 26 is a graph showing the VI characteristic curve of a photovoltaic panel under constant voltage control in the tracking solar photovoltaic power generation system according to Embodiment 11 of the present invention. FIG. 26(A) shows normal characteristics of a photovoltaic panel that is not targeted for correction, FIG. 26(B) shows characteristics under a condition in which a tracking position is moved in order to detect a shift in the position of a photovoltaic panel that is targeted for correction, (C) shows combined characteristics of a photovoltaic panel that is not targeted for correction and a photovoltaic panel that is targeted for correction.

The VI characteristic curve CCs (FIG. 26(A)) of the photovoltaic panel 10-1 that is not targeted for correction is similar to those in FIGS. 24(A) and 25(A), showing normal characteristics in accordance with sunlight irradiation conditions. Also, a fixed output voltage Vpf that is determined for the entire system, and an output current Ipf that corresponds to the fixed output voltage Vpf on the VI characteristic curve CCs of the photovoltaic panel 10-1 can be detected from the curve.

A photovoltaic panel 10-2 that is targeted for correction is shifted from a normal tracking state in order to detect a shift in position. Therefore, its characteristic curve corresponds to a detection VI characteristic curve CCc (FIG. 26(B)), giving an open-circuit voltage Vp1 (<normal open-circuit voltage Vpo) and a short circuit current Ip4 (<normal short circuit current Ips).

Also, the output voltage Vp becomes the fixed output voltage Vpf because the photovoltaic panel 10-2 is operated under constant voltage control. Accordingly, the operating point becomes a detection operating point WPc corresponding to the fixed output voltage Vpf, and the output current Ip is detected as output current Ipc (current detected by the current detecting portion 23) on the detection VI characteristic curve CCc.

A combined output of the photovoltaic panel 10-1 and the photovoltaic panel 10-2 forms a combined detection VI characteristic curve TCCc (FIG. 26(C)). Since the output of the photovoltaic panel 10-2 is lower than that of the photovoltaic panel 10-1, a combined output current TIp during short circuiting equals Ips+Ip4 (TIp<2Ips). The combined output current TIp at the detection operating point WPc equals Ip6 (=Ipf+Ipc).

Therefore, the fixed output voltage Vpf can be maintained even in the case of correcting a shift in position. It is thus possible to detect the output current Ip (output current Ip5) with high precision and to thereby detect a shift in position with high precision. It should be noted that, although the fixed output voltage Vpf may be determined arbitrarily, a shift in position can be detected with higher precision if the fixed output voltage is set to exactly the same or close enough to the optimum output voltage Vpj corresponding to the optimum operating point WPj on the VI characteristic curve CCs showing normal characteristics or on the combined detection VI characteristic curve TCCs.

It should be noted that the present invention may be embodied in various other forms without departing from the gist or essential characteristics thereof. Therefore, the embodiments described above are to be considered in all respects as illustrative and not limiting. The scope of the invention is indicated by the appended claims rather than by the foregoing description, and all modifications or changes that come within the meaning and range of equivalency of the claims are intended to be embraced therein.

### INDUSTRIAL APPLICABILITY

The present invention is suitably applicable to a tracking solar photovoltaic power generation system that causes a photovoltaic panel to track the solar trajectory.

### DESCRIPTION OF REFERENCE NUMERALS

1, 1-1, 1-2, 1-n Tracking drive solar photovoltaic power generator
1s Tracking solar photovoltaic power generation system
10, 10-1, 10-2, 10-n Photovoltaic panel
11 Column
12 Driving portion
13, 13-1, 13-2, 13-n Tracking control portion
13b Communication line
13c Control line
20 Electric power monitoring board
20b, 20c Electric power line
21 Switch
22, 22-1, 22-2, 22-n Detection circuit
22b Detection line
25 Output side circuit breaker
26 A/D conversion portion
30 PC
40 Inverter
41 Simulated load
50 Power conversion portion
50j Electric power line connection portion
51 Common inverter
51c MPPT control portion
53, 53-1, 53-2, 53-n Individual inverters

1. A tracking control method for a tracking solar photovoltaic power generation system for causing a photovoltaic panel to track a solar trajectory,
the system comprising a tracking drive solar photovoltaic power generator that comprises a photovoltaic panel that converts sunlight into electric power, and a tracking control portion that provides tracking control over a turning position and a tilt position of a photovoltaic panel so that the photovoltaic panel can track the solar trajectory based on control coordinates, namely a turning coordinate and a tilt coordinate that have been set corresponding to a solar azimuth angle and a solar altitude, the tracking control method comprising:
a first directly-facing turning coordinate detection process for detecting a first directly-facing turning coordinate at which a panel output reaches its maximum value, by moving the turning position of the photovoltaic panel while sequentially changing the turning coordinate in a first turning detection range that is defined in connection with a first turning coordinate that corresponds to the solar azimuth angle; and
a first directly-facing tilt coordinate detection process for detecting a first directly-facing tilt coordinate at which the panel output reaches its maximum value, by moving the tilt position of the photovoltaic panel while sequentially changing the tilt coordinate in a first tilt detection range that is defined in connection with a first tilt coordinate that corresponds to the solar altitude.

2. The tracking control method for the tracking solar photovoltaic power generation system according to claim 1, wherein the first turning detection range is defined from a first turning detection start coordinate to a first turning detection end coordinate by using the first turning coordinate as a first turning detection reference coordinate and applying a predetermined first turning displacement angle in both positive and negative directions of the first turning detection reference coordinate, and
the first tilt detection range is defined from a first tilt detection start coordinate to a first tilt detection end coordinate by using either the first tilt coordinate or a first time-dependent corrected tilt coordinate obtained through time-dependent correction of the first tilt coordinate as a first tilt detection reference coordinate and applying a predetermined first tilt displacement angle in both positive and negative directions of the first tilt detection reference coordinate.

3. The tracking control method for the tracking solar photovoltaic power generation system according to claim 1, wherein the first directly-facing tilt coordinate detection process is performed after execution of a first directly-facing turning coordinate alignment process for aligning the turning coordinate with the first directly-facing turning coordinate detected in the first directly-facing turning coordinate detection process.

4. The tracking control method for the tracking solar photovoltaic power generation system according to claim 1, wherein, before execution of the first directly-facing tilt coordinate detection process, the first time-dependent corrected tilt coordinate is calculated by performing time-dependent correction reflecting an amount of change in the solar altitude over time in the first tilt coordinate, and the first tilt detection reference coordinate is displaced in advance from the first tilt coordinate to the first time-dependent corrected tilt coordinate.

5. The tracking control method for the tracking solar photovoltaic power generation system according to claim 1, wherein the photovoltaic panel is driven by application of a corrected target turning coordinate and a corrected target tilt coordinate that have been set by specifying a targeted solar azimuth angle as a target solar azimuth angle and a targeted solar altitude as a target solar altitude, performing coordinate transformation using preset equations from the target solar azimuth angle and the target solar altitude to a target turning coordinate and a target tilt coordinate for the turning coordinate and the tilt coordinate, and correcting the target turning coordinate and the target tilt coordinate based on the first directly-facing turning coordinate and the first directly-facing tilt coordinate.

6. The tracking control method for the tracking solar photovoltaic power generation system according to claim 1, wherein voltage is used to detect the panel output in the first directly-facing turning coordinate detection process and the first directly-facing tilt coordinate detection process.

7. The tracking control method for the tracking solar photovoltaic power generation system according to claim 1, wherein current is used to detect the panel output in the first directly-facing turning coordinate detection process and the first directly-facing tilt coordinate detection process.

8. The tracking control method for the tracking solar photovoltaic power generation system according to claim 1, comprising:
a second directly-facing turning coordinate detection process for detecting a second directly-facing turning coordinate at which the panel output reaches its maximum value, by moving the turning position of the photovoltaic panel while sequentially changing the turning coordinate in a second turning detection range that is defined in connection with the first directly-facing turning coordinate; and
a second directly-facing tilt coordinate detection process for detecting a second directly-facing tilt coordinate at which the panel output reaches its maximum value, by moving the tilt position of the photovoltaic panel while sequentially changing the tilt coordinate in a second tilt detection range that is defined in connection with the first directly-facing tilt coordinate.

9. The tracking control method for the tracking solar photovoltaic power generation system according to claim 8, wherein the second turning detection range is defined from a second turning detection start coordinate to a second turning detection end coordinate by using either the first directly-facing turning coordinate or a first time-dependent corrected turning coordinate obtained through time-dependent correction of the first directly-facing turning coordinate as a second turning detection reference coordinate and applying a predetermined second turning displacement angle that is smaller than the first turning displacement angle, in both positive and negative directions of the second turning detection reference coordinate, and
the second tilt detection range is defined from a second tilt detection start coordinate to a second tilt detection end coordinate by using either the first directly-facing tilt coordinate or a second time-dependent corrected tilt coordinate obtained through time-dependent correction of the first directly-facing tilt coordinate as a second tilt detection reference coordinate and applying a predetermined second tilt displacement angle that is smaller than the first tilt displacement angle, in both positive and negative directions of the second tilt detection reference coordinate.

10. The tracking control method for the tracking solar photovoltaic power generation system according to claim 8, wherein, before execution of the second directly-facing turning coordinate detection process, the first time-dependent corrected turning coordinate is calculated by performing time-dependent correction reflecting an amount of change in the solar azimuth angle over time in the first directly-facing turning coordinate, and the second turning detection reference coordinate is displaced in advance from the first directly-facing turning coordinate to the first time-dependent corrected turning coordinate.

11. The tracking control method for the tracking solar photovoltaic power generation system according to claim 8, wherein the second directly-facing tilt coordinate detection process is performed after execution of a second directly-facing turning coordinate alignment process for aligning the turning coordinate with the second directly-facing turning coordinate detected in the second directly-facing turning coordinate detection process.

12. The tracking control method for the tracking solar photovoltaic power generation system according to claim 8, wherein, before execution of the second directly-facing tilt coordinate detection process, the second time-dependent corrected tilt coordinate is calculated by performing time-dependent correction reflecting an amount of change in the solar altitude over time in the first directly-facing tilt coordinate, and the second tilt detection reference coordinate is displaced in advance from the first directly-facing tilt coordinate to the second time-dependent corrected tilt coordinate.

13. The tracking control method for the tracking solar photovoltaic power generation system according to claim 8, wherein the photovoltaic panel is driven by application of a corrected target turning coordinate and a corrected target tilt coordinate that have been set by specifying a targeted solar azimuth angle as a target solar azimuth angle and a targeted solar altitude as a target solar altitude, performing coordinate transformation using preset equations from the target solar azimuth angle and the target solar altitude to a target turning coordinate and a target tilt coordinate for the turning coordinate and the tilt coordinate, and correcting the target turning coordinate and the target tilt coordinate based on the second directly-facing turning coordinate and the second directly-facing tilt coordinate.

14. The tracking control method for the tracking solar photovoltaic power generation system according to claim 8, wherein voltage is used to detect the panel output in the first directly-facing turning coordinate detection process and the first directly-facing tilt coordinate detection process, and
current is used to detect the panel output in the second directly-facing turning coordinate detection process and the second directly-facing tilt coordinate detection process.

15. The tracking control method for the tracking solar photovoltaic power generation system according to claim 8, wherein current is used to detect the panel output in the first directly-facing turning coordinate detection process and the first directly-facing tilt coordinate detection process and to detect the panel output in the second directly-facing turning coordinate detection process and the second directly-facing tilt coordinate detection process.

16. The tracking control method for the tracking solar photovoltaic power generation system according to claim 8, comprising:
a third directly-facing turning coordinate detection process for detecting a third directly-facing turning coordinate at which the panel output reaches its maximum value, by controlling the turning position of the photovoltaic panel while sequentially changing the turning coordinate in a third turning detection range that is defined in connection with the second directly-facing turning coordinate; and
a third directly-facing tilt coordinate detection process for detecting a third directly-facing tilt coordinate at which the panel output reaches its maximum value, by controlling the tilt position of the photovoltaic panel while sequentially changing the tilt coordinate in a third tilt detection range that is defined in connection with the second directly-facing tilt coordinate,
wherein the third turning detection range is defined from a third turning detection start coordinate to a third turning detection end coordinate by using either the second directly-facing turning coordinate or a second time-dependent corrected turning coordinate obtained through time-dependent correction of the second directly-facing turning coordinate as a third turning detection reference coordinate and applying a predetermined third turning displacement angle that is smaller than the second turning displacement angle, in both positive and negative directions of the third turning detection reference coordinate, and
the third tilt detection range is defined from a third tilt detection start coordinate to a third tilt detection end coordinate by using either the second directly-facing tilt coordinate or a third time-dependent corrected tilt coordinate obtained through time-dependent correction of the second directly-facing tilt coordinate as a third tilt detection reference coordinate and applying a predetermined third tilt displacement angle that is smaller than the second tilt displacement angle, in both positive and negative directions of the third tilt detection reference coordinate.

17. The tracking control method for the tracking solar photovoltaic power generation system according to claim 12, wherein current is used to detect the panel output in the third directly-facing turning coordinate detection process and the third directly-facing tilt coordinate detection process.

18. A tracking shift correction method for a tracking solar photovoltaic power generation system for causing a photovoltaic panel to track a solar trajectory, the system comprising a plurality of tracking drive solar photovoltaic power generators that are arranged in parallel connection, and a power conversion portion that converts direct-current electric power generated by the tracking drive solar photovoltaic power generators into alternating-current electric power and supplies the alternating-current electric power to an interconnection load, each of the tracking drive solar photovoltaic power generators comprising a photovoltaic panel that converts sunlight into direct-current electric power, and a driving portion that drives the photovoltaic panel based on tracking information that causes the photovoltaic panel to track the solar trajectory, wherein a tracking shift of any of the photovoltaic panels that is targeted for tracking shift correction is detected in a state in which the corresponding tracking drive solar photovoltaic power generator is running by being connected to the power conversion portion.

19. The tracking shift correction method for the tracking solar photovoltaic power generation system according to claim 18, wherein each of the tracking drive solar photovoltaic power generators comprises a tracking control portion that outputs the tracking information, in which the tracking control portion detects a tracking shift and the driving portion corrects a tracking shift of the photovoltaic panel in accordance with the tracking shift detected by the tracking control portion.

20. The tracking shift correction method for the tracking solar photovoltaic power generation system according to claim 19, wherein each of the tracking drive solar photovoltaic power generators comprises a detection circuit that detects the output of the photovoltaic panel, in which the tracking control portion detects a tracking shift based on the output of the photovoltaic panel detected by the detection circuit.

21. The tracking shift correction method for the tracking solar photovoltaic power generation system according to claim 20, wherein the detection circuit includes a current detecting portion that detects an output current of the photovoltaic panel.

22. The tracking shift correction method for the tracking solar photovoltaic power generation system according to claim 21, wherein a directly-facing position in which the photovoltaic panel directly faces the solar trajectory is determined based on the output current detected by the current detecting portion, and the photovoltaic panel is moved to the directly-facing position so as to correct a shift in position.

23. The tracking shift correction method for the tracking solar photovoltaic power generation system according to claim 20, wherein the detection circuit includes a voltage detecting portion that detects an output voltage of the photovoltaic panel.

24. The tracking shift correction method for the tracking solar photovoltaic power generation system according to claim 23, wherein a directly-facing position in which the photovoltaic panel directly faces the solar trajectory is determined based on the output voltage detected by the voltage detecting portion, and the photovoltaic panel is moved to the directly-facing position so as to correct a shift in position.

25. The tracking shift correction method for the tracking solar photovoltaic power generation system according to claim 22, wherein the directly-facing position is determined as a directly-facing turning position that is a directly-facing position in a turning direction.

26. The tracking shift correction method for the tracking solar photovoltaic power generation system according to claim 22, wherein the directly-facing position is determined as a directly-facing tilt position that is a directly-facing position in a tilt direction.

27. The tracking shift correction method for the tracking solar photovoltaic power generation system according to claim 18, wherein the power conversion portion comprises a common inverter that is connected so as to convert direct-current electric power that is output from each of the photovoltaic panels collectively into alternating-current electric power and supply the resultant alternating-current electric power to the interconnection load.

28. The tracking shift correction method for the tracking solar photovoltaic power generation system according to claim 18, wherein the power conversion portion comprises a plurality of individual inverters that are connected so as to each convert direct-current electric power that is output from each of the photovoltaic panels individually into alternating-current electric power and supply the resultant alternating-current electric power collectively to the interconnection load.

29. The tracking shift correction method for the tracking solar photovoltaic power generation system according to claim 27, wherein the common inverter causes output operating points of the photovoltaic panels to follow an optimum operating point under maximum power point tracking control.

30. The tracking shift correction method for the tracking solar photovoltaic power generation system according to claim 27, wherein the common inverter or the individual inverters operate under constant voltage control and hold output operating points of the photovoltaic panels at a constant voltage.

31. The tracking shift correction method for the tracking solar photovoltaic power generation system, according to claim 28, wherein the common inverter or the individual inverters operate under constant voltage control and hold output operating points of the photovoltaic panels at a constant voltage.

32. A tracking solar photovoltaic power generation system for causing a photovoltaic panel to track a solar trajectory, comprising:
a plurality of tracking drive solar photovoltaic power generators that are arranged in parallel connection; and
a power conversion portion that converts direct-current electric power generated by the tracking drive solar photovoltaic power generators into alternating-current electric power and supplies the alternating-current electric power to an interconnection load, each of the tracking drive solar photovoltaic power generators comprising a photovoltaic panel that converts sunlight into direct-current electric power, and a driving portion that drives the photovoltaic panel based on tracking information that causes the photovoltaic panel to track the solar trajectory, wherein a tracking shift of any of the photovoltaic panels that is targeted for tracking shift correction is detected in a state in which the corresponding tracking drive solar photovoltaic power generator is running by being connected to the power conversion portion.

33. The tracking solar photovoltaic power generation system according to claim 32, wherein the power conversion portion comprises a common inverter that is connected so as to convert direct-current electric power that is output from each of the photovoltaic panels collectively into alternating-current electric power and supply the resultant alternating-current electric power to the interconnection load.

34. The tracking solar photovoltaic power generation system according to claim 32, wherein the power conversion portion comprises a plurality of individual inverters that are connected so as to each convert direct-current electric power that is output from each of the photovoltaic panels individually into alternating-current electric power and supply the resultant alternating-current electric power collectively to the interconnection load.
